(19) United States
(12) Patent Application Publication
(10) Pub. No.: US 2013/0065180 A1
(43) Pub. Date: Mar. 14, 2013

(54) RESIST COMPOSITION AND METHOD OF FORMING RESIST PATTERN

(71) Applicants: Tsuyoshi Kurosawa, Kawasaki-shi (JP); Kotaro Endo, Kawasaki-shi (JP); Yuta Iwasawa, Kawasaki-shi (JP); Yoshitaka Komuro, Kawasaki-shi (JP); Akiya Kawaue, Kawasaki-shi (JP)

(72) Inventors: Tsuyoshi Kurosawa, Kawasaki-shi (JP); Kotaro Endo, Kawasaki-shi (JP); Yuta Iwasawa, Kawasaki-shi (JP); Yoshitaka Komuro, Kawasaki-shi (JP); Akiya Kawaue, Kawasaki-shi (JP)

(73) Assignee: TOKYO OHKA KOGYO CO., LTD., Kawasaki-shi (JP)

(21) Appl. No.: 13/605,338

(22) Filed: Sep. 6, 2012

(30) Foreign Application Priority Data
Sep. 8, 2011 (JP) 2011-196391
May 7, 2012 (JP) 2012-105953

(51) Int. Cl. G03F 7/004; G03F 7/20

(52) U.S. Cl. 430/270.1; 430/325

(57) ABSTRACT

A resist composition comprising: a base component (A) which exhibits changed solubility in a developing solution under action of acid; an acid-generator component (B) which generates acid upon exposure; and a compound (D1) including of a cation moiety which contains a quaternary nitrogen atom, and an anion moiety represented by formula (d1-an1) or (d1-an2) shown below. In the formulas, X represents a cyclic aliphatic hydrocarbon group of 3 to 30 carbon atoms which may have a substituent; and Y¹ represents a fluorinated alkylene group of 1 to 4 carbon atoms which may have a substituent.

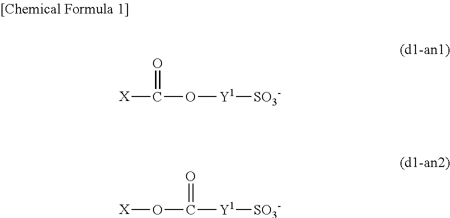

### TECHNICAL FIELD

The present invention relates to a resist composition and a method of forming a resist pattern.

Priority is claimed on Japanese Patent Application No. 2011-196391, filed Sep. 8, 2011, and Japanese Patent Application No. 2012-105953, filed May 7, 2012, the contents of which are incorporated herein by reference.

### DESCRIPTION OF RELATED ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid-generator component that generates acid upon exposure.

For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid-generator component, and the action of this acid causes an increase in the solubility of the resin component in an alkali developing solution, making the exposed portions soluble in the alkali developing solution. In this manner, the unexposed portions remain to form a positive resist pattern. The base resin used exhibits increased polarity by the action of acid, thereby exhibiting increased solubility in an alkali developing solution, whereas the solubility in an organic solvent is decreased. When such a base resin is applied to a process using a developing solution containing an organic solvent (organic developing solution) (hereafter, this process is referred to as “solvent developing process” or “negative tone-developing process”) instead of an alkali developing process, the solubility of the exposed portions in an organic developing solution is decreased. As a result, in the solvent developing process, the unexposed portions of the resist film are dissolved and removed by the organic developing solution, and a negative resist pattern in which the exposed portions are remaining is formed. The negative tone-developing process and the resist composition used for the process is proposed, for example, in Patent Document 1.

Currently, resins that contain structural units derived from (meth)acrylate esters within the main chain (acrylic resins) are now widely used as base resins for resist compositions that use ArF excimer laser lithography, as they exhibit excellent transparency in the vicinity of 193 nm (for example, see Patent Document 2).

The base resin contains a plurality of structural units for improving lithography properties and the like. For example, in the case of a resin component which exhibits increased polarity by the action of acid, a base resin containing a structural unit having an acid decomposable group which is decomposed by the action of an acid generated from the acid generator to increase the polarity, a structural unit having a polar group such as a hydroxy group, a structural unit having a lactone structure, and the like is typically used. In particular, the structural units having a polar group are widely used because it is effective in increasing the compatibility with an alkali developing solution, thereby contributing to improvement in resolution.

Furthermore, currently, in addition to the base resin and the acid generator, a nitrogen-containing organic compound such as an alkylamine, an alkylalcoholamine or the like is added to chemically amplified resists (see, for example, Patent Document 3). In particular, as the nitrogen-containing organic compound, a tertiary amine is widely used. The nitrogen-containing organic compound component functions as a quencher which traps the acid generated from the acid generator, and contributes to improving various lithography properties and resist pattern shape.

Further, there have been proposed that an to a quaternary ammonium compound containing an anion moiety having a specific structure is added to a resist composition as a nitrogen-containing organic compound (see Patent Document 4). The quaternary ammonium compound disclosed in Patent Document 4 is not expected to act as a quencher, but promotes a uniform diffusion of acid generated from the acid generator component, and contributes to the improvement of the pattern shape.

### DOCUMENTS OF RELATED ART

### Patent Document

[Patent Document 1] Japanese Unexamined Patent Application, First Publication No. 2009-025723
[Patent Document 2] Japanese Unexamined Patent Application, First Publication No. 2003-241385
[Patent Document 3] Japanese Unexamined Patent Application, First Publication No. Hei 5-232706
[Patent Document 4] Japanese Unexamined Patent Application, First Publication No. 2010-160447

### SUMMARY OF THE INVENTION

In recent years, as the miniaturization of resist patterns progresses, in addition to high resolution, further improvement in various lithography properties has been demanded.

For example, with respect to mask reproducibility when forming a resist pattern, improvement in this characteristic becomes more important as the pattern becomes finer. Mask error factor (MEF) is one of indexes which indicate mask reproducibility. The MEF is a parameter that indicates how faithfully mask patterns of differing dimensions can be reproduced by using the same exposure dose with fixed pitch and changing the mask size (i.e., mask reproducibility). Smaller MEF value is more preferable.

In addition, in order to improve process margin when forming a pattern, improvement of depth of focus (DOF) properties also becomes important. DOF is the range of depth of focus in which a resist pattern having a predetermined size within the range corresponding to the target size can be formed when the exposure focus is moved upwardly or downwardly with the same exposure dose, i.e., the range in which a resist pattern faithful to the mask pattern can be obtained. Larger DOF is more preferable.

However, in a conventional resist composition, there was a problem that in the case of forming a hole pattern, when the amount of acid generated upon exposure was increased in order to improve DOF properties, MEF was deteriorated, and therefore, it was difficult to achieve a balance between DOF properties and MEF.

The present invention takes the above circumstances into consideration, with an object of providing a resist composition which exhibits excellent depth of focus (DOF) properties and mask error factor (MEF), and a method of forming a resist pattern.

For solving the above-mentioned problems, the present invention employs the following aspects.

Specifically, a first aspect of the present invention is a resist composition including: a base component (A) which exhibits changed solubility in a developing solution under action of acid; an acid-generator component (B) which generates acid upon exposure; and a compound (D1) including a cation moiety which contains a quaternary nitrogen atom, and an anion moiety represented by formula (d1-an1) or (d1-an2) shown below.

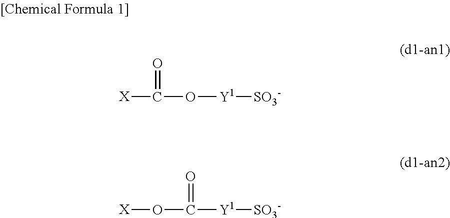

In the formula, X represents a cyclic aliphatic hydrocarbon group of 3 to 30 carbon atoms which may have a substituent; and Y¹ represents a fluorinated alkylene group of 1 to 4 carbon atoms which may have a substituent.

A second aspect of the present invention is a method of forming a resist pattern, including using a resist composition according to the first aspect to form a resist film on a substrate, subjecting the resist film to exposure, and subjecting the resist film to developing to form a resist pattern.

In the present description and claims, the term “exposure” is used as a general concept that includes irradiation with any form of radiation.

The term “structural unit” refers to a monomer unit that contributes to the formation of a polymeric compound (resin, polymer, copolymer).

The term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified. A “halogenated alkyl group” is a group in which part or all of the hydrogen atoms of an alkyl group is substituted with a halogen atom, and a “halogenated alkylene group” is a group in which part or all of the hydrogen atoms of an alkylene group is substituted with a halogen atom. Examples of the halogen atom include a fluorine atom, a chlorine atom, a bromine atom and an iodine atom.

The fluorinated alkyl group is a group in which part or all of the hydrogen atoms of an alkyl group is substituted with a fluorine atom, and a “fluorinated alkylene group” is a group in which part or all of the hydrogen atoms of an alkylene group is substituted with a fluorine atom.

According to the present invention, there are provided a resist composition which exhibits excellent depth of focus (DOF) properties and mask error factor (MEF), and a method of forming a resist pattern.

### DETAILED DESCRIPTION OF THE INVENTION

### Resist Composition

The resist composition of the present invention includes: a base component (A) which exhibits changed solubility in a developing solution under action of acid (hereafter, referred to as “component (A)”); an acid-generator component (B) which generates acid upon exposure (hereafter, referred to as “component (B)”); and a compound (D1) including a cation moiety which contains a quaternary nitrogen atom, and an anion moiety represented by the aforementioned formula (d1-an1) or (d1-an2) (hereafter, referred to as “component (D1)”).

When a resist film formed using the resist composition is subjected to a selective exposure, acid is generated from the component (B) at exposed portions, and the generated acid acts on the component (A) to change the solubility of the component (A) in a developing solution. On the other hand, at unexposed portions, the solubility of the component (A) in a developing solution remains unchanged, so that there is a difference between the exposed portions and the unexposed portions in terms of solubility in a developing solution. Therefore, by developing the resist film, the exposed portions are dissolved and removed in the case that the resist composition is a positive resist, thereby enabling formation of a positive resist pattern, whereas the unexposed portions are dissolved and removed in the case that the resist composition is a negative resist, thereby enabling formation of a negative resist pattern.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition of the present invention may be either a positive resist composition or a negative resist composition.

Further, in the formation of a resist pattern, the resist composition of the present invention can be applied to an alkali developing process using an alkali developing solution in the developing treatment, or a solvent developing process using a developing solution containing an organic solvent (organic developing solution) in the developing treatment.

### <Component (A)>

As the component (A), an organic compound typically used as a base component for a chemically amplified resist composition can be used alone, or two or more of such organic compounds can be mixed together.

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed.

The organic compound which can be used as a base component is broadly classified into non-polymers and polymers.

In general, as a non-polymer, any of those which have a molecular weight in the range of 500 to less than 4,000 is used. Hereafter, a “low molecular weight compound” refers to a non-polymer having a molecular weight in the range of 500 to less than 4,000.

As a polymer, any of those which have a molecular weight of 1,000 or more is generally used. In the present description and claims, the term “resin” refers to a polymer having a molecular weight of 1,000 or more.

The molecular weight of the polymeric compound is the weight average molecular weight in terms of the polystyrene equivalent value determined by gel permeation chromatography (GPC).

The component (A) may be a component that exhibits increased solubility in a developing solution under the action of acid, or may be a component that exhibits decreased solubility in a developing solution under the action of acid.

When the resist composition of the present invention is a resist composition for alkali developing process which forms a negative resist pattern in an alkali developing process (or a resist composition for solvent developing process which forms a positive resist pattern), for example, as the component (A), a base component that is soluble in an alkali developing solution (hereafter, referred to as “alkali soluble base component”) is used, and a cross-linking agent is blended in the resist composition. Generally, a resin (alkali soluble resin) is used as the alkali soluble base component.

Generally, the alkali soluble base component contains alkali soluble groups such as a hydroxy group, a carboxy group and an amino group. As the cross-linking agent, a compound containing reactive groups such as a methylol group or alkoxymethyl group, which can react with the alkali soluble groups by the action of acid, can be used. Therefore, when a resist film formed using the resist composition is subjected to a selective exposure, acid is generated from the component (B) at exposed portions, and the action of the generated acid causes cross-linking between the alkali soluble base component and the cross-linking agent, thereby decreasing the number of alkali soluble groups in the alkali soluble base component, decreasing polarity, and increasing the molecular weight. As a result, the solubility in an alkali developing solution is decreased (that is, the solubility in an organic developing solution is increased).

Therefore, in the formation of a resist pattern, by conducting selective exposure of a resist film formed by applying the resist composition onto a substrate, the exposed portions become insoluble in an alkali developing solution (that is, soluble in an organic developing solution), whereas the unexposed portions remain soluble in an alkali developing solution (that is, insoluble in an organic developing solution), and hence, a negative resist pattern can be formed by alkali developing. In addition, when an organic developing solution is used as a developing solution, a positive resist pattern can be formed.

As the cross-linking agent, typically, an amino-based cross-linking agent such as a glycoluril having a methylol group or alkoxymethyl group, or a melamine-based cross-linking agent is preferable, as it enables formation of a resist pattern with minimal swelling. The amount of the cross linking agent added is preferably within a range from 1 to 50 parts by weight, relative to 100 parts by weight of the alkali-soluble resin.

It is noted that in the case that the alkali soluble base component is a self-crosslinkable component (for example, in the case that the alkali soluble base component has a group which can react with an alkali soluble group by the action of acid), it is not necessary to add a cross-linking agent to the resist composition.

In the case where the resist composition of the present invention is a resist composition which forms a positive resist pattern in an alkali developing process and a negative resist pattern in a solvent developing process, it is preferable to use a base component (A0) (hereafter, referred to as “component (A0)”) which exhibits increased polarity by the action of acid as the component (A). Since the polarity of the component (A0) changes prior to and after exposure, an excellent development contrast can be obtained not only in an alkali developing process, but also in a solvent developing process.

More specifically, in the case of applying an alkali developing process, the component (A0) is substantially insoluble in an alkali developing solution prior to exposure, but when acid is generated from the component (B) upon exposure, the action of this acid causes an increase in the polarity of the base component, thereby increasing the solubility of the component (A0) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing. On the other hand, in the case of a solvent developing process, the component (A0) exhibits high solubility in an organic developing solution prior to exposure, and when acid is generated from the component (B) upon exposure, the polarity of the component (A0) is increased by the action of the generated acid, thereby decreasing the solubility of the component (A0) in an organic developing solution.

Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the present invention, as the component (A), a component (A0) is preferred. That is, the resist composition of the present invention is preferably a chemically amplified resist composition which becomes a positive type in the case of an alkali developing process, and a negative type in the case of a solvent developing process.

The component (A0) may be a resin component that exhibits increased polarity under the action of acid, a low molecular weight material that exhibits increased polarity under the action of acid, or a mixture thereof

### [Component (A1)]

It is preferable that the component (A0) is a resin component which exhibits increased polarity by the action of acid, and it is particularly preferable that the component (A0) includes a polymeric compound (A1) (hereafter, referred to as “component (A1)”) which has a structural unit (a1) containing an acid decomposable group that exhibits increased polarity by the action of acid. As the structural unit (a1), a structural unit derived from an acrylate ester which may have the hydrogen atom bonded to the carbon atom on the α-position substituted with a substituent is preferred.

The component (A1) preferably includes at least one selected from the group consisting of a structural unit (a0) containing a —SO₂-containing cyclic group and a structural unit (a2) containing a lactone-containing cyclic group, as well as the structural unit (a1).

In addition to the structural unit (a1) or in addition to the structural unit (a1) and at least one selected from the structural unit (a0) and structural unit (a2), it is preferable that the component (A1) further include a structural unit (a3) derived from an acrylate ester containing a polar group-containing aliphatic hydrocarbon group and may have the hydrogen atom bonded to the carbon atom on the α-position substituted with a substituent.

(Structural Unit (a1))

The structural unit (a1) is a structural unit containing an acid decomposable group which exhibits increased polarity by the action of an acid.

The term “acid decomposable group” refers to a group in which at least a part of the bond within the structure thereof is cleaved by the action of acid generated from the component (B) upon exposure.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H). Among these, a polar group containing —OH in the structure thereof (hereafter, referred to as “OH-containing polar group”) is preferable, a carboxy group or a hydroxy group is more preferable, and a carboxy group is particularly desirable.

Specific examples of an acid decomposable group include a group in which the aforementioned polar group has been protected with an acid dissociable group (such as a group in which the hydrogen atom of the OH-containing polar group has been protected with an acid dissociable group) can be given.

An “acid dissociable group” is a group in which at least the bond between the acid dissociable group and the adjacent carbon atom is cleaved by the action of acid generated from the component (B) upon exposure. It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, thereby increasing the polarity. As a result, the polarity of the entire component (A1) is increased. When the polarity of the component (A1) is increased, the solubility of the component (A1) in a developing solution is relatively changed. When the developing solution is an alkali developing solution, the solubility of the component (A1) is increased. On the other hand, when the developing solution is a developing solution containing an organic solvent (that is, organic developing solution), the solubility of the component (A1) is decreased.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxy group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

The term “aliphatic branched” refers to a branched structure having no aromaticity. The “aliphatic branched, acid dissociable group” is not limited to be constituted of only carbon atoms and hydrogen atoms (not limited to hydrocarbon groups), but is preferably a hydrocarbon group. Further, the “hydrocarbon group” may be either saturated or unsaturated, but is preferably saturated.

As an example of the aliphatic branched, acid dissociable group, for example, a group represented by the formula —C(R⁷¹)(R⁷²)(R⁷³) can be given. In the formula, each of R⁷¹ to R⁷³ independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly desirable.

The term “aliphatic cyclic group” refers to a monocyclic group or polycyclic group that has no aromaticity.

In the “aliphatic cyclic group-containing acid dissociable group”, the “aliphatic cyclic group” may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

The aliphatic cyclic group preferably has 3 to 30 carbon atoms, more preferably 5 to 30, still more preferably 5 to 20, particularly preferably 6 to 15, and most preferably 6 to 12. As such aliphatic cyclic groups, groups in which one or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples of aliphatic cyclic hydrocarbon groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane. In these aliphatic cyclic hydrocarbon groups, part of the carbon atoms constituting the ring may be replaced with an ethereal oxygen atom (—O—).

Examples of aliphatic cyclic group-containing acid dissociable groups include

(i) a monovalent aliphatic cyclic group in which a substituent (a group or an atom other than hydrogen) is bonded to the carbon atom on the ring skeleton to which an atom adjacent to the acid dissociable group (e.g., “—O—” within “—C(═O)—O— group”) is bonded to form a tertiary carbon atom; and

(ii) a group which has a branched alkylene group containing a tertiary carbon atom, and a monovalent aliphatic cyclic group to which the tertiary carbon atom is bonded.

In the group (i), as the substituent bonded to the carbon atom to which an atom adjacent to the acid dissociable group on the ring skeleton of the aliphatic cyclic group, an alkyl group can be mentioned. Examples of the alkyl group include the same groups as those represented by R¹⁴ in formulas (1-1) to (1-9) described later.

Specific examples of the group (i) include groups represented by general formulas (1-1) to (1-9) shown below.

Specific examples of the group (ii) include groups represented by general formulas (2-1) to (2-6) shown below.

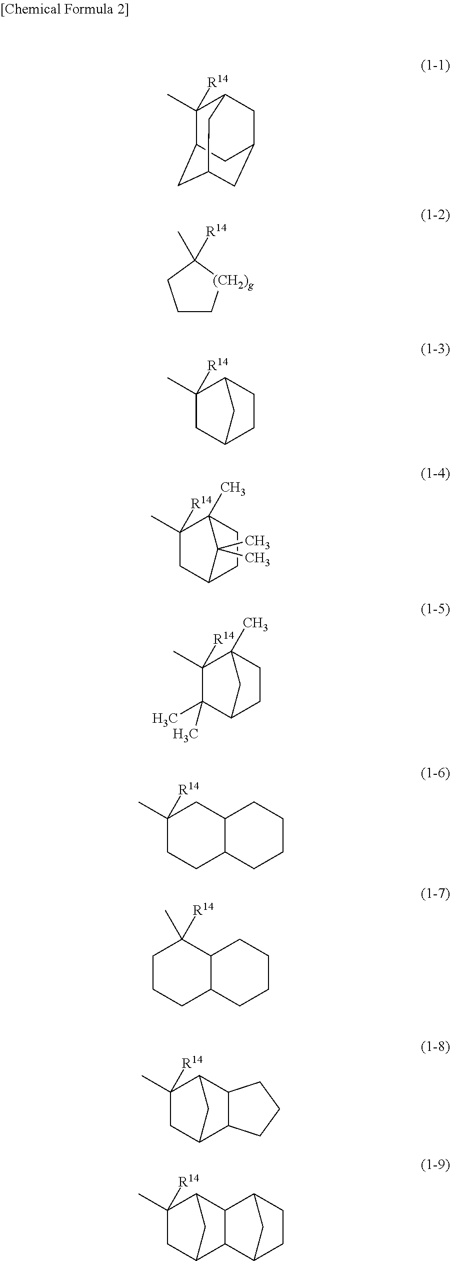

In the formulas above, R¹⁴ represents an alkyl group; and g represents an integer of 0 to 8.

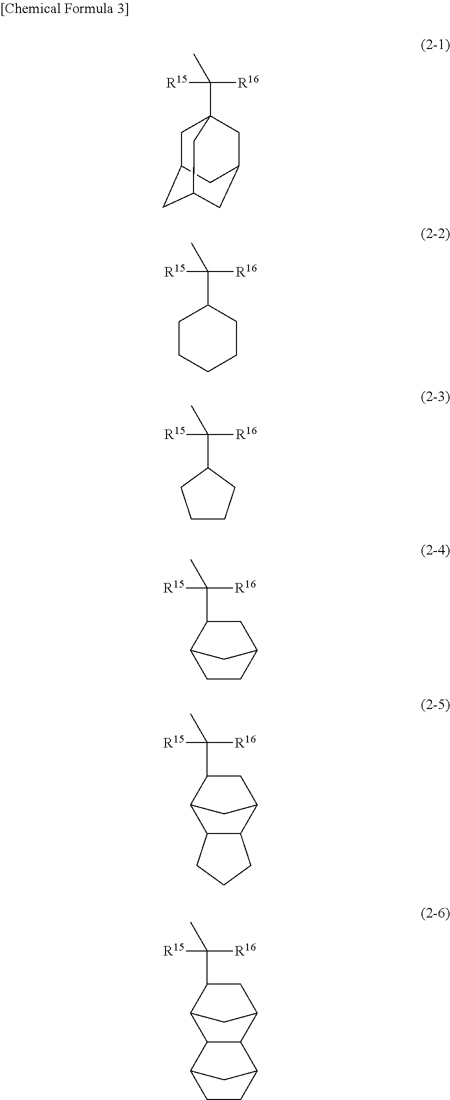

In the formulas above, each of R¹⁵ and R¹⁶ independently represents an alkyl group.

In formulas (1-1) to (1-9), the alkyl group for R¹⁴ may be linear, branched or cyclic, and is preferably linear or branched.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is most desirable.

g is preferably an integer of 0 to 3, more preferably 1 to 3, and still more preferably 1 or 2.

In formulas (2-1) to (2-6), as the alkyl group for R¹⁵ and R¹⁶, the same alkyl groups as those for R¹⁴ can be used.

In formulas (1-1) to (1-9) and (2-1) to (2-6), part of the carbon atoms constituting the ring may be replaced with an ethereal oxygen atom (—O—).

Further, in formulas (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxy group or hydroxyl group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxy group or a hydroxy group.

Examples of acetal-type acid dissociable groups include groups represented by general formula (p1) shown below.

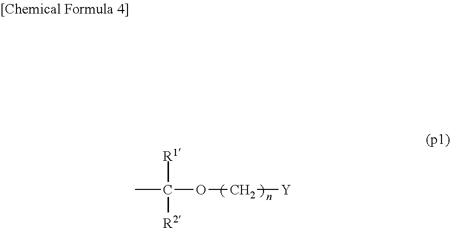

In the formula, R¹′ and R²′ each independently represent a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1), n is preferably an integer of 0 to 2, more preferably 0 or 1, and most preferably 0.

As the alkyl group for R¹′ and R²′, a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group. Among these, a methyl group and an ethyl group is preferable, and a methyl group is most preferable.

In the present invention, it is preferable that at least one of R¹′ and R²′ be a hydrogen atom. That is, it is preferable that the acid dissociable group (p1) is a group represented by general formula (p1-1) shown below.

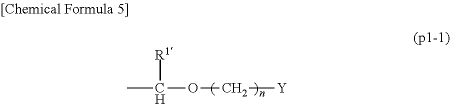

In the formula, R¹′, n and Y are the same as defined above.

As the alkyl group for Y, a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

As the aliphatic cyclic group for Y, any of the aliphatic monocyclic/polycyclic groups which have been proposed for conventional ArF resists and the like can be appropriately selected for use. For example, the same aliphatic cyclic groups described above in connection with the “acid dissociable group containing an aliphatic cyclic group” can be used.

Further, as the acetal-type, acid dissociable group, groups represented by general formula (p2) shown below can also be used.

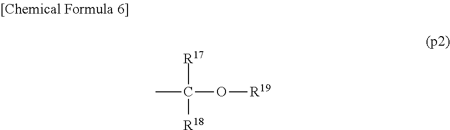

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the R¹⁷ group is bonded to the R¹⁹ group to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and the R¹⁹ group may be bonded to the R¹⁷ group.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4 to 7-membered ring, and more preferably a 4 to 6-membered ring. Specific examples of the cyclic group include tetrahydropyranyl group and tetrahydrofuranyl group.

In the polymer according to the present invention, examples of the structural unit (a1) include a structural unit (a11) which is derived from an acrylate ester which may have the hydrogen atom bonded to the carbon atom on the α-position substituted with a substituent and contains an acid decomposable group which exhibits increased polarity by the action of acid, a structural unit (a12) in which at least part of hydrogen atoms of hydroxy groups in the structural unit derived from a hydroxystyrene or hydroxystyrene derivatives is protected with a substituent containing an acid decomposable group, and a structural unit (a13) in which at least part of the hydrogen atoms of —C(═O)—OH groups in a structural unit derived from a vinylbenzoic acid or vinylbenzoic acid derivatives is protected with a substituent containing an acid decomposable group.

In the present descriptions and claims, the term “structural unit derived from an acrylate ester” refers to a structural unit which is formed by cleavage of the ethylenic double bond of an acrylate ester.

An “acrylate ester” refers to a compound in which the terminal hydrogen atom of the carboxy group of acrylic acid (CH₂═CH—COOH) has been substituted with an organic group.

An acrylate ester may have the hydrogen atom bonded to the carbon atom on the α-position substituted with a substituent. The substituent bonded to the carbon atom on the α-position is a group or atom other than a hydrogen atom. Examples of the substituent bonded to the carbon atom on the α-position include an alkyl group of 1 to 5 carbon atoms, a halogenated alkyl group of 1 to 5 carbon atoms and a hydroxyalkyl group of 1 to 5 carbon atoms. A carbon atom on the α-position of an acrylate ester refers to the carbon atom bonded to the carbonyl group, unless specified otherwise.

In the present specification, an acrylate ester in which the hydrogen atom bonded to the carbon atom on the α position has been substituted with a substituent is referred to as an “α-substituted acrylate ester”. Further, acrylate esters and α-substituted acrylate esters are collectively referred to as “(α-substituted) acrylate ester”.

As the alkyl group for the substituent at the α-position in the α-substituted acrylate ester, a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group for the substituent at the α-position include groups in which part or all of the hydrogen atoms of the aforementioned “alkyl group for the substituent at the α-position” are substituted with halogen atoms. Examples of the halogen atom include a fluorine atom, a chlorine atom, a bromine atom and an iodine atom, and a fluorine atom is particularly preferred.

Specific examples of the hydroxy alkyl group for the substituent at the α-position include groups in which part or all of the hydrogen atoms of the aforementioned “alkyl group for the substituent at the α-position” are substituted with hydroxy group.

It is preferable that a hydrogen atom, an alkyl group of 1 to 5 carbon atoms or a halogenated alkyl group of 1 to 5 carbon atoms is bonded to the α-position of the acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

A “structural unit derived from a hydroxystyrene or hydroxystyrene derivatives” refers to a structural unit that is formed by the cleavage of the ethylenic double bond of a hydroxystyrene or hydroxystyrene derivatives.

The term “hydroxystyrene derivatives” includes compounds in which the hydrogen atom at the α-position of a hydroxystyrene has been substituted with another substituent such as an alkyl group and a halogenated alkyl group, and derivatives thereof. A carbon atom on the α-position refers to the carbon atom bonded to the benzene ring, unless specified otherwise.

A “structural unit derived from a vinylbenzoic acid or vinylbenzoic acid derivatives” refers to a structural unit that is formed by the cleavage of the ethylenic double bond of a vinylbenzoic acid or vinylbenzoic acid derivatives.

The term “vinylbenzoic acid derivatives” includes compounds in which the hydrogen atom at the α-position of a vinylbenzoic acid has been substituted with another substituent such as an alkyl group and a halogenated alkyl group, and derivatives thereof. A carbon atom on the α-position refers to the carbon atom bonded to the benzene ring, unless specified otherwise.

The structural unit (a11), structural unit (a12) and structural unit (a13) will be described below.

-Structural Unit (a11)

Specific examples of the structural unit (a11) include a structural unit represented by general formula (a11-0-1) shown below and a structural unit represented by general formula (a11-0-2) shown below.

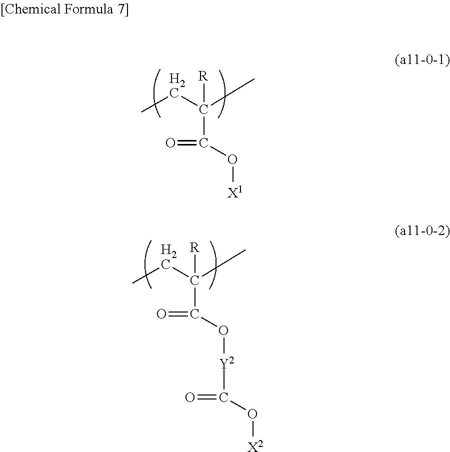

In the formulas, R represents a hydrogen atom, an alkyl group of 1 to 5 carbon atoms or a halogenated alkyl group of 1 to 5 carbon atoms; X¹ represents an acid dissociable group; Y² represents a divalent linking group; and X² represents an acid dissociable group.

In general formula (a11-0-1), the alkyl group and the halogenated alkyl group for R are respectively the same as defined for the alkyl group and the halogenated alkyl group for the substituent which may be bonded to the carbon atom on the α-position of the aforementioned α-substituted acrylate ester. R is preferably a hydrogen atom, an alkyl group of 1 to 5 carbon atoms or a fluorinated alkyl group of 1 to 5 carbon atoms, and most preferably a hydrogen atom or a methyl group.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a11-0-2), R is the same as defined above.

X¹ is the same as defined for X¹ in general formula (a11-0-1).

The divalent linking group for Y² is not particularly limited, and preferable examples thereof include a divalent hydrocarbon group which may have a substituent and a divalent linking group containing a hetero atom.

A hydrocarbon “has a substituent” means that part or all of the hydrogen atoms within the hydrocarbon group is substituted with a substituent (a group or an atom other than hydrogen atom).

The hydrocarbon group may be either an aliphatic hydrocarbon group or an aromatic hydrocarbon group.

An “aliphatic hydrocarbon group” refers to a hydrocarbon group that has no aromaticity.

The divalent aliphatic hydrocarbon group as the divalent hydrocarbon group for Y² may be either saturated or unsaturated. In general, the divalent aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 6, still more preferably 1 to 4, and most preferably 1 to 3.

As the linear aliphatic hydrocarbon group, a linear alkylene group is preferable, and specific examples include a methylene group [—CH₂—], an ethylene group [—(CH₂)₂-], a trimethylene group [—(CH₂)₃-], a tetramethylene group [—(CH₂)₄-] and a pentamethylene group [—(CH₂)₅-].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and an oxygen atom (═O).

As examples of the hydrocarbon group containing a ring in the structure thereof, an alicyclic hydrocarbon group (a group in which two hydrogen atoms have been removed from an aliphatic hydrocarbon ring), and a group in which the alicyclic hydrocarbon group is bonded to the terminal of the linear or branched aliphatic hydrocarbon group or interposed within the aforementioned linear aliphatic hydrocarbon group, can be given. Examples of the linear or branched aliphatic hydrocarbon group include the same groups as described above.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The alicyclic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

The aromatic hydrocarbon group is a hydrocarbon group having an aromatic ring.

The aromatic hydrocarbon group as a divalent hydrocarbon group for Y² preferably has 5 to 30 carbon atoms, more preferably 5 to 20, particularly preferably 6 to 15, and most preferably 6 to 10. Here, the number of carbon atoms within a substituent(s) is not included in the number of carbon atoms of the aromatic hydrocarbon group.

Examples of the aromatic ring in the aromatic hydrocarbon group include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom.

Specific examples of the aromatic hydrocarbon group include a group in which two hydrogen atoms have been removed from the aromatic hydrocarbon ring (arylene group); a group in which one of hydrogen atom of the group in which one hydrogen atom has been removed from the aromatic hydrocarbon group (aryl group) is substituted with an alkylene group (for example, a group in which one hydrogen atom is removed from an aryl group in an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and particularly preferably 1.

The aromatic hydrocarbon group may or may not have a substituent. For example, one or more of the hydrogen atoms bonded to the aromatic hydrocarbon ring in the aromatic hydrocarbon group may be substituted with a substituent. Examples of substituents include an alkyl group, an alkoxy group, a halogen atom, a halogenated alkyl group, a hydroxyl group and an oxygen atom (═O).

The alkyl group as the substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

With respect to a “divalent linking group containing a hetero atom” for Y², a hetero atom is an atom other than carbon and hydrogen, and examples thereof include an oxygen atom, a nitrogen atom, a sulfur atom and a halogen atom.

Examples of the divalent linking group containing a hetero atom include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, —NH—C(═O)—, ═N— and a group represented by general formula —Y²¹—O—Y²²—, —[Y²¹—C(═O)—O]_{m′}—Y²²— or —Y²¹—O—C(═O)—Y²² [in the formulas, each of Y²¹ and Y²² independently represents a divalent hydrocarbon group which may have a substituent, O represents an oxygen atom, and m′ represents an integer of 0 to 3].

When Y² represents —NH—, H may be substituted with a substituent such as an alkyl group, an aryl group (an aromatic group) or the like. The substituent (an alkyl group, an aryl group or the like) preferably has 1 to 10 carbon atoms, more preferably 1 to 8, and particularly preferably 1 to 5.

In the formula —Y²¹—O—Y²²—, —[Y²¹—C(═O)—O]_{m′}—Y²²— or —Y²¹—O—C(═O)—Y²², each of Y²¹ and Y²² independently represents a divalent hydrocarbon group which may have a substituent. As the divalent hydrocarbon group, the same groups as those described above for the “divalent hydrocarbon group which may have a substituent” for Y², can be mentioned.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and particularly preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a hetero atom, a linear group containing an oxygen atom as the hetero atom e.g., a group containing an ether bond or an ester bond is preferable, and a group represented by the aforementioned formula —Y²¹—O—Y²²—, —[Y²¹—C(═O)—O]_{m′}—Y²²— or —Y²¹—O—C(═O)—Y²²— is more preferable.

As the divalent linking group for Y², a linear or branched alkylene group, a divalent alicyclic hydrocarbon group or a divalent linking group containing a hetero atom is particularly desirable. Among these, a linear or branched alkylene group or a divalent linking group containing a hetero atom is more preferable.

Specific examples of the structural unit (a11) include structural units represented by general formulas (a1-1) to (a1-4) shown below.

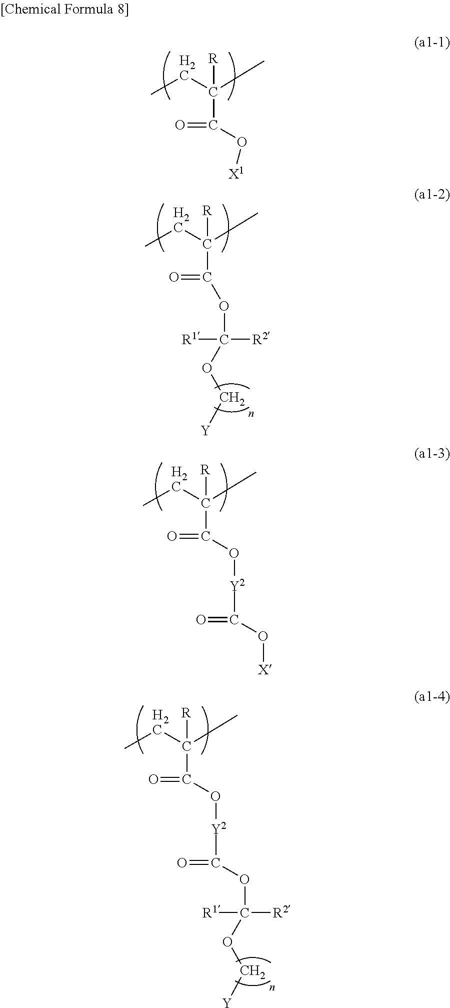

In the formulas, R, R¹′, R²′, n, Y and Y² are the same as defined above; and X′ represents a tertiary alkyl ester-type acid dissociable group.

In the formulas, the tertiary alkyl ester-type acid dissociable group for X′ include the same tertiary alkyl ester-type acid dissociable groups as those described above.

As R¹′, R²′, n and Y are respectively the same as defined for R¹′, R²′, n and Y in general formula (p1) described above in connection with the “acetal-type acid dissociable group”.

Y² is the same as defined for Y² in general formula (a11-0-2).

Specific examples of structural units represented by general formulas (a1-1) to (a1-4) are shown below.

In the formulas shown below, R^{α} represents a hydrogen atom, a methyl group or a trifluoromethyl group.

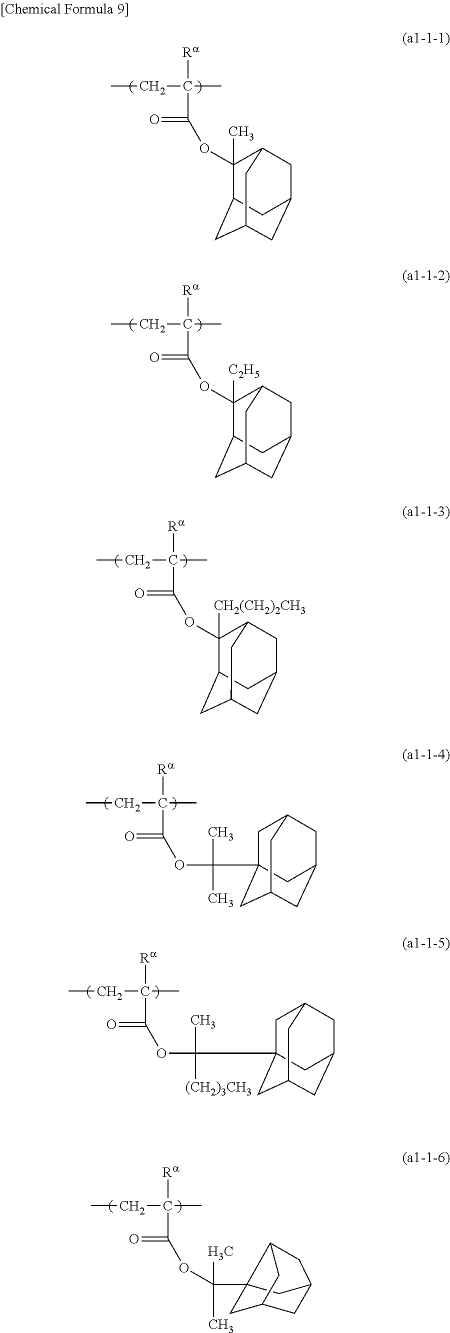

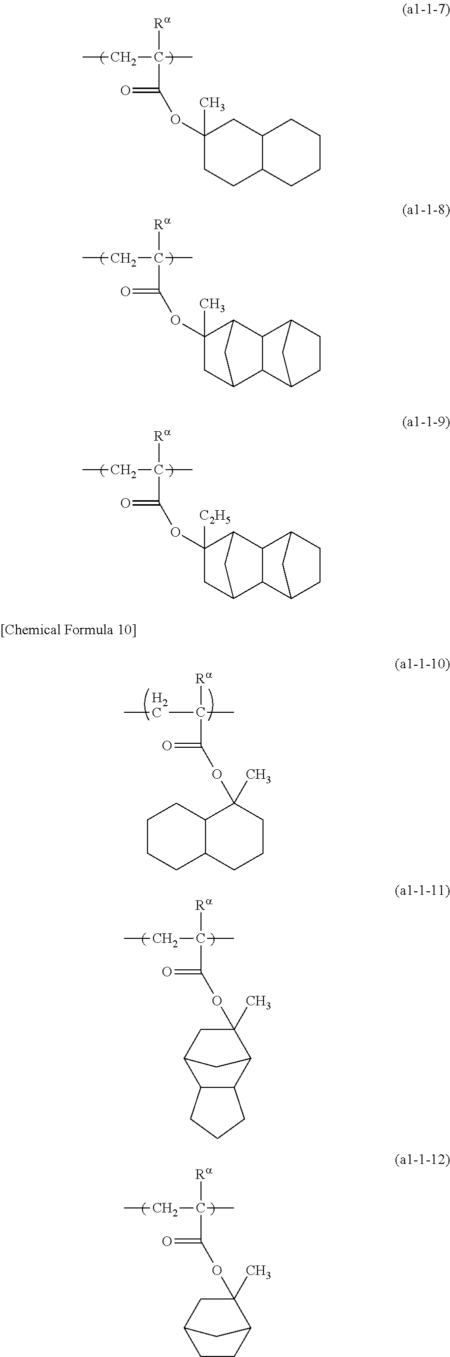

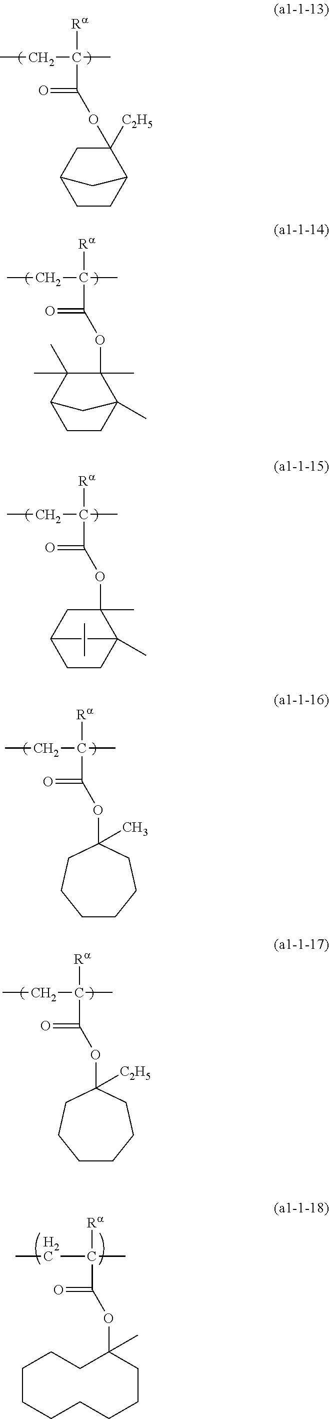

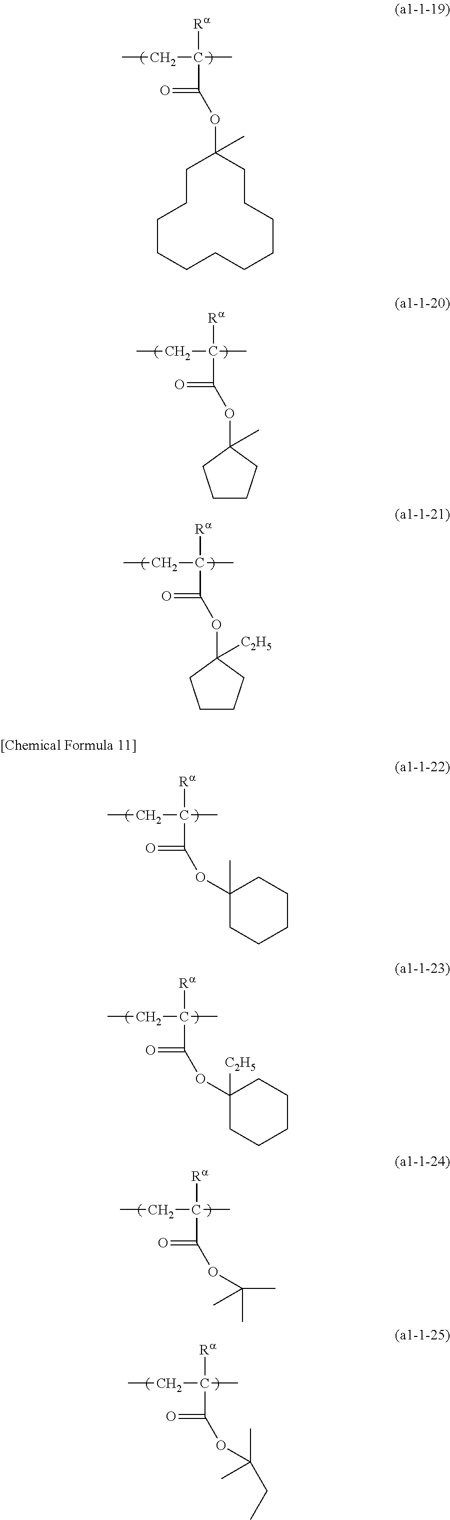

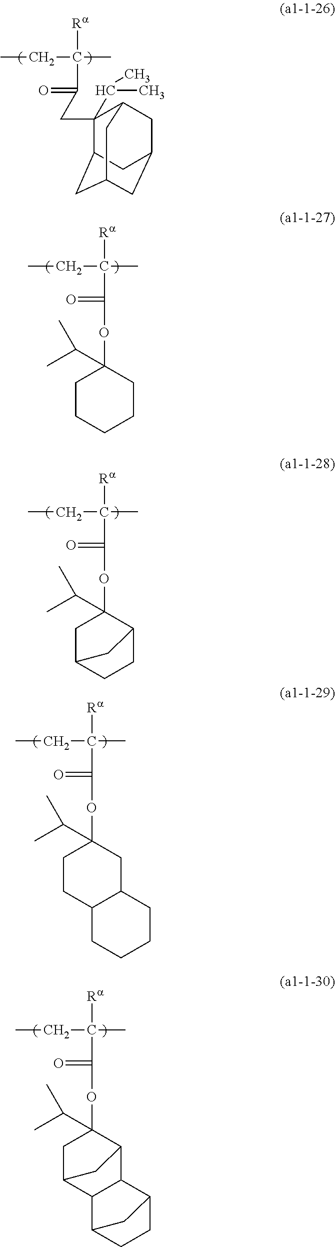

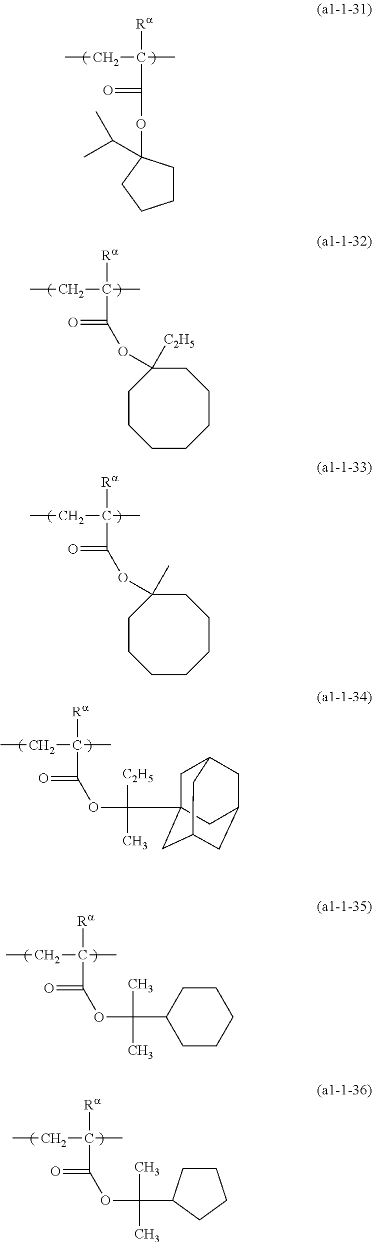

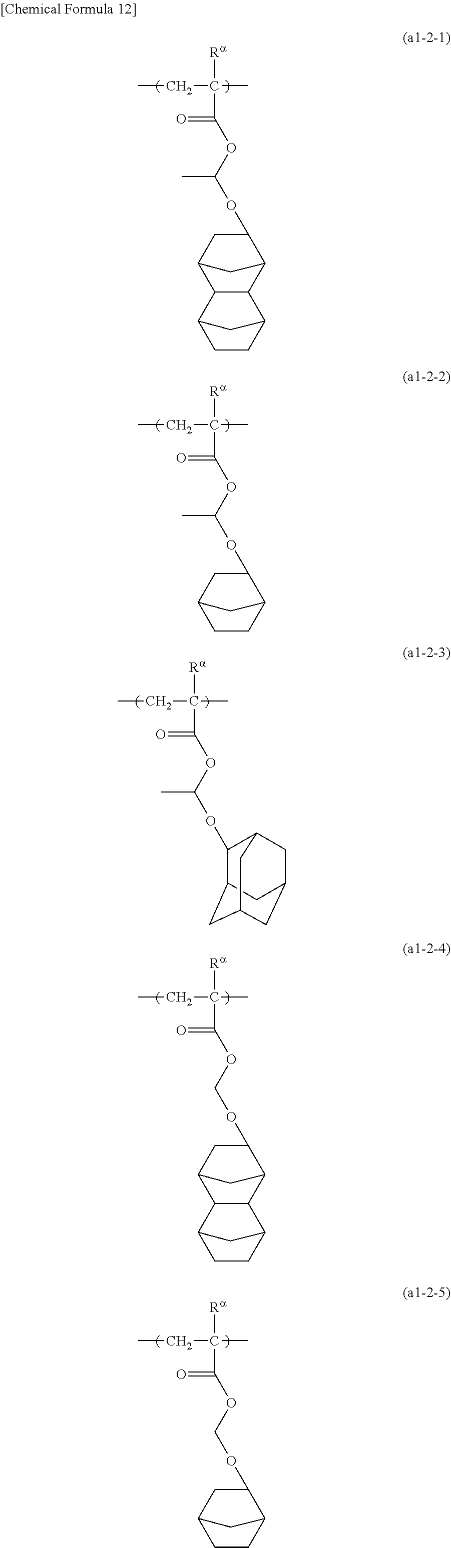

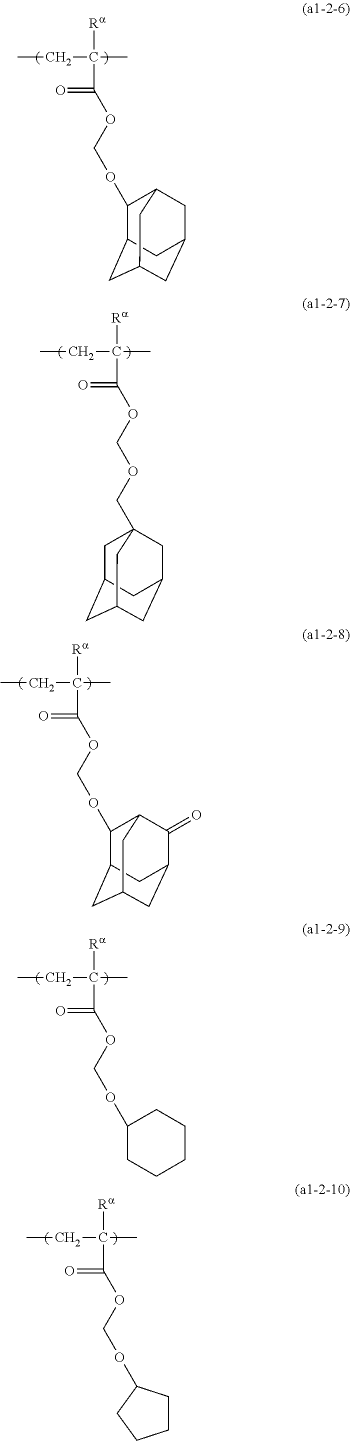

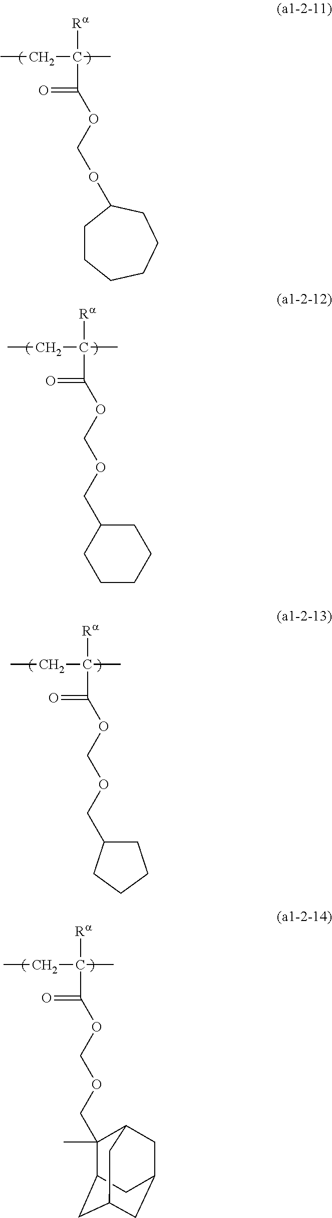

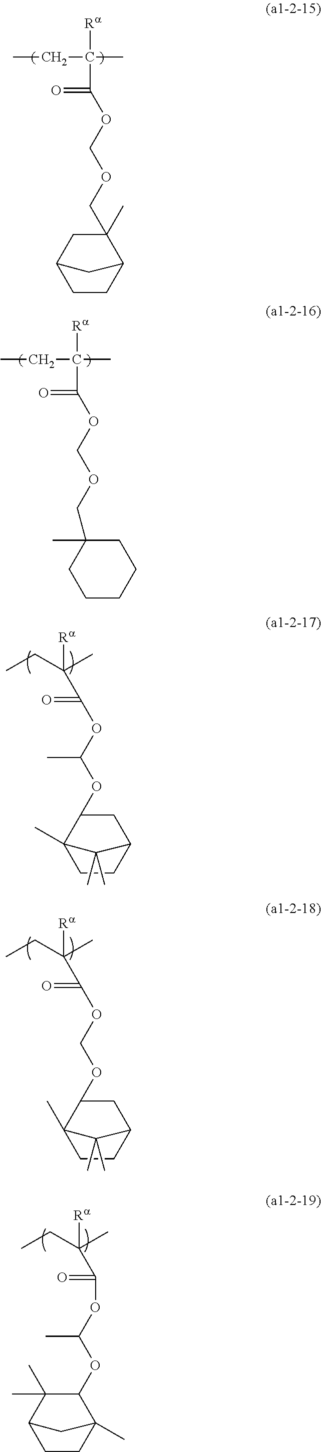

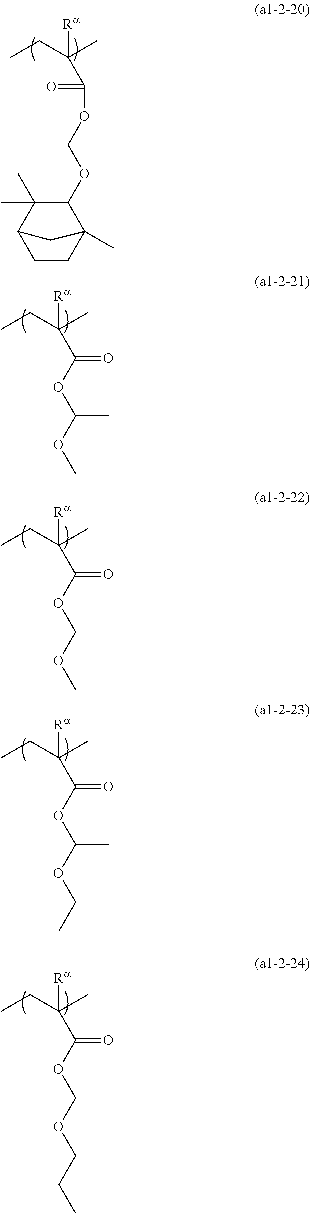

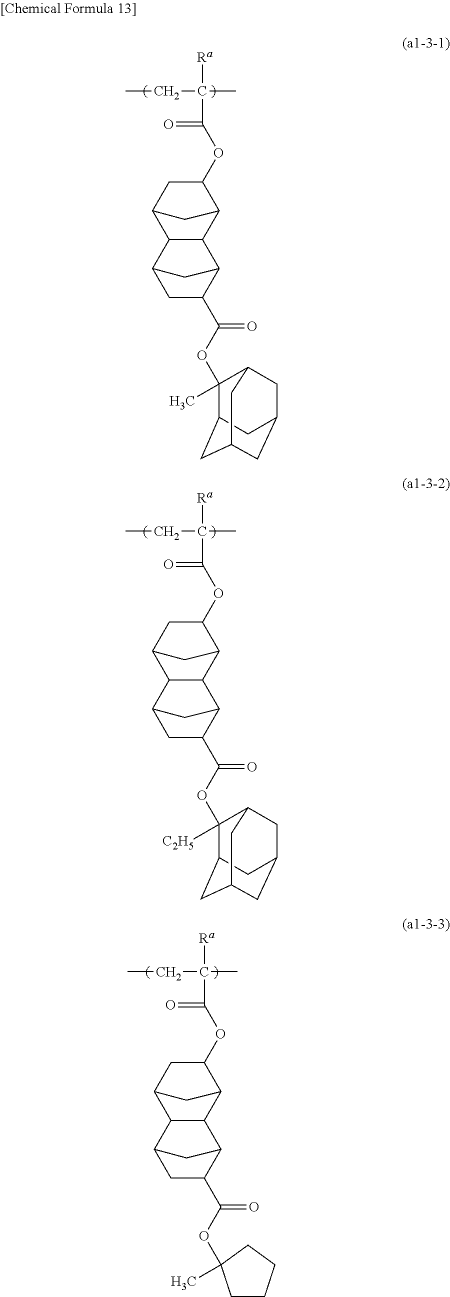

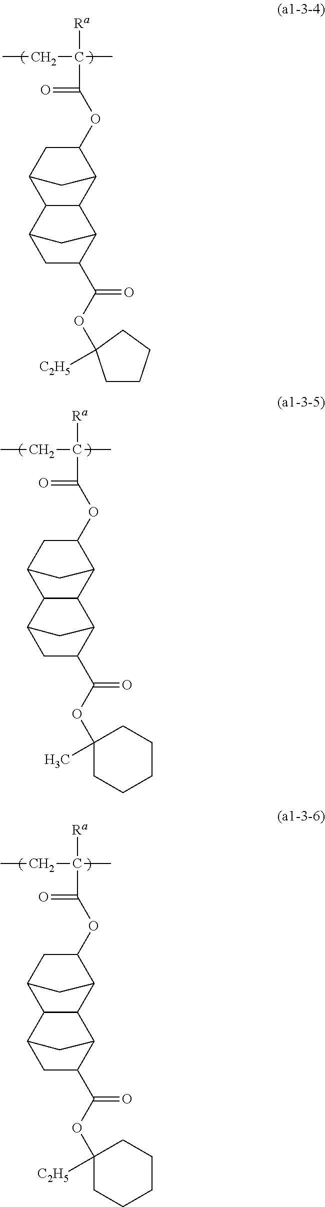

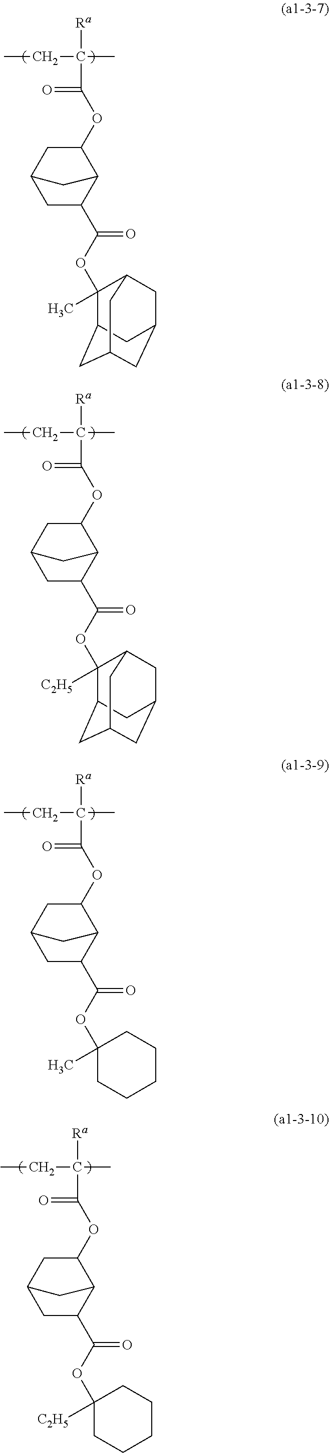

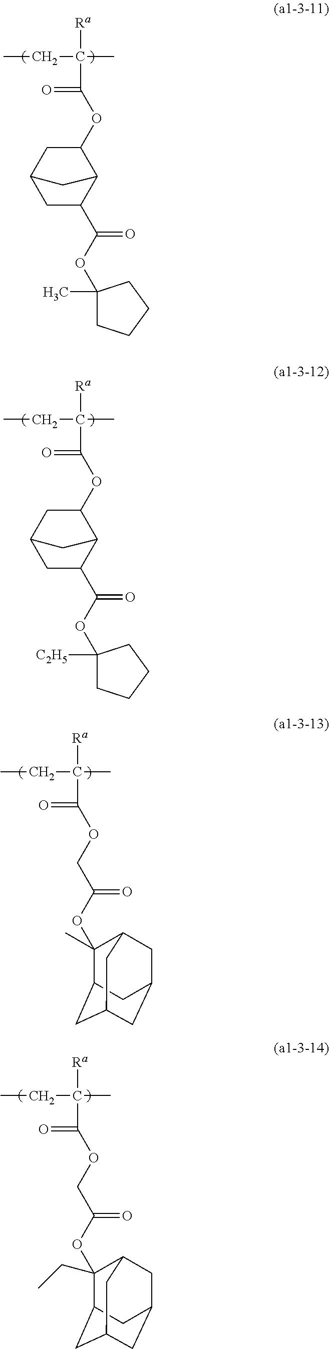

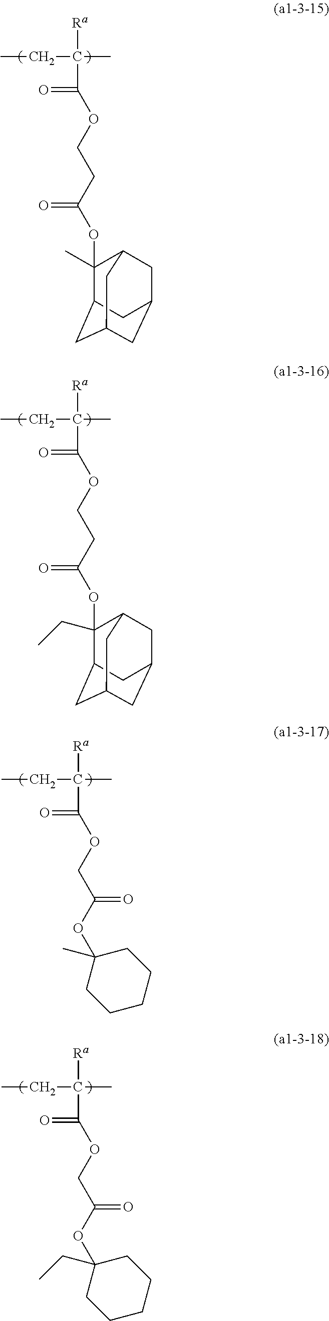

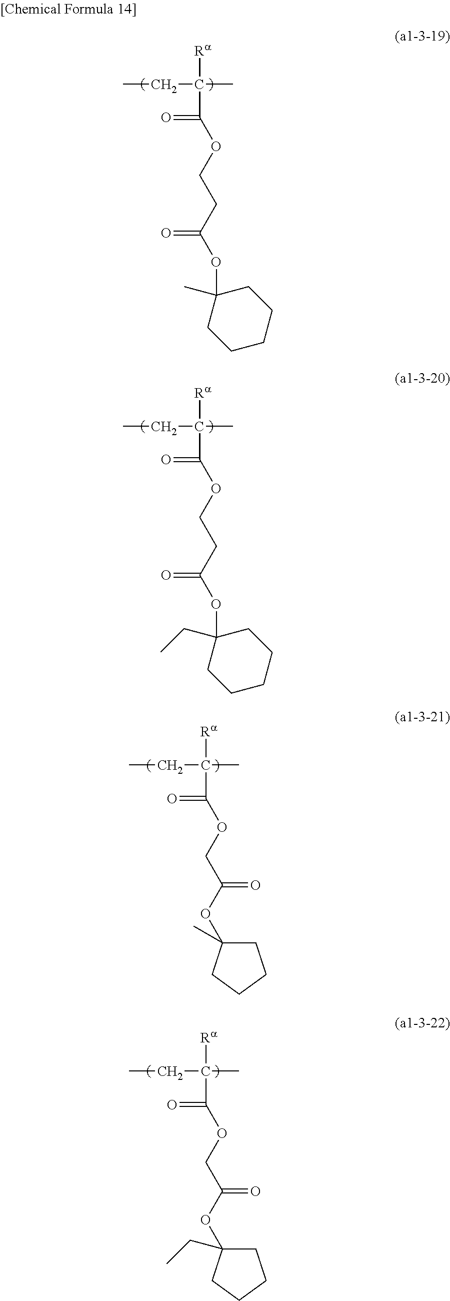

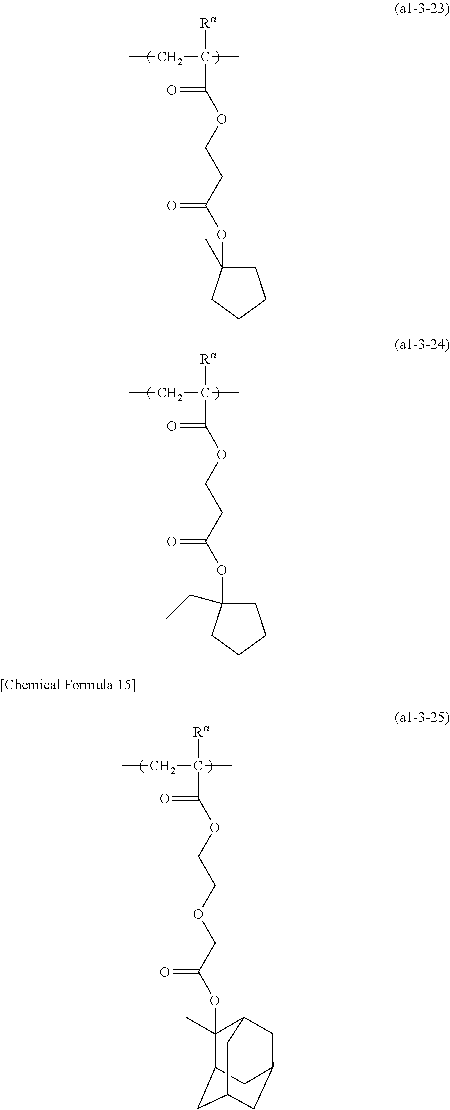

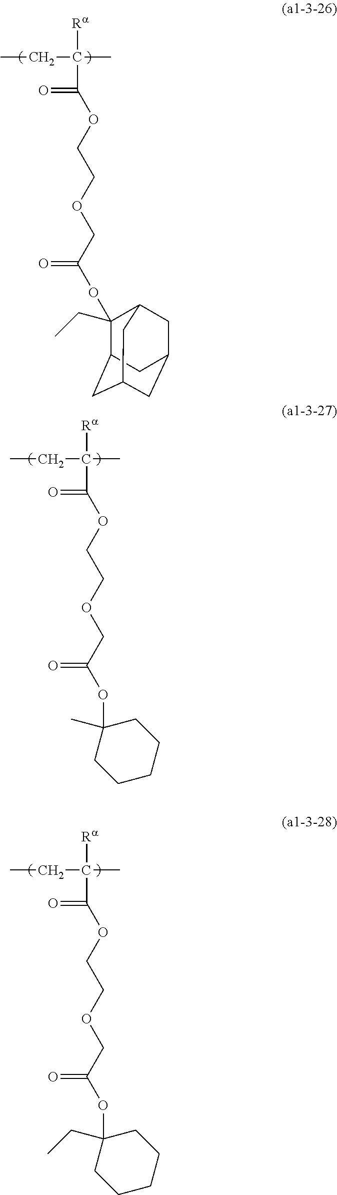

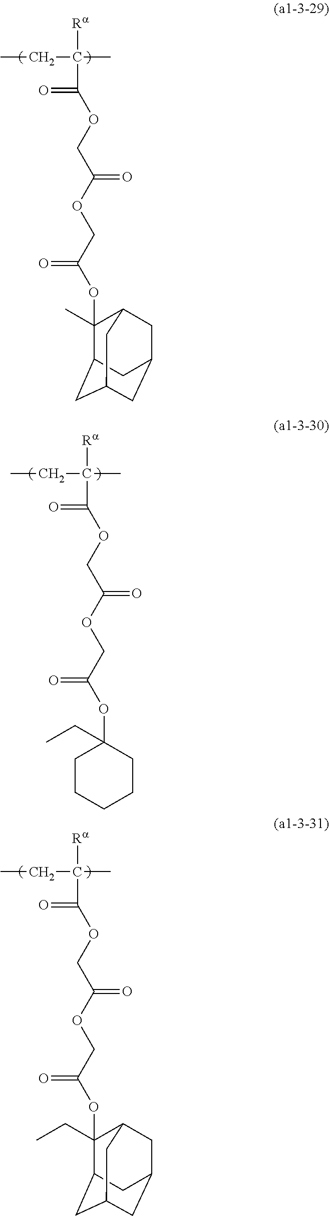

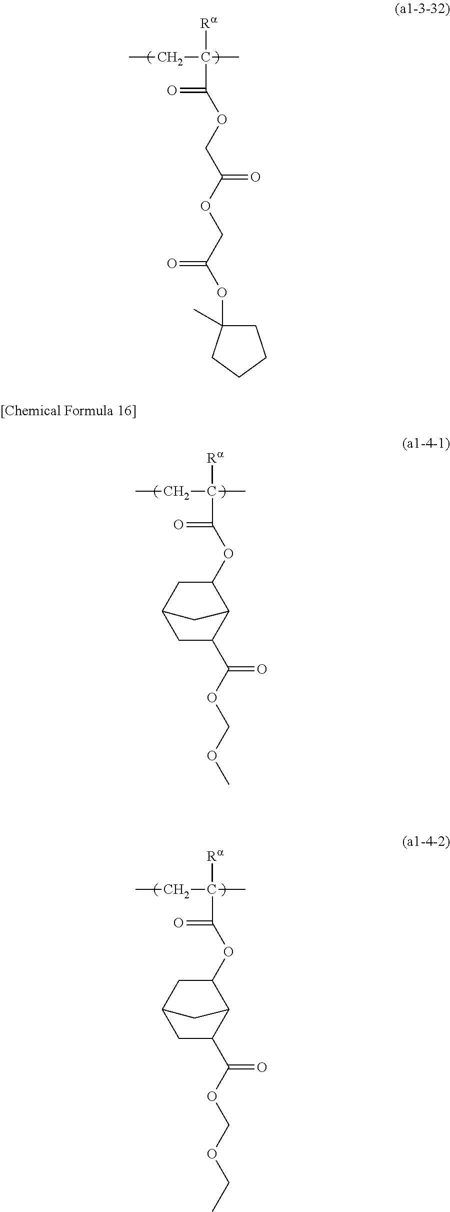

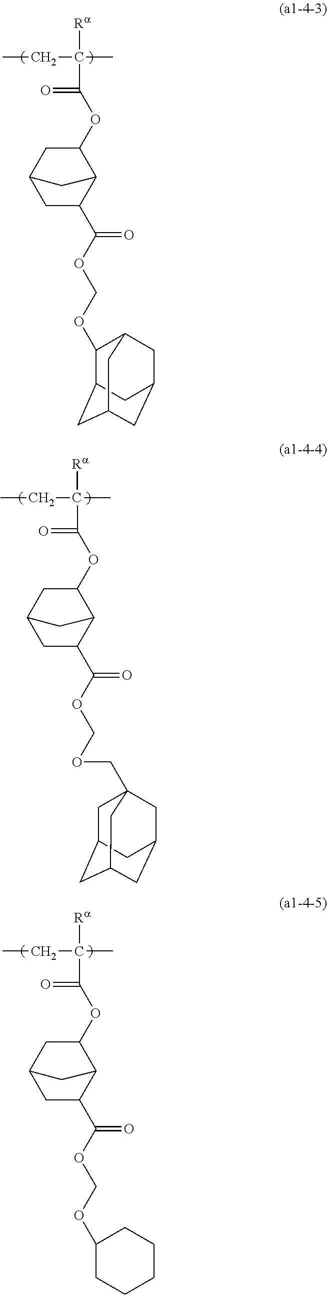

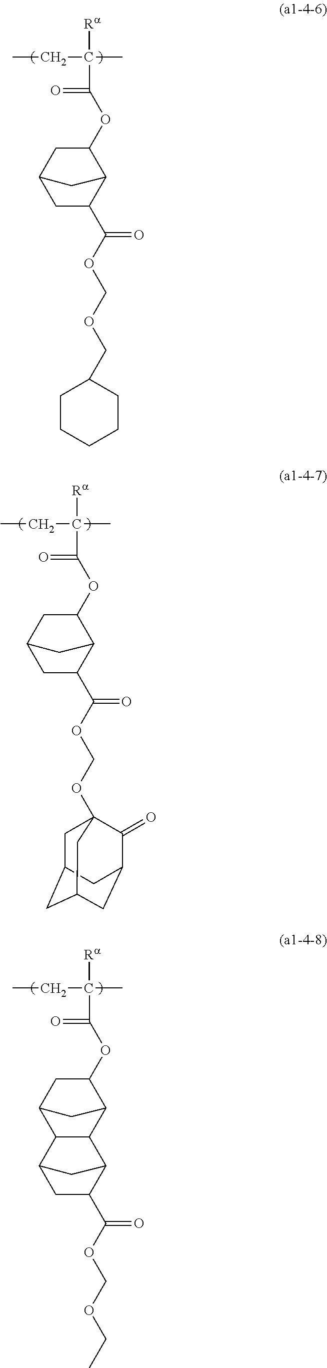

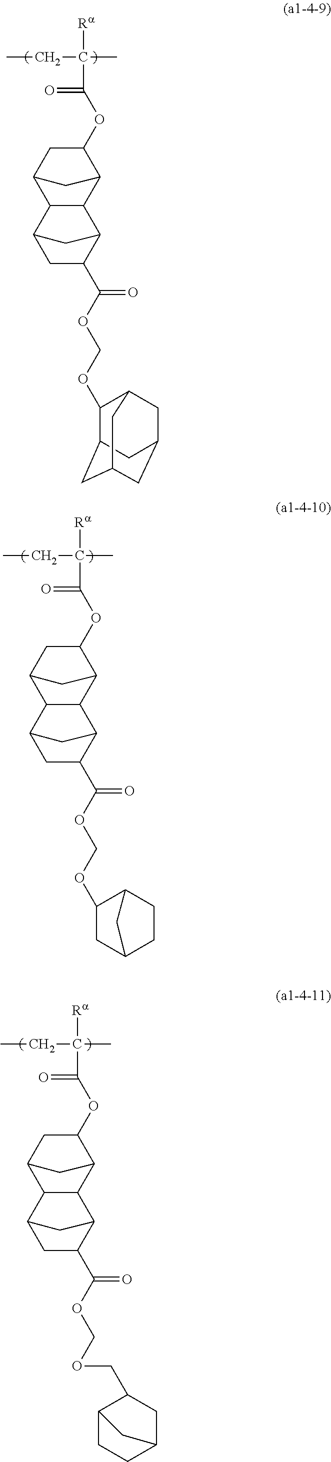

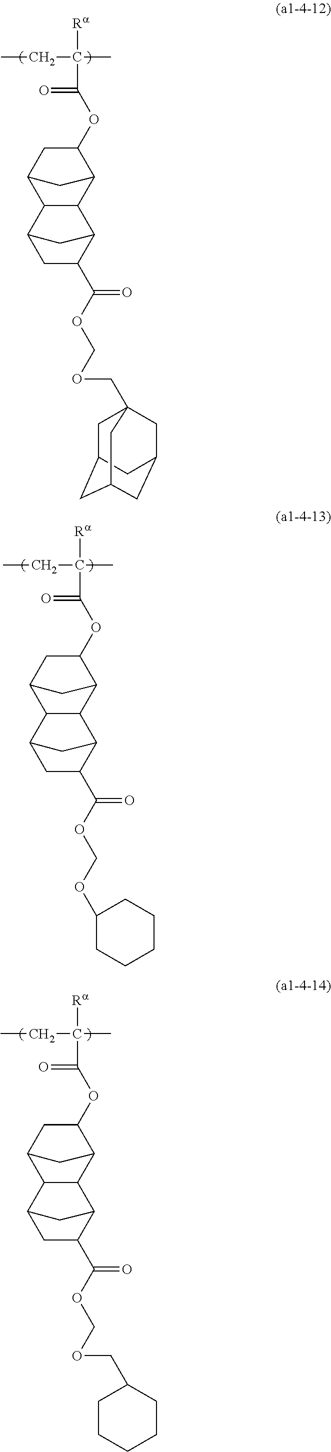

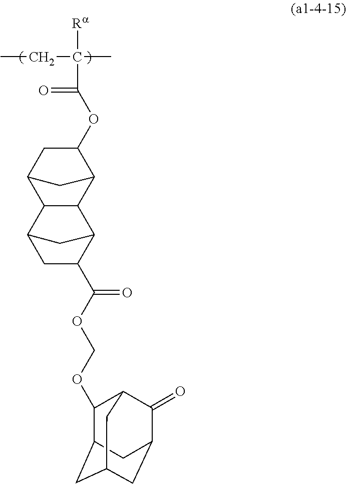

In the present invention, as the structural unit (a11), it is preferable to include at least one structural unit selected from the group consisting of a structural unit represented by general formula (a11-0-11) shown below, a structural unit represented by general formula (a11-0-12) shown below, a structural unit represented by general formula (a11-0-13) shown below, a structural unit represented by general formula (a11-0-14) shown below, a structural unit represented by general formula (a11-0-15) shown below and a structural unit represented by general formula (a11-0-2) shown below.

Among these, it is more preferable to include at least one structural unit selected from the group consisting of a structural unit represented by general formula (a11-0-11) shown below, a structural unit represented by general formula (a11-0-12) shown below, a structural unit represented by general formula (a11-0-13) shown below, a structural unit represented by general formula (a11-0-14) shown below and a structural unit represented by general formula (a11-0-15) shown below.

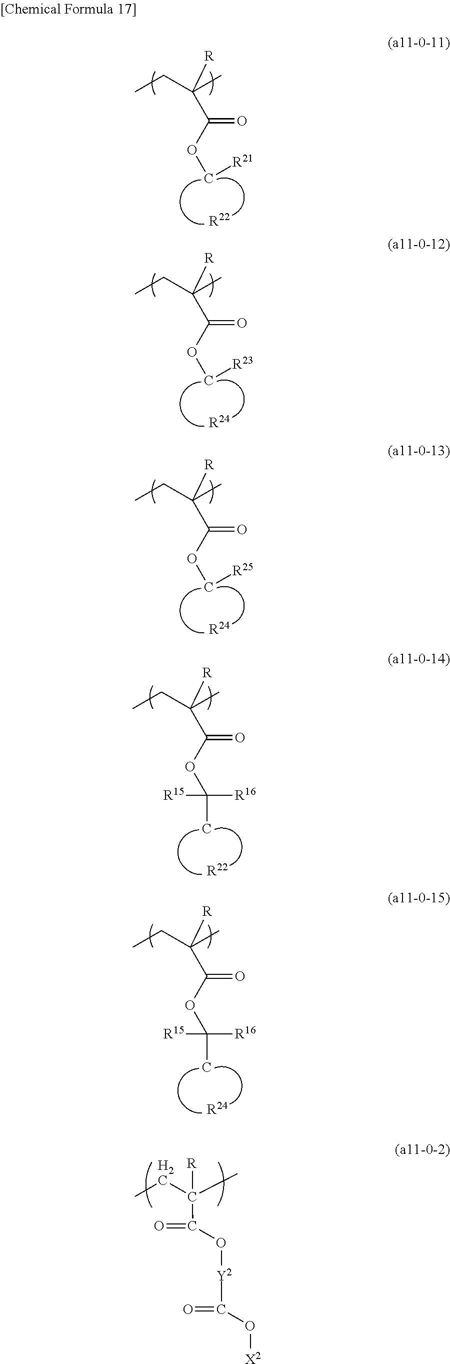

In the formulas, R represents a hydrogen atom, an alkyl group of 1 to 5 carbon atoms or a halogenated alkyl group of 1 to 5 carbon atoms; R²¹ represents an alkyl group; R²² represents a group which forms an aliphatic monocyclic group with the carbon atom to which R²² is bonded; R²³ represents a branched alkyl group; R²⁴ represents a group which forms an aliphatic polycyclic group with the carbon atom to which R²⁴ is bonded; R²⁵ represents a linear alkyl group of 1 to 5 carbon atoms; In the formulas above, each of R¹⁵ and R¹⁶ independently represents an alkyl group; Y² represents a divalent linking group; and X² represents an acid dissociable group.

In the formulas, R, Y² and X² are the same as defined above.

In general formula (a11-0-11), as the alkyl group for R²¹, the same alkyl groups as those described above for R¹⁴ in formulas (1-1) to (1-9) can be used, preferably a methyl group, an ethyl group or an isopropyl group.

As the aliphatic monocyclic group formed by R²² and the carbon atoms to which R²² is bonded, the same aliphatic cyclic groups as those described above for the aforementioned tertiary alkyl ester-type acid dissociable group and which are monocyclic can be used. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and particularly preferably a 5- or 6-membered ring.

The monocycloalkane may or may not have part of the carbon atoms constituting the ring replaced with an ether bond (—O—).

Further, the monocycloalkane may have a substituent such as an alkyl group of 1 to 5 carbon atoms, a fluorine atom or a fluorinated alkyl group of 1 to 5 carbon atoms.

As an examples of R²² constituting such an aliphatic monocyclic group, an alkylene group which may have an ether bond (—O—) interposed between the carbon atoms can be given.

Specific examples of structural units represented by general formula (a11-0-11) include structural units represented by the aforementioned formulas (a1-1-16) to (a1-1-23), (a1-1-27) and (a1-1-31). Among these, a structural unit represented by general formula (a11-1-02) shown below which includes the structural units represented by the aforementioned formulas (a1-1-16), (a1-1-17), (a1-1-20) to (a1-1-23), (a1-1-27), (a1-1-31), (a1-1-32) and (a1-1-33) is preferable. Further, a structural unit represented by general formula (a11-1-02′) shown below is also preferable.

In the formulas, h represents an integer of 1 to 4, and is preferably 1 or 2.

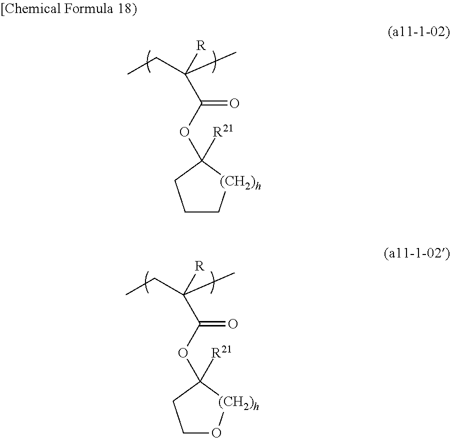

In the formulas, R and R²¹ are the same as defined above; and h represents an integer of 1 to 4.

In general formula (a11-0-12), as the branched alkyl group for R²³, the same alkyl groups as those described above for R¹⁴ in formulas (1-1) to (1-9) which are branched can be used, and an isopropyl group is particularly desirable.

As the aliphatic polycyclic group formed by R²⁴ and the carbon atoms to which R²⁴ is bonded, the same aliphatic cyclic groups as those described above for the aforementioned tertiary alkyl ester-type acid dissociable group and which are polycyclic can be used.

Specific examples of structural units represented by general formula (a11-0-12) include structural units represented by the aforementioned formulas (a1-1-26) and (a1-1-28) to (a1-1-30).

As the structural unit (a11-0-12), a structural unit in which the aliphatic polycyclic group formed by R²⁴ and the carbon atom to which R²⁴ is bonded is a 2-adamantyl group is preferable, and a structural unit represented by the aforementioned formula (a1-1-26) is particularly desirable.

In general formula (a11-0-13), R and R²⁴ are the same as defined above.

As the linear alkyl group for R²⁵, the same linear alkyl groups as those described above for R¹⁴ in the aforementioned formulas (1-1) to (1-9) can be mentioned, and a methyl group or an ethyl group is particularly desirable.

Specific examples of structural units represented by general formula (a11-0-13) include structural units represented by the aforementioned formulas (a1-1-1), (a1-1-2) and (a1-1-7) to (a1-1-15) which were described above as specific examples of the structural unit represented by general formula (a1-1).

As the structural unit (a11-0-13), a structural unit in which the aliphatic polycyclic group formed by R²⁴ and the carbon atom to which R²⁴ is bonded is a 2-adamantyl group is preferable, and a structural unit represented by the aforementioned formula (a1-1-1) or (a1-1-2) is particularly desirable.

As the aliphatic polycyclic group formed by R²⁴ and the carbon atom to which R²⁴ is bonded is preferably a group in which one or more hydrogen atoms have been removed from tetracyclododecane, and a structural unit represented by the aforementioned formulas (a1-1-8), (a1-1-9) or (a1-1-30) is also desirable.

In general formula (a11-0-14), R and R²² are the same as defined above. R¹⁵ and R¹⁶ are the same as defined for R¹⁵ and R¹⁶ in the general formulas (2-1) to (2-6).

Specific examples of structural units represented by general formula (a11-0-14) include structural units represented by the aforementioned formulas (a1-1-35) and (a1-1-36) which were described above as specific examples of the structural unit represented by general formula (a1-1).

In general formula (a11-0-15), R and R²⁴ are the same as defined above. R¹⁵ and R¹⁶ are the same as defined for R¹⁵ and R¹⁶ in the general formulas (2-1) to (2-6).

Specific examples of structural units represented by general formula (a11-0-15) include structural units represented by the aforementioned formulas (a1-1-4) to (a1-1-6) and (a1-1-34) which were described above as specific examples of the structural unit represented by general formula (a1-1).

Examples of structural units represented by general formula (a11-0-2) include structural units represented by the aforementioned formulas (a1-3) and (a1-4), and a structural unit represented by formula (a1-3) is preferable.

As a structural unit represented by general formula (a11-0-2), those in which Y² is a group represented by the aforementioned formula —Y²¹—O—Y²²— or —Y²¹—C(═O)—O—Y²²— is particularly desirable.

Preferable examples of such structural units include a structural unit represented by general formula (a1-3-01) shown below, a structural unit represented by general formula (a1-3-02) shown below, and a structural unit represented by general formula (a1-3-03) shown below.

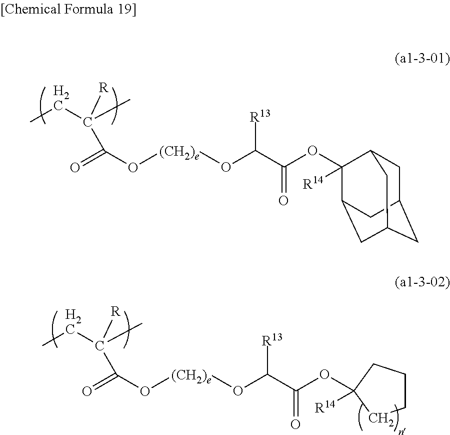

In the formulas, R is the same as defined above; R¹³ represents a hydrogen atom or a methyl group; R¹⁴ represents an alkyl group; e represents an integer of 1 to 10; and n′ represents an integer of 0 to 3.

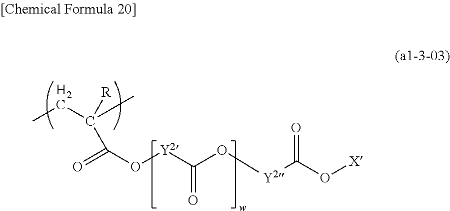

In the formula, R is as defined above; each of Y²′ and Y²″ independently represents a divalent linking group; X′ represents an acid dissociable group; and w represents an integer of 0 to 3.

In general formulas (a1-3-01) and (a1-3-02), R¹³ is preferably a hydrogen atom.

R¹⁴ is the same as defined for R¹⁴ in the aforementioned formulas (1-1) to (1-9).

e is preferably an integer of 1 to 8, more preferably 1 to 5, and most preferably 1 or 2.

n′ is preferably 1 or 2, and most preferably 2.

Specific examples of structural units represented by general formula (a1-3-01) include structural units represented by the aforementioned formulas (a1-3-25) and (a1-3-26).

Specific examples of structural units represented by general formula (a1-3-02) include structural units represented by the aforementioned formulas (a1-3-27) and (a1-3-28).

In general formula (a1-3-03), as the divalent linking group for Y²′ and Y²″, the same groups as those described above for Y² in general formula (a1-3) can be used.

As Y²′, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As Y²″, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As the acid dissociable group for X′, the same groups as those described above can be used. X′ is preferably a tertiary alkyl ester-type acid dissociable group, more preferably the aforementioned group (i) in which a substituent is bonded to the carbon atom to which an atom adjacent to the acid dissociable group is bonded to on the ring skeleton to form a tertiary carbon atom. Among these, a group represented by the aforementioned general formula (1-1) is particularly desirable.

w represents an integer of 0 to 3, preferably an integer of 0 to 2, more preferably 0 or 1, and most preferably 1.

As the structural unit represented by general formula (a1-3-03), a structural unit represented by general formula (a1-3-03-1) or (a1-3-03-2) shown below is preferable, and a structural unit represented by general formula (a1-3-03-1) is particularly desirable.

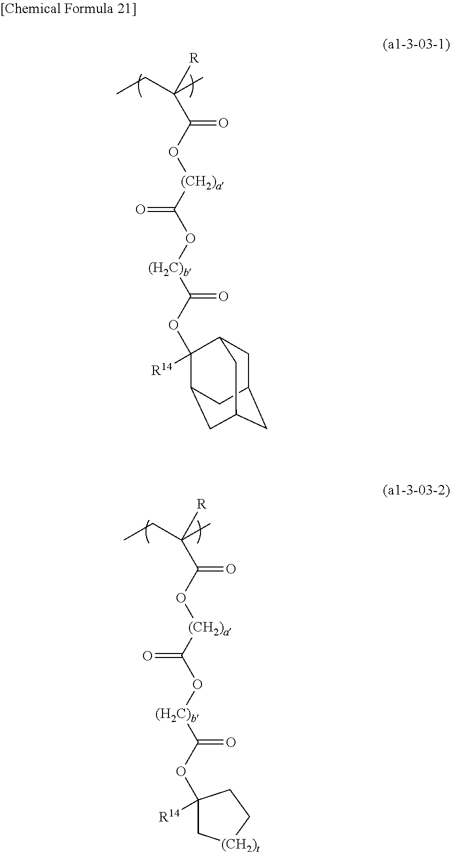

In the formulas, R and R¹⁴ are the same as defined above; a′ represents an integer of 1 to 10; b′ represents an integer of 1 to 10; and t represents an integer of 0 to 3.

In general formulas (a1-3-03-1) and (a1-3-03-2), a′ is preferably an integer of 1 to 8, more preferably 1 to 5, and particularly preferably 1 or 2.

b′ is preferably an integer of 1 to 8, more preferably 1 to 5, and particularly preferably 1 or 2.

t is preferably an integer of 1 to 3, and particularly preferably 1 or 2.

Specific examples of structural units represented by general formula (a1-3-03-1) or (a1-3-03-2) include structural units represented by the aforementioned formulas (a1-3-29) to (a1-3-32).

-Structural Unit (a12) and Structural Unit (a13)

In the present specification, the structural unit (a12) is a structural unit in which at least part of the hydrogen atoms of the hydroxy group in a structural unit derived from a hydroxystyrene or hydroxystyrene derivatives is protected with a substituent containing an acid decomposable group.

In addition, a structural unit (a13) is a structural unit in which at least part of the hydrogen atom of —C(═O)—OH in a structural unit derived from a vinylbenzoic acid or vinylbenzoic acid derivatives is protected with a substituent containing an acid decomposable group.

In the structural unit (a12) and structural unit (a13), preferable examples of the substituent containing an acid decomposable group include the aforementioned tertiary alkyl ester-type acid dissociable groups and acetal-type acid dissociable groups.

As the structural unit (a1) contained in the component (A1), 1 type of structural unit may be used, or 2 or more types may be used.

Among these, as the structural unit (a1), a structural unit (a11) derived from an acrylate ester which may have the hydrogen atom bonded to the carbon atom on the α-position substituted with a substituent is preferred.

When the component (A1) contains at least two types of structural units (a1), a combination of at least two structural units having the aforementioned tertiary alkyl ester-type acid dissociable group is preferable, more preferably (i) a combination of at least two structural units having the aforementioned group which has a tertiary carbon atom on the ring structure of a cyclic alkyl group.

In the component (A1), the amount of the structural unit (a1) based on the combined total of all structural units constituting the component (A1) is preferably 15 to 70 mol %, more preferably 15 to 60 mol %, and still more preferably 20 to 55 mol %.

When the amount of the structural unit (a1) is at least as large as the lower limit of the above-mentioned range, a pattern can be easily formed using a resist composition containing the polymer, and various lithography properties such as sensitivity, resolution, LWR and the like are improved. On the other hand, when the amount of the structural unit (a1) is no more than the upper limit of the above-mentioned range, a good balance can be achieved with the other structural units.

(Structural Unit (a0))

The structural unit (a0) is a structural unit containing —SO₂-containing cyclic group.

By virtue of using the resist composition containing the component (A1) including structural unit (a0), the resist composition is capable of improving the adhesion of a resist film to a substrate. Further, the structural unit (a0) contributes to improvement in various lithography properties such as sensitivity, resolution, exposure latitude (EL margin), line width roughness (LWR), line edge roughness (LER) and mask reproducibility.

Here, an “—SO₂— containing cyclic group” refers to a cyclic group having a ring containing —SO₂— within the ring skelton thereof, i.e., a cyclic group in which the sulfur atom (S) within —SO₂— forms part of the ring skeleton of the cyclic group.

In the —SO₂— containing cyclic group, the ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings.

The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S-within the —O—SO₂— group forms part of the ring skeleton thereof is particularly desirable.

The —SO₂— containing cyclic group preferably has 3 to 30 carbon atoms, more preferably 4 to 20, still more preferably 4 to 15, and particularly preferably 4 to 12. Herein, the number of carbon atoms refers to the number of carbon atoms constituting the ring skeleton, excluding the number of carbon atoms within a substituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton has been substituted with a —O—SO₂— group and has at least one hydrogen atom removed therefrom.

The alicyclic hydrocarbon group preferably has 3 to 20 carbon atoms, and more preferably 3 to 12 carbon atoms.

The alicyclic hydrocarbon group may be either a monocyclic group or a polycyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of the substituent include an alkyl group, an alkoxy group, a halogen atom, a halogenated alkyl group, a hydroxy group, an oxygen atom (═O), —OC(═O)R″, a hydroxyalkyl group and a cyano group (wherein R″ represents a hydrogen atom or an alkyl group).

The alkyl group for the substituent is preferably an alkyl group of 1 to 6 carbon atoms. Further, the alkyl group is preferably a linear alkyl group or a branched alkyl group. Specific examples include a methyl group, ethyl group, propyl group, isopropyl group, n-butyl group, isobutyl group, tert-butyl group, pentyl group, isopentyl group, neopentyl group and hexyl group. Among these, a methyl group or ethyl group is preferable, and a methyl group is particularly desirable.

As the alkoxy group for the substituent, an alkoxy group of 1 to 6 carbon atoms is preferable. Further, the alkoxy group is preferably a linear alkoxy group or a branched alkoxyl group. Specific examples of the alkoxy groups include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

As examples of the halogenated alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ preferably represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxy group.

More specific examples of the —SO₂— containing cyclic group include groups represented by general formulas (3-1) to (3-4) shown below.

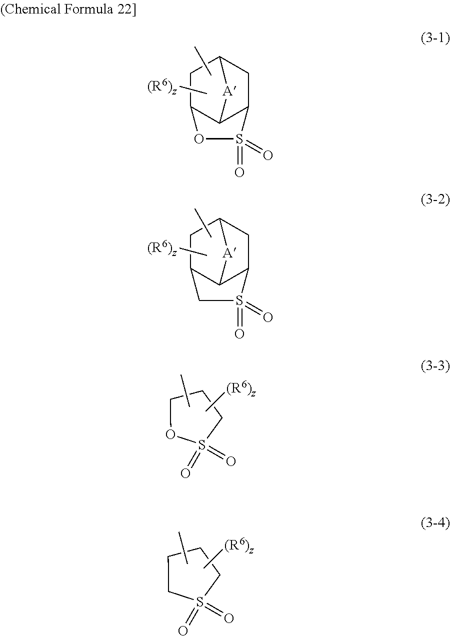

In the formulas, A′ represents an oxygen atom, a sulfur atom or an alkylene group of 1 to 5 carbon atoms which may contain an oxygen atom or a sulfur atom; z represents an integer of 0 to 2; and R⁶ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms for A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or interposed within the alkylene group. Specific examples of such alkylene groups include —O—CH₂—, —CH₂—O—CH₂—, —S—CH₂— and —CH₂—S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

If there are two or more of the R⁶ group, as indicated by the value z, then the two or more of the R₆ group may be the same or different from each other.

As the alkyl group, alkoxy group, halogenated alkyl group, —COOR″, —OC(═O)R″ and hydroxyalkyl group for R⁶, the same alkyl groups, alkoxy groups, halogenated alkyl groups, —COOR″, —OC(═O)R″ and hydroxyalkyl groups as those described above as the substituent for the —SO₂— containing cyclic group can be mentioned.

Specific examples of the cyclic groups represented by general formulas (3-1) to (3-4) are shown below. In the formulas shown below, “Ac” represents an acetyl group.

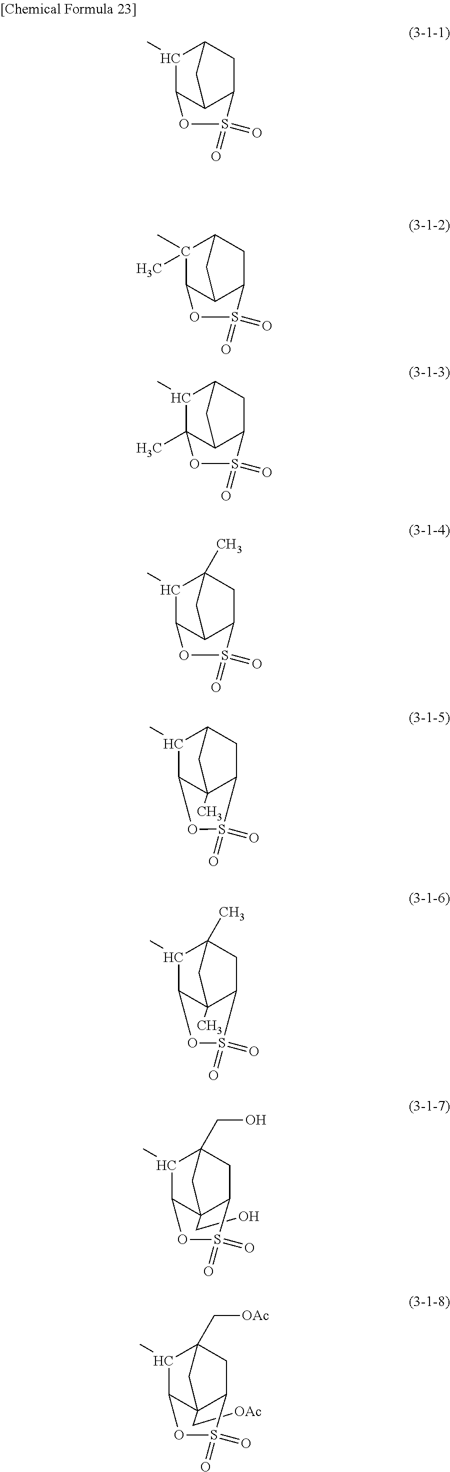

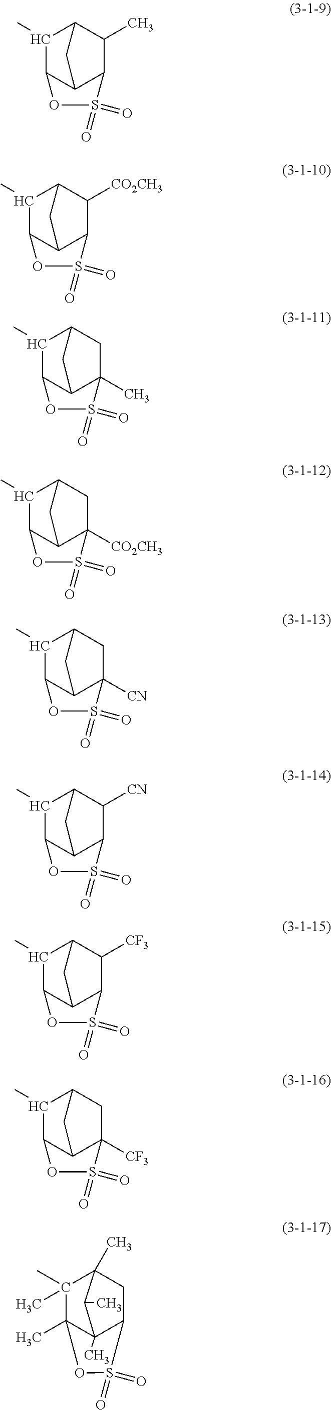

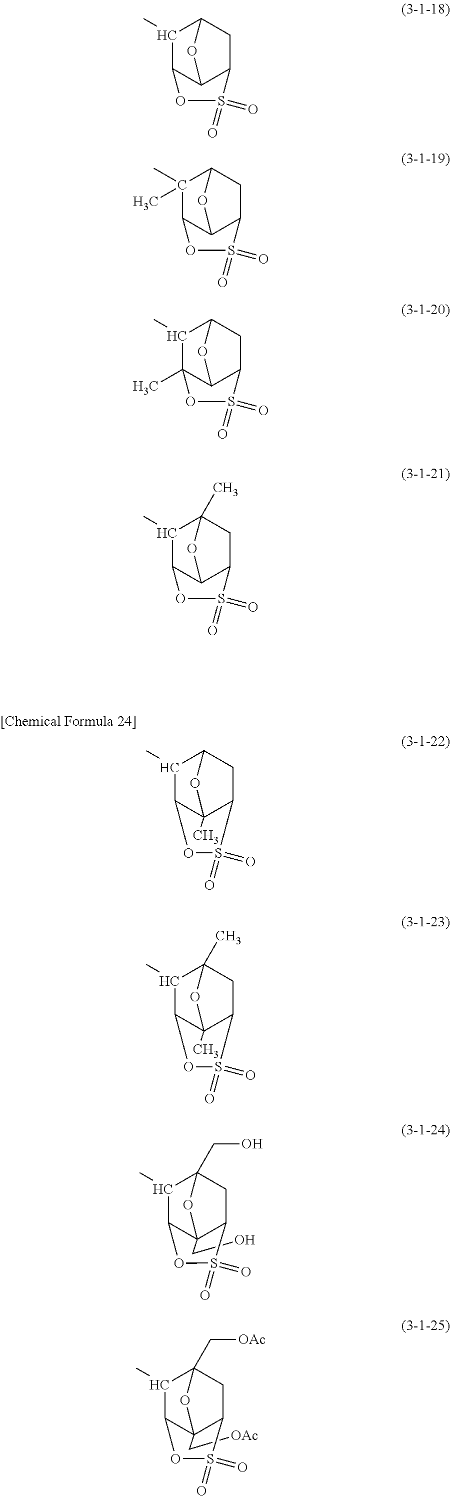

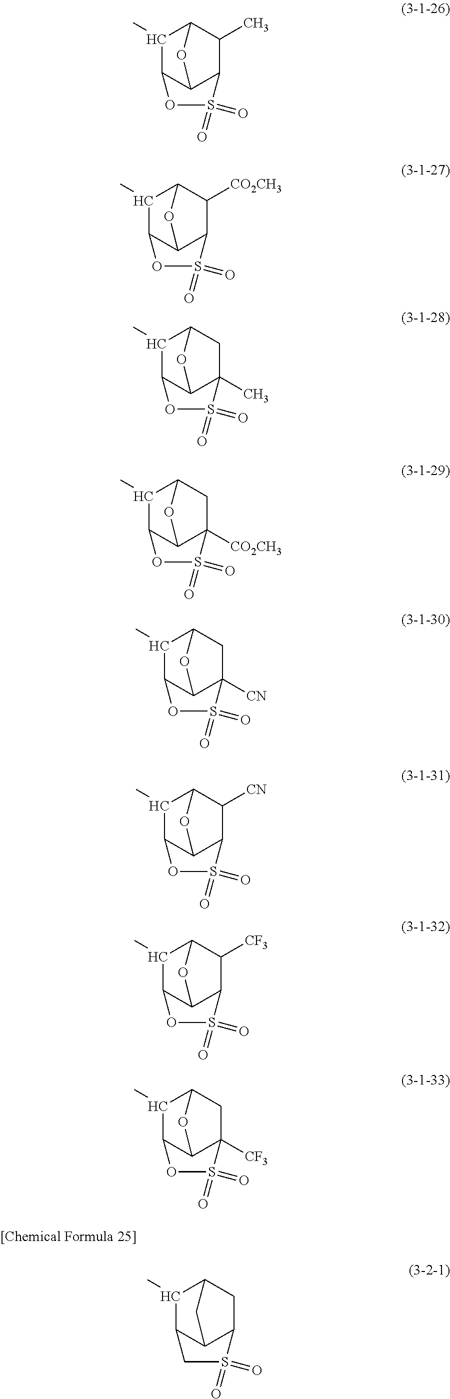

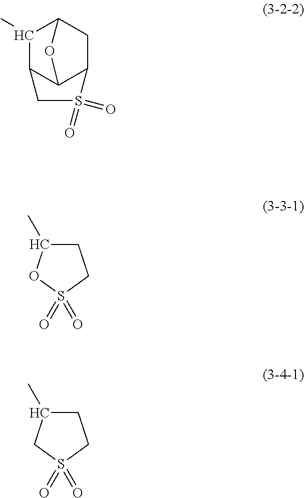

As the —SO₂— containing cyclic group, a group represented by the aforementioned general formula (3-1) is preferable, at least one member selected from the group consisting of groups represented by the aforementioned chemical formulas (3-1-1), (3-1-18), (3-3-1) and (3-4-1) is more preferable, and a group represented by chemical formula (3-1-1) is most preferable.

The structural unit (a0) is a structural unit derived from an acrylate ester and may have the hydrogen atom bonded to the carbon atom on the α-position substituted with a substituent.

More specifically, examples of the structural unit (a0) include structural units represented by general formula (a0-0) shown below.

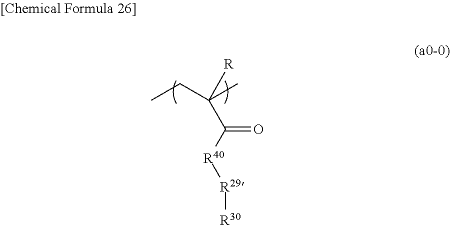

In the formula, R represents a hydrogen atom, an alkyl group of 1 to 5 carbon atoms or a halogenated alkyl group of 1 to 5 carbon atoms; R⁴⁰ represents —O— or —NH—; R³⁰ represents a —SO₂— containing cyclic group; and R²⁹′ represents a single bond or a divalent linking group.

As the alkyl group for R in the formula (a0-0), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In the formula (a0-0), R⁴⁰ represents —O— or —NH—.

In formula (a0-0), R³⁰ is the same those as defined for the aforementioned —SO₂-containing group.

In the formula (a0-0), R²⁹′ may be a single bond or a divalent linking group. R²⁹′ is preferably a divalent linking group, because it results in improved lithographic properties.

As preferable examples of the divalent linking group for R²⁹′, a divalent hydrocarbon group which may have a substituent, and a divalent linking group containing a hetero atom can be given.

As examples of the divalent hydrocarbon group for R²⁹′, the same groups as those described above for the divalent hydrocarbon group which may have a substituent and the divalent linking group containing a hetero atom in relation to Y² in general formula (a11-0-2) can be given.

As the divalent linkage group for R²⁹′, an alkylene group, a divalent aliphatic hydrocarbon group or a divalent linkage group containing a hetero atom is preferable. Among these, an alkylene group or a divalent linking group containing an ester bond (—C(═O)—O—) is preferable.

As the alkylene group, a linear or branched alkylene group is preferable.

As the divalent linking group containing an ester bond, a group represented by general formula: —R²⁰—C(═O)—O— (in the formula, R²⁰ represents a divalent linking group) is particularly desirable. Namely, the structural unit (a0) is preferably a structural unit represented by general formula (a0-0-1) shown below.

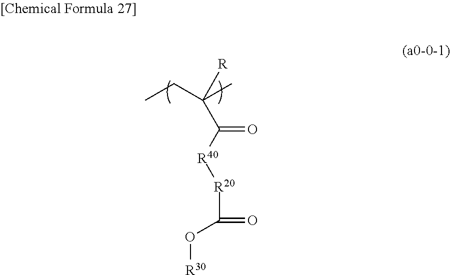

In the formula, R represents a hydrogen atom, an alkyl group of 1 to 5 carbon atoms or a halogenated alkyl group of 1 to 5 carbon atoms; R⁴⁰ represents —O— or —NH—; R²⁰ represents a divalent linking group; and R³⁰ represents an —SO₂— containing cyclic group.

R²⁰ is not particularly limited. For example, the same divalent linking groups as those described for R²⁹′ in general formula (a0-0) can be mentioned.

As the divalent linking group for R²⁰, a linear or branched alkylene group, a divalent alicyclic hydrocarbon group or a divalent linking group containing a hetero atom is preferable.

As the linear or branched alkylene group, the divalent alicyclic hydrocarbon group and the divalent linking group containing a hetero atom, the same linear or branched alkylene group, divalent alicyclic hydrocarbon group and divalent linking group containing a hetero atom as those described above as preferable examples of R²⁹′ can be mentioned.

Among these, a linear or branched alkylene group, or a divalent linking group containing an oxygen atom as a hetero atom is more preferable.

As the linear alkylene group, a methylene group or an ethylene group is preferable, and a methylene group is particularly desirable.

As the branched alkylene group, an alkylmethylene group or an alkylethylene group is preferable, and —CH(CH₃)—, —C(CH₃)₂— or —C(CH₃)₂CH₂— is particularly desirable.

As the divalent linking group containing a hetero atom, a divalent linking group containing an ether bond or an ester bond is preferable, and a group represented by the aforementioned formulas —Y²¹—O—Y²²—, —[Y²¹—C(═O)—O]_{m′}—Y²²— or a group represented by the aforementioned formulas —Y²¹—O—C(═O)—Y²²— is more preferable. Y²¹, Y²² and m′ the same those as defined above.

Among these, a group represented by the formula —Y²¹—O—C(═O)—Y²²— is preferable, a group represented by the formula —(CH₂)_{c}—O—C(═O)—(CH₂)_{d}— is particularly desirable. c represents an integer of 1 to 5, and is preferably an integer of 1 to 3, and more preferably an integer of 1 or 2. d represents an integer of 1 to 5, and is preferably an integer of 1 to 3, and more preferably an integer of 1 or 2.

In particular, as the structural unit (a0), a structural unit represented by general formula (a0-0-11) or (a0-0-12) shown below is preferable, and a structural unit represented by general formula (a0-0-12) is more preferable.

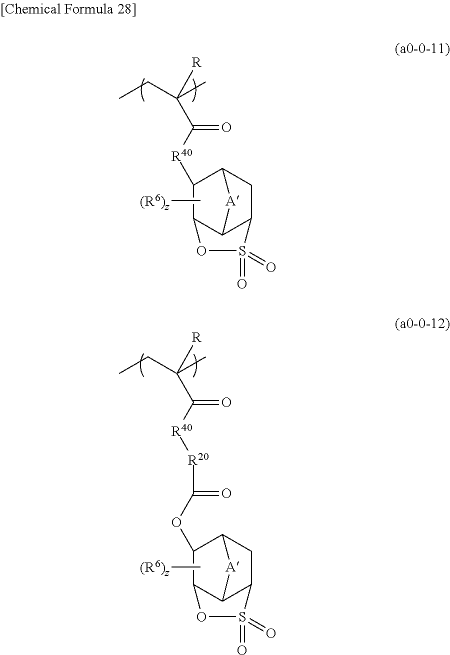

In the formulas, R represents a hydrogen atom, an alkyl group of 1 to 5 carbon atoms, or a halogenated alkyl group of 1 to 5 carbon atoms; R⁴⁰ represents —O— or —NH—; R²⁰ a divalent linking group; A′ represents an oxygen atom, a sulfur atom or an alkylene group of 1 to 5 carbon atoms which may contain an oxygen atom or a sulfur atom; z represents an integer of 0 to 2; and R⁶ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (a0-0-11) and (a0-0-12), R, R⁴⁰, A′, R⁶, z and R²⁰ are the same those as defined above.

In general formula, A′ is preferably a methylene group, an ethylene group, an oxygen atom (—O—) or a sulfur atom (—S—).

As R²⁰ a linear or branched alkylene group or a divalent linking group containing an oxygen atom is preferable. As the linear or branched alkylene group and the divalent linking group containing an oxygen atom represented by R²⁰, the same linear or branched alkylene groups and the divalent linking groups containing an oxygen atom as those described above can be mentioned.

As the structural unit represented by general formula (a0-0-12), a structural unit represented by general formula (a0-0-12a) or (a0-0-12b) shown below is particularly desirable.

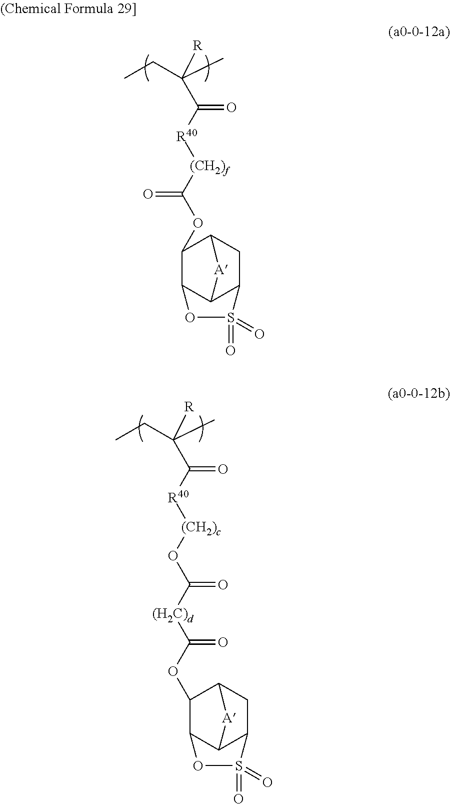

In the formulas, R, R⁴⁰ and A′ are the same as defined above; each of c and d is the same those as defined above; and f represents an integer of 1 to 5 (preferably an integer of 1 to 3).

In the case that the structural unit (a0) is contained in the component (A1) 1 type of structural unit (a0) may be used, or 2 or more types may be used.

In the component (A1), the amount of the structural unit (a0) based on the combined total of all structural units constituting the component (A1) is preferably 1 to 60 mol %, more preferably 5 to 55 mol %, still more preferably 10 to 50 mol %, and most preferably 15 to 48 mol %.

When the amount of the structural unit (a0) is no less than the lower limit of the above-mentioned range, a resist pattern formed using a resist composition containing the component (A1) has an excellent shape, and lithography properties such as EL margin, LWR and mask reproducibility can be improved. On the other hand, when the amount of the structural unit (a0) is no more than the upper limit of the above-mentioned range, in the case of using the other structural units, a good balance can be achieved with them.

(Structural Unit (a2))

The structural unit (a2) is a structural unit containing a lactone-containing cyclic group.

The term “lactone-containing cyclic group” refers to a cyclic group including a ring containing a —O—C(═O)— structure (lactone ring). The term “lactone ring” refers to a single ring containing a —O—C(═O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for the structural unit (a2) is not particularly limited, and an arbitrary structural unit may be used. Specific examples of lactone-containing monocyclic groups include a group in which one hydrogen atom has been removed from a 4- to 6-membered lactone ring, such as a group in which one hydrogen atom has been removed from β-propionolatone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

As the structural unit (a2), a structural unit derived from an acrylate ester which may have the hydrogen atom bonded to the carbon atom on the α-position substituted with a substituent is preferred. Examples of the structural unit (a2) include structural units represented by the aforementioned general formula (a0-0) in which the R³⁰ group has been substituted with a lactone-containing cyclic group. Specific examples include structural units represented by general formulas (a2-1) to (a2-5) shown below.

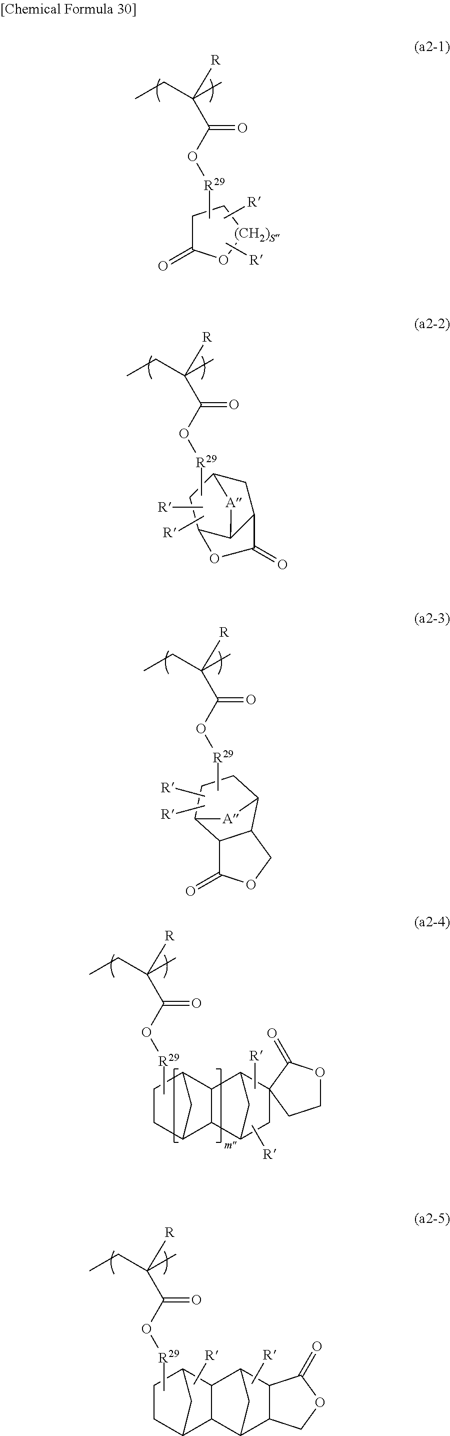

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m″ represents 0 or 1.

In general formulas (a2-1) to (a2-5), R is the same as defined above.

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group.

In terms of industrial availability, R′ is preferably a hydrogen atom.

The alkyl group for R″ may be any of linear, branched or cyclic.

When R″ is a linear or branched alkyl group, it preferably has 1 to 10 carbon atoms, more preferably 1 to 5 carbon atoms.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As examples of A″, the same groups as those described above for A′ in general formula (3-1) can be given. A″ is preferably an alkylene group of 1 to 5 carbon atoms, an oxygen atom (—O—) or a sulfur atom (—S—), and more preferably an alkylene group of 1 to 5 carbon atoms or —O—. As the alkylene group of 1 to 5 carbon atoms, a methylene group or a dimethylethylene group is preferable, and a methylene group is particularly desirable.

R²⁹ is the same as defined for R²⁹′ in the aforementioned general formula (a0-0).

In formula (a2-1), s″ is preferably 1 or 2.

Specific examples of structural units represented by general formulas (a2-1) to (a2-5) are shown below. In the formulas shown below, R^{α} represents a hydrogen atom, a methyl group or a trifluoromethyl group.

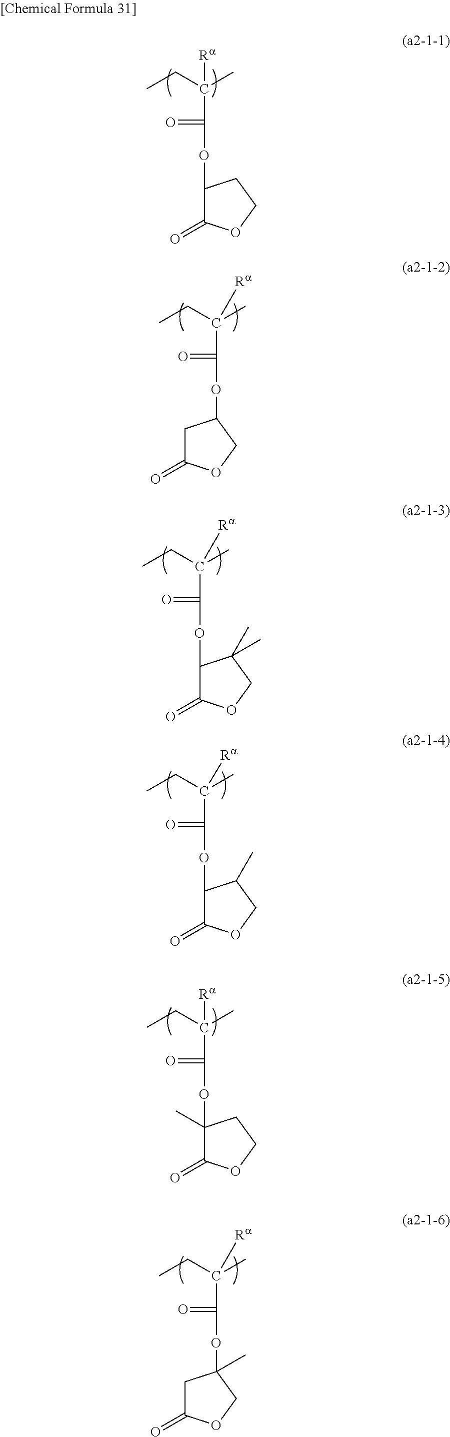

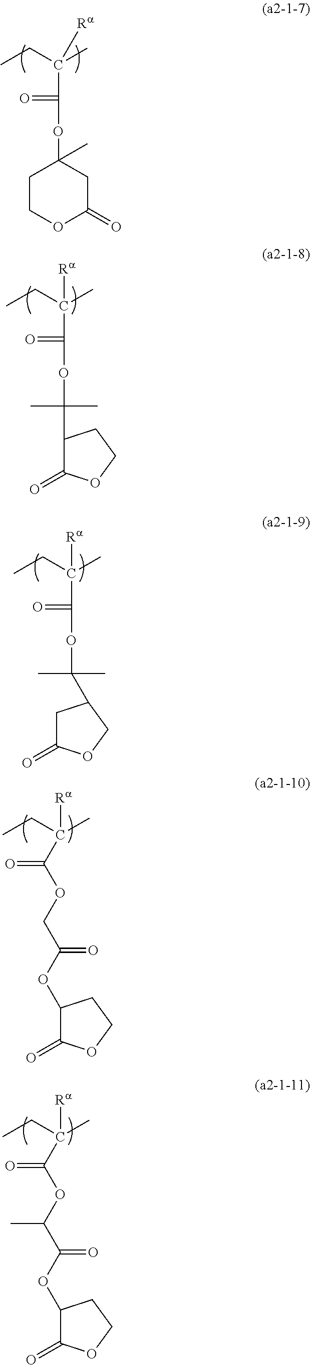

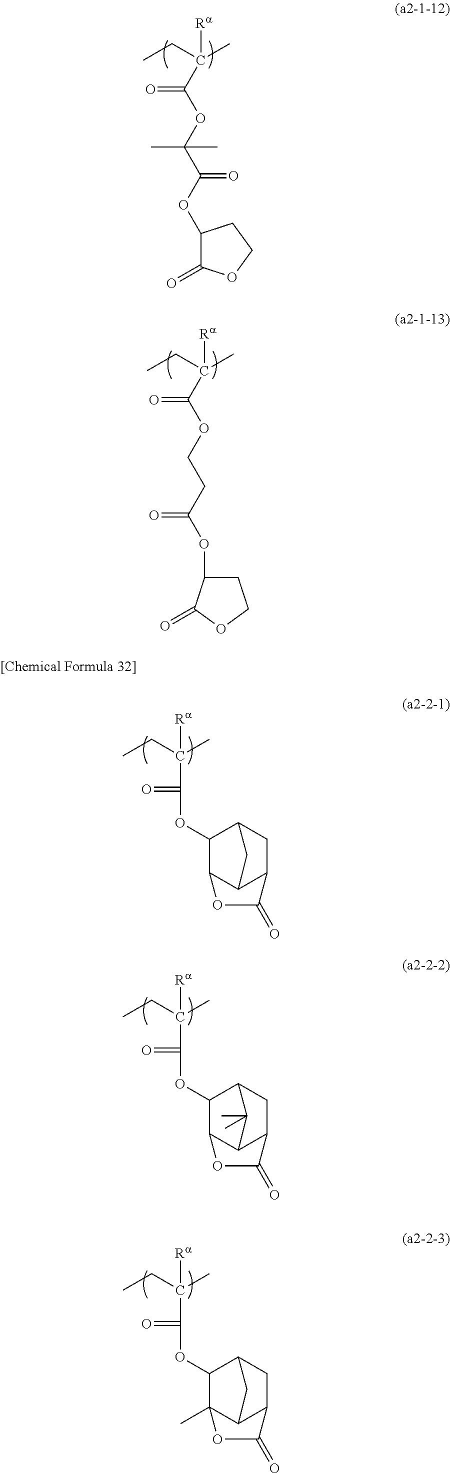

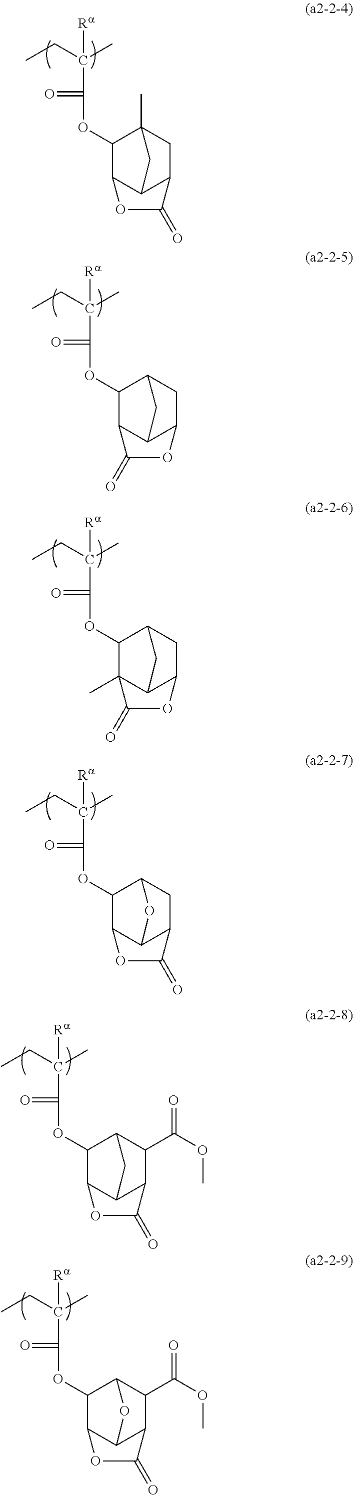

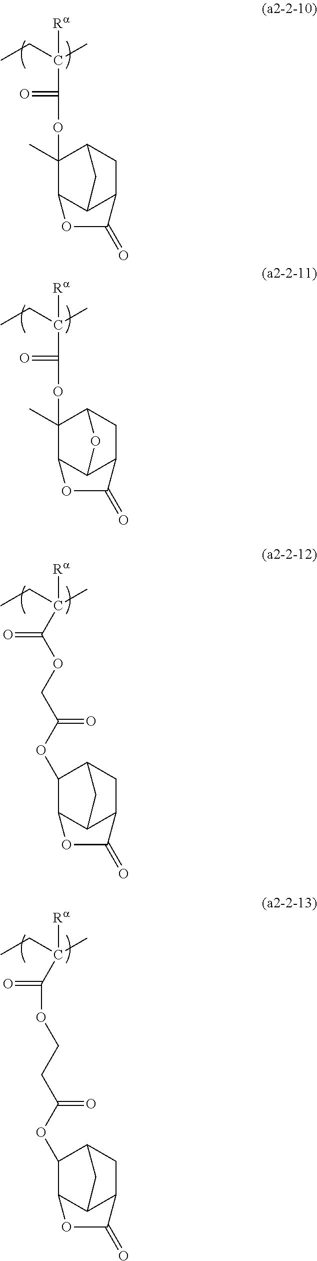

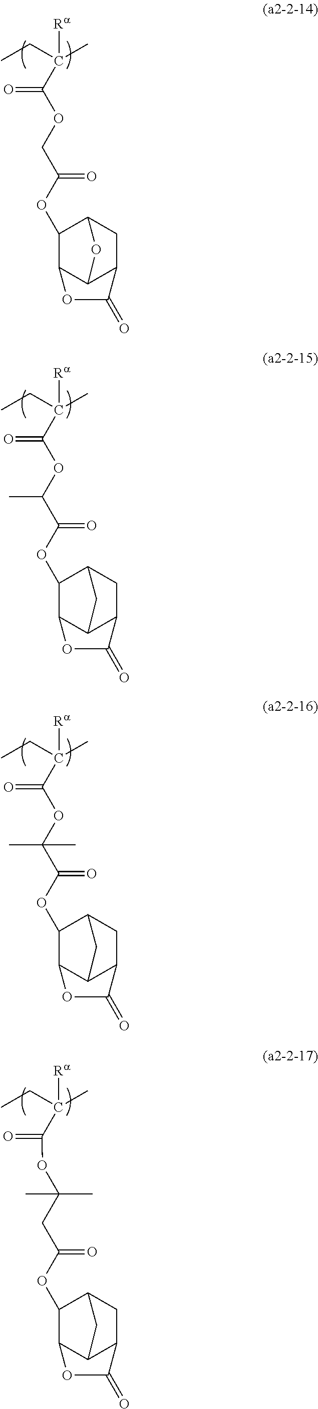

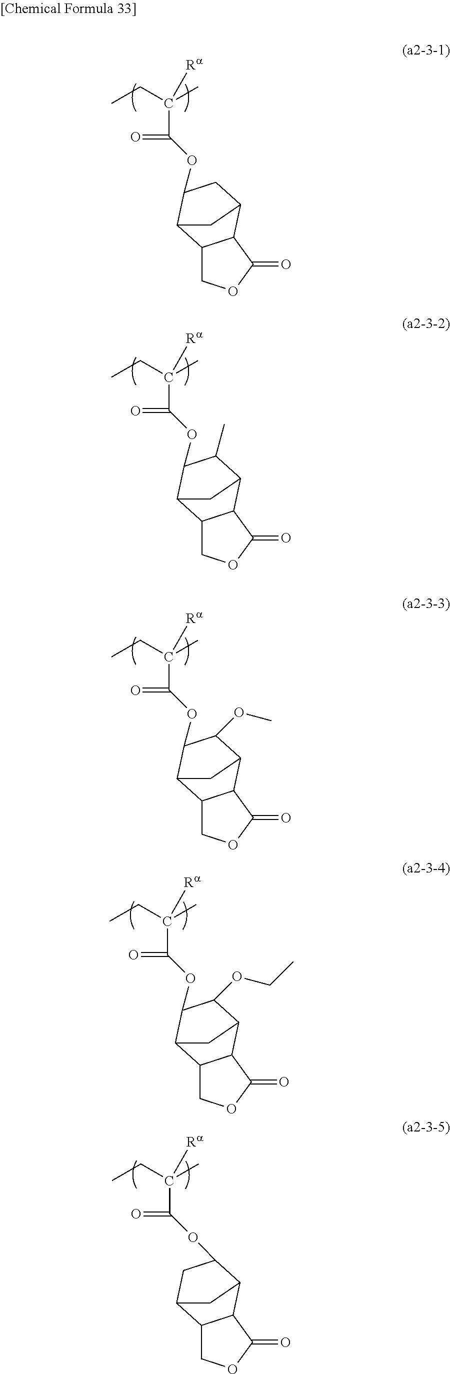

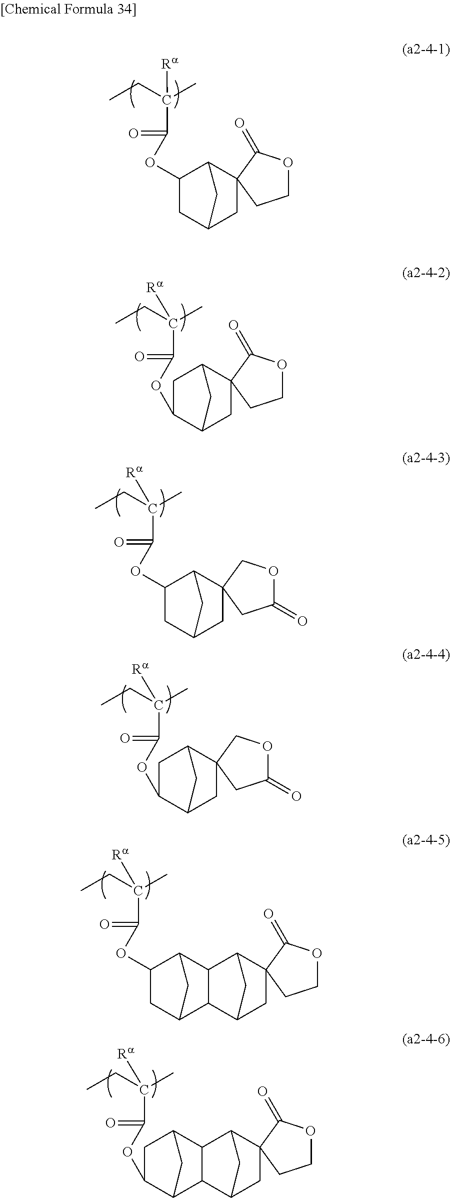

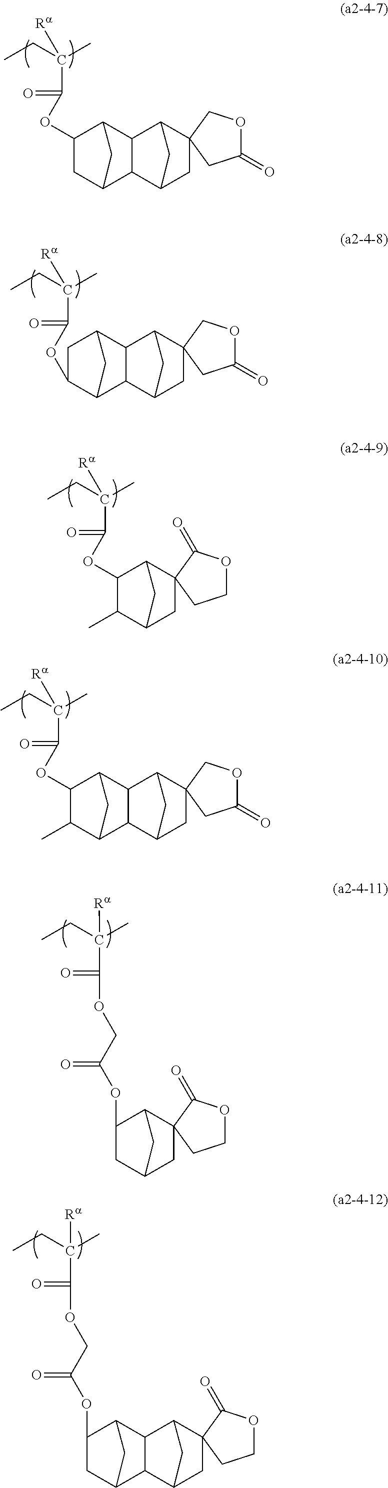

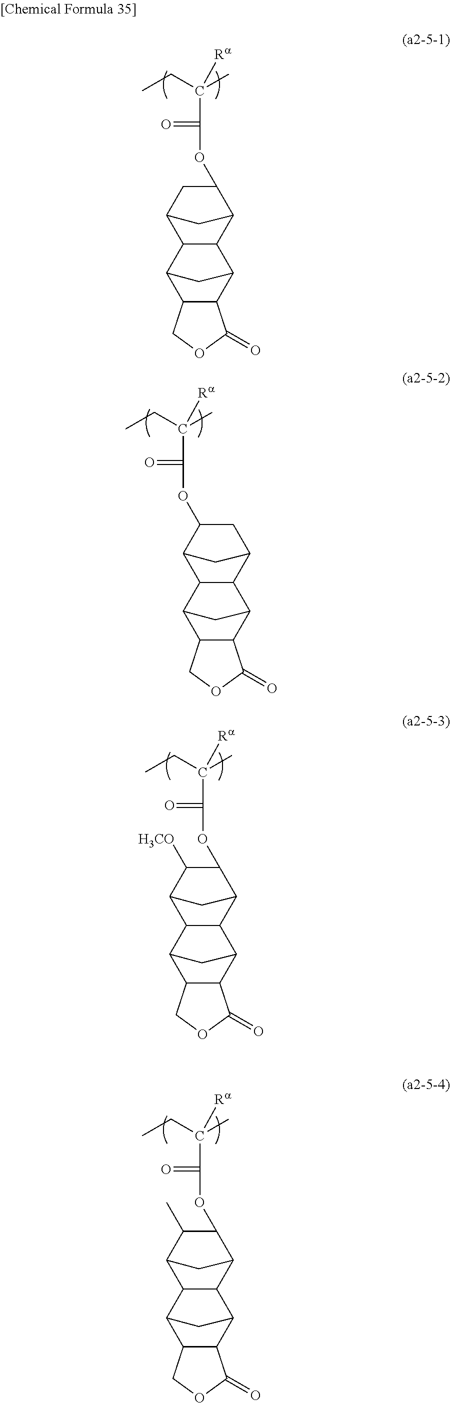

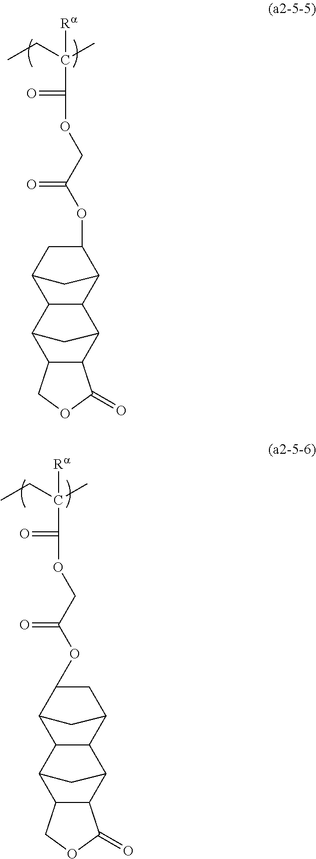

As the structural unit (a2), it is preferable to include at least one structural unit selected from the group consisting of structural units represented by the aforementioned general formulas (a2-1) to (a2-5), more preferably at least one structural unit selected from the group consisting of structural units represented by the aforementioned general formulas (a2-1) to (a2-3), and particularly preferably at least one structural unit selected from the group consisting of structural units represented by the aforementioned general formulas (a2-1) and (a2-3).

Specifically, it is preferable to use at least one structural unit selected from the group consisting of formulas (a2-1-1), (a2-1-2), (a2-2-1), (a2-2-7), (a2-2-12), (a2-2-14), (a2-3-1) and (a2-3-5).

Furthermore, as the structural unit (a2), structural units represented by general formulas (a2-6) and (a2-7) are also preferable.

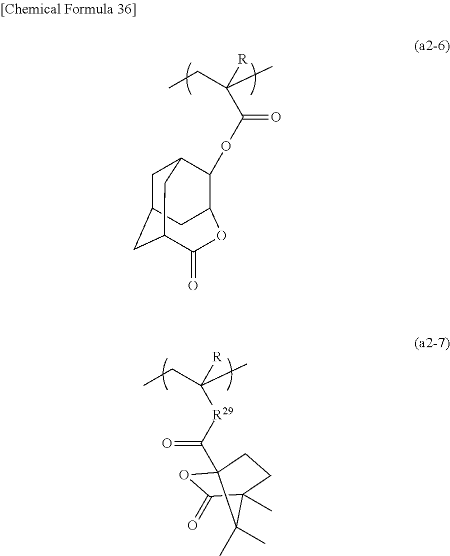

In the formula, R²⁹ is the same as those defined above.

In the case that the structural unit (a2) is contained in the component (A1), 1 type of structural unit (a2) may be used, or 2 or more types may be used.

In the component (A1), the amount of the structural unit (a2) based on the combined total of all structural units constituting the component (A1) is preferably 1 to 80 mol %, more preferably 10 to 70 mol %, still more preferably 10 to 65 mol %, and particularly preferably 10 to 60 mol %.

When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as EL margin, LWR, mask reproducibility, DOF and CDU and pattern shape can be improved.

(Structural Unit (a3))

The structural unit (a3) is a structural unit derived from an acrylate ester which may have the hydrogen atom bonded to the carbon atom on the α-position substituted with a substituent and contains a polar group-containing aliphatic hydrocarbon group (provided that, the structural unit (a3) excludes the aforementioned structural units (a1), (a0) and (a2)).

By virtue of the resist composition containing the polymer including the structural unit (a3), the hydrophilicity of the polymer is enhanced, thereby improving in resolution.

Examples of the polar group include a hydroxyl group, cyano group, carboxyl group, or hydroxyalkyl group in which part of the hydrogen atoms of the alkyl group have been substituted with fluorine atoms, although a hydroxyl group is particularly desirable.

Examples of the aliphatic hydrocarbon group include linear or branched hydrocarbon groups (preferably alkylene groups) of 1 to 10 carbon atoms, and cyclic aliphatic hydrocarbon groups (cyclic groups). These cyclic groups can be selected appropriately from the multitude of groups that have been proposed for the resins of resist compositions designed for use with ArF excimer lasers. The cyclic group is preferably a polycyclic group, more preferably a polycyclic group of 7 to 30 carbon atoms.

Of the various possibilities, structural units derived from an acrylate ester that include an aliphatic polycyclic group that contains a hydroxyl group, cyano group, carboxyl group or a hydroxyalkyl group in which part of the hydrogen atoms of the alkyl group have been substituted with fluorine atoms are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the aliphatic hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid. On the other hand, when the hydrocarbon group is a polycyclic group, structural units represented by formulas (a3-1), (a3-2) and (a3-3) shown below are preferable.

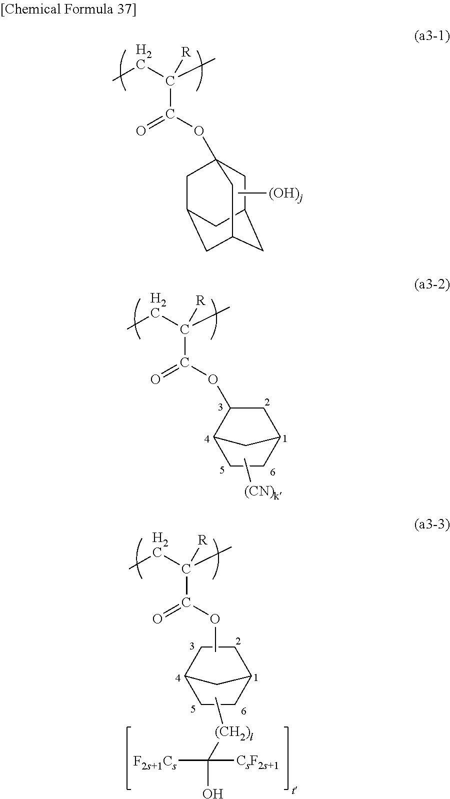

In the formulas, R is as defined above; j is an integer of 1 to 3; k′ is an integer of 1 to 3; t′ is an integer of 1 to 3; 1 is an integer of 1 to 5; and s is an integer of 1 to 3.

In formula (a3-1), j is preferably 1 or 2, and more preferably 1. When j is 2, it is preferable that the hydroxyl groups be bonded to the 3rd and 5th positions of the adamantyl group. When j is 1, it is preferable that the hydroxyl group be bonded to the 3rd position of the adamantyl group.

j is preferably 1, and it is particularly desirable that the hydroxyl group be bonded to the 3rd position of the adamantyl group.

In formula (a3-2), k′ is preferably 1. The cyano group is preferably bonded to the 5th or 6th position of the norbornyl group.

In formula (a3-3), t′ is preferably 1. l is preferably 1. s is preferably 1. Further, in formula (a3-3), it is preferable that a 2-norbonyl group or 3-norbonyl group be bonded to the terminal of the carboxy group of the acrylic acid. The fluorinated alkyl alcohol is preferably bonded to the 5th or 6th position of the norbornyl group.

In the case that the structural unit (a3) is contained in the component (A1) 1 type of structural unit (a3) may be used, or 2 or more types may be used.

The amount of the structural unit (a3) within the component (A1) based on the combined total of all structural units constituting the component (A1) is preferably 5 to 50 mol %, more preferably 5 to 40 mol %, and still more preferably 5 to 25 mol %.

When the amount of the structural unit (a3) is at least as large as the lower limit of the above-mentioned range, the effect of using the structural unit (a3) can be satisfactorily achieved. On the other hand, when the amount of the structural unit (a3) is no more than the upper limit of the above-mentioned range, a good balance can be achieved with the other structural units.

### (Other Structural Units)

The component (A1) may include a structural unit other than the structural units (a0) and (a1) to (a3), as long as the effects of the present invention are not impaired.

As such a structural unit, any other structural unit which cannot be classified as the aforementioned structural units can be used without any particular limitation, and any of the multitude of conventional structural units used within resist resins for ArF excimer lasers or KrF excimer lasers (and particularly for ArF excimer lasers) can be used.

Preferable examples of the other structural unit include the structural unit (a4) derived from an acrylate ester which may have the hydrogen atom bonded to the carbon atom on the α-position substituted with a substituent and containing an acid non-dissociable aliphatic polycyclic group.

-Structural Unit (a4)

The structural unit (a4) is a structural unit derived from an acylate ester which may have the hydrogen atom bonded to the carbon atom on the α position substituted with a substituent and contains an acid non-dissociable aliphatic polycyclic group.

In the structural unit (a4), examples of this polycyclic group include the same polycyclic groups as those described above in relation to the aforementioned structural unit (a1), and any of the multitude of conventional polycyclic groups used within the resin component of resist compositions for ArF excimer lasers or KrF excimer lasers (and particularly for ArF excimer lasers) can be used.

In consideration of industrial availability and the like, at least one polycyclic group selected from amongst a tricyclodecyl group, adamantyl group, tetracyclododecyl group, isobornyl group, and norbornyl group is particularly desirable. These polycyclic groups may be substituted with a linear or branched alkyl group of 1 to 5 carbon atoms.

Specific examples of the structural unit (a4) include units with structures represented by general formulas (a-4-1) to (a-4-5) shown below.

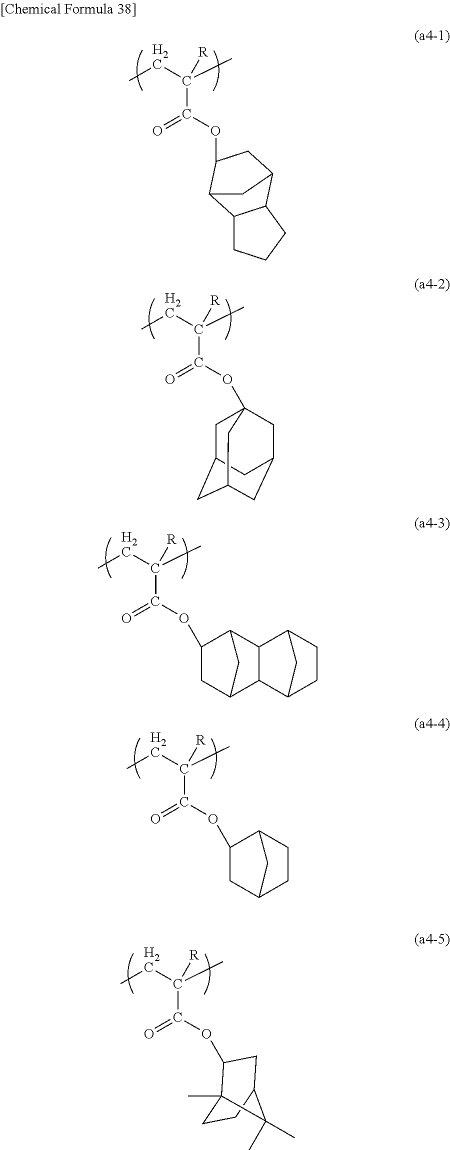

In the formulas, R is the same as defined above.

In the component (A1), as the structural unit (a4), one type of structural unit may be used, or two or more types may be used in combination.

When the structural unit (a4) is included in the component (A1), the amount of the structural unit (a4) based on the combined total of all the structural units that constitute the component (A1) is preferably within the range from 1 to 30 mol %, and more preferably from 10 to 20 mol %.

In the resist composition of the present invention, it is preferable that the component (A) contains a polymeric compound (A1) having a structural unit (a1).

Examples of such component (A1) include a polymeric compound consisting of a repeating structure of the structural units (a1), structural unit (a0) and structural unit (a3); a polymeric compound consisting of a repeating structure of structural unit (a1), structural unit (a2) and structural unit (a3); and a polymeric compound consisting of a repeating structure of structural units (a1), structural unit (a0), structural unit (a2) and structural unit (a3).

In the present invention, as the component (A1), a polymeric compound including a combination of the structural units represented by general formula (A1-1) shown below, and a polymeric compound including a combination of the structural units represented by general formula (A1-2) shown below are preferred.

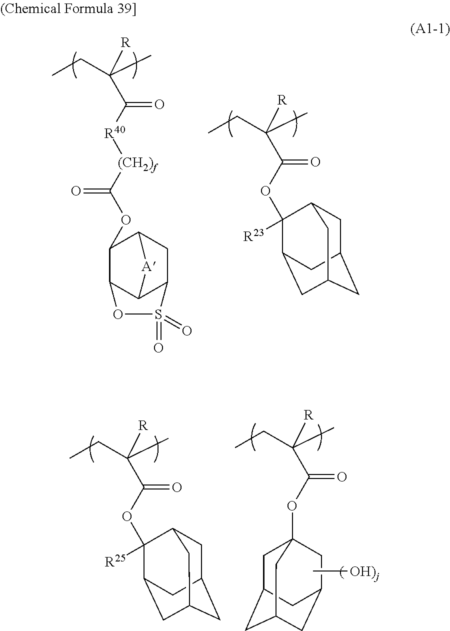

In the formula, R, R⁴⁰, f, A′, R²³, R²⁵ and j are the same as defined above, and the plurality of R may be the same or different from each other.

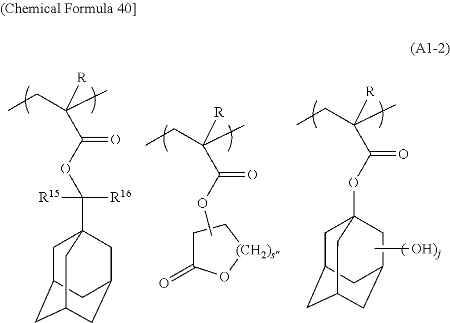

In the formula, R, R¹⁵, R¹⁶, s″ and j are the same as defined above, and the plurality of R may be the same or different from each other.

The weight average molecular weight (Mw) (the polystyrene equivalent value determined by gel permeation chromatography) of the component (A1) is not particularly limited, but is preferably 1,000 to 50,000, more preferably 1,500 to 30,000, and most preferably 2,000 to 20,000.

When the weight average molecular weight of the component (A1) is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.2 to 2.5. Here, Mn is the number average molecular weight.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

As the monomers for deriving the corresponding structural units, commercially available monomers may be used, or the monomers may be synthesized by a conventional method.

In the component (A), as the component (A1), one type may be used alone, or two or more types may be used in combination.

In the component (A), the amount of the component (A1) based on the total weight of the component (A) is preferably 25% by weight or more, more preferably 50% by weight or more, still more preferably 75% by weight or more, and may be even 100% by weight. When the amount of the component (A1) is 25% by weight or more, sensitivity is improved, and a resist pattern having an excellent shape can be obtained.

### [Component (A2)]

The component (A) may contain a base component which exhibits increased solubility in an alkali developing solution under action of acid other than the component (A1) (hereafter, referred to as “component (A2)”), that is, a base component which exhibits increased polarity by the action of acid, thereby exhibiting increased solubility in an alkali developing solution, as long as the effects of the present invention are not impaired.

In a resist composition of the present invention, as the component (A2), a lo molecular weight compound that has a molecular weight of at least 500 and less than 2,500, contains a hydrophilic group, and also contains an acid dissociable group described above in connection with the component (A1) may be used. Specific examples include compounds containing a plurality of phenol skeletons in which a part of the hydrogen atoms within hydroxyl groups have been substituted with the aforementioned acid dissociable groups.

Examples of the low-molecular weight compound include low molecular weight phenolic compounds in which a portion of the hydroxyl group hydrogen atoms have been substituted with an aforementioned acid dissociable group, and these types of compounds are known, for example, as sensitizers or heat resistance improvers for use in non-chemically amplified g-line or i-line resists.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers, tetramers, pentamers and hexamers of formalin condensation products of phenols such as phenol, m-cresol, p-cresol and xylenol. Needless to say, the low molecular weight phenol compound is not limited to these examples. In particular, a phenol compound having 2 to 6 triphenylmethane skeletons is preferable in terms of resolution and line width roughness (LWR). Also, there are no particular limitations on the acid dissociable group, and suitable examples include the groups described above.

In the resist composition of the present invention, as the component (A), one type may be used, or two or more types of compounds may be used in combination.

In the resist composition of the present invention, the amount of the component (A) can be appropriately adjusted depending on the thickness of the resist film to be formed, and the like.

### <Component (13)>

In the resist composition according to the present invention, as the component (B), there is no particular limitation, and any of the known acid generators used in conventional chemically amplified resist compositions can be used.

Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

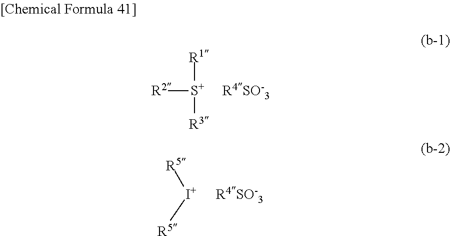

In formula, R¹″ to R³″ and R⁵″ to R⁶″each independently represents an aryl group which may have a substituent, an alkyl group which may have a substituent, or an alkenyl group which may have a substituent. In formula (b-1), two of R¹″ to R³″ may be bonded to each other to form a ring with the sulfur atom. R⁴″ represents an alkyl group, a halogenated alkyl group, an aryl group or an alkenyl group which may have a substituent.

In formula (b-1), R¹″ to R³″ each independently represents an aryl group which may have a substituent, an alkyl group which may have a substituent or an alkenyl group which may have a substituent. Two of R¹″ to R³″ may be mutually bonded to form a ring with the sulfur atom.

In terms of improving lithography properties and resist pattern shape, among R¹″ to R³″, it is more preferable that at least one of R¹″ to R³″ is aryl groups, it is more preferable that two or more of R¹″ to R³″ are aryl groups, and it is particularly preferable that all of R¹″ to R³″ are aryl groups.

Examples of the aryl group for R¹″ to R³″ include an unsubstituted aryl group of 6 to 20 carbon atoms; a substituted aryl group in which part or all of the hydrogen atoms of the aforementioned unsubstituted aryl group has been substituted with an alkyl group, an alkoxy group, a halogen atom, a hydroxy group, an oxo group (═O), an aryl group, an alkoxyalkyloxy group, an alkoxycarbonylalkyloxy group, —C(═O)—O—R⁶′, —O—C(═O)—R⁷′ or —O—R⁸′. Each of R⁶′, R⁷′ and R⁸′ independently represents a linear or branched saturated hydrocarbon group of 1 to 25 atoms, a cyclic saturated hydrocarbon group of 3 to 20 carbon atoms or a linear or branched, aliphatic unsaturated hydrocarbon group of 2 to 5 carbon atoms.

The unsubstituted aryl group for R¹″ to R³″ is preferably an aryl group having 6 to 10 carbon atoms because it can be synthesized at a low cost. Specific examples thereof include a phenyl group and a naphthyl group.

The alkyl group as the substituent for the substituted aryl group represented by R¹″ to R³″ is preferably an alkyl group having 1 to 5 carbon atoms, and a methyl group, an ethyl group, a propyl group, an n-butyl group, or a tert-butyl group is most desirable.

The alkoxy group as the substituent for the substituted aryl group is preferably an alkoxy group having 1 to 5 carbon atoms, and a methoxy group, an ethoxy group, an n-propoxy group, an iso-propoxy group, an n-butoxy group or a tert-butoxy group is most desirable.

The halogen atom as the substituent for the substituted aryl group is preferably a fluorine atom.

As the aryl group as the substituent for the substituted aryl group, the same aryl groups as those described above for R¹″ to R³″ can be mentioned, and an aryl group of 6 to 20 carbon atoms is preferable, an aryl group of 6 to 10 carbon atoms is more preferable, and a phenyl group or a naphthyl group is still more preferable.

Examples of alkoxyalkyloxy groups as the substituent for the substituted aryl group include groups represented by a general formula shown below:

general formula: —O—C(R⁴⁷)(R⁴⁸)—O—R⁴⁹ [In the formula, R⁴⁷ and R⁴⁸ each independently represents a hydrogen atom or a linear or branched alkyl group; and R⁴⁹ represents an alkyl group.]

The alkyl group for R⁴⁷ and R⁴⁸ preferably has 1 to 5 carbon atoms, and may be either linear or branched, and is preferably an ethyl group or a methyl group, and most preferably a methyl group.

It is preferable that at least one of R⁴⁷ and R⁴⁸ be a hydrogen atom. It is particularly desirable that at least one of R⁴⁷ and R⁴⁸ be a hydrogen atom, and the other be a hydrogen atom or a methyl group.

The alkyl group for R⁴⁹ preferably has 1 to 15 carbon atoms, and may be linear, branched or cyclic.

The linear or branched alkyl group for R⁴⁹ preferably has 1 to 5 carbon atoms. Examples thereof include a methyl group, an ethyl group, a propyl group, an n-butyl group and a tert-butyl group.

The cyclic alkyl group for R⁴⁹ preferably has 4 to 15 carbon atoms, more preferably 4 to 12, and most preferably 5 to 10. Specific examples thereof include groups in which one or more hydrogen atoms have been removed from a monocycloalkane or a polycycloalkane such as a bicycloalkane, tricycloalkane or tetracycloalkane, and which may or may not be substituted with an alkyl group of 1 to 5 carbon atoms, a fluorine atom or a fluorinated alkyl group. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

Examples of the alkoxycarbonylalkyloxy group as the substituent for the substituted aryl group include groups represented by a general formula shown below: general formula: —O—R⁵⁰—C(═O)—O—R⁵⁶ [In the formula, R⁵⁰ represents a linear or branched alkylene group, and R⁵⁶ represents a tertiary alkyl group.]

The linear or branched alkylene group for R⁵⁰ preferably has 1 to 5 carbon atoms, and examples thereof include a methylene group, an ethylene group, a trimethylene group, a tetramethylene group and a 1,1-dimethylethylene group.

The alkyl group for R⁵⁶ is a tertiary alkyl group, and examples thereof include a 2-methyl-2-adamantyl group, a 2-ethyl-2-adamantyl group, a 1-methyl-1-cyclopentyl group, a 1-ethyl-1-cyclopentyl group, a 1-methyl-1-cyclohexyl group, a 1-ethyl-1-cyclohexyl group, a 1-(1-adamantyl)-1-methyl ethyl group, a 1-(1-adamantyl)-1-methylpropyl group, a 1-(1-adamantyl)-1-methylbutyl group, a 1-(1-adamantyl)-1-methylpentyl group, a 1-(1-cyclopentyl)-1-methylethyl group, a 1-(1-cyclopentyl)-1-methylpropyl group, a 1-(1-cyclopentyl)-1-methylbutyl group, a 1-(1-cyclopentyl)-1-methylpentyl group, a 1-(1-cyclohexyl)-1-methyl ethyl group, a 1-(1-cyclohexyl)-1-methylpropyl group, a 1-(1-cyclohexyl)-1-methylbutyl group, a 1-(1-cyclohexyl)-1-methylpentyl group, a tert-butyl group, a tert-pentyl group and a tert-hexyl group.

Further, a group in which R⁵⁶ in the group represented by the aforementioned general formula: —O—R⁵⁰—C(═O)—O—R⁵⁶ has been substituted with R⁵⁶′ can also be mentioned. R⁵⁶′ represents a hydrogen atom, an alkyl group, a fluorinated alkyl group or an aliphatic cyclic group which may contain a hetero atom.

The alkyl group for R⁵⁶′ is the same as defined for the alkyl group for the aforementioned R⁴⁹.

Examples of the fluorinated alkyl group for R⁵⁶′ include groups in which part or all of the hydrogen atoms within the alkyl group for R⁴⁹ has been substituted with a fluorine atom.

Examples of the aliphatic cyclic group for R⁵⁶′ which may contain a hetero atom include an aliphatic cyclic group which does not contain a hetero atom, an alipahtic cyclic group containing a hetero atom in the ring structure, and an aliphatic cyclic group in which a hydrogen atom has been substituted with a hetero atom.

As an aliphatic cyclic group for R⁵⁶′ which does not contain a hetero atom, a group in which one or more hydrogen atoms have been removed from a monocycloalkane or a polycycloalkane such as a bicycloalkane, a tricycloalkane or a tetracycloalkane can be mentioned. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

Specific examples of the aliphatic cyclic group for R⁵⁶′ containing a hetero atom in the ring structure include groups represented by formulas (L1) to (L6) and (S1) to (S4) described later.

As the aliphatic cyclic group for R⁵⁶′ in which a hydrogen atom has been substituted with a hetero atom, an aliphatic cyclic group in which a hydrogen atom has been substituted with an oxygen atom (═O) can be mentioned.

In the groups —C(═O)—O—R⁶′, —O—C(═O)—R⁷′, —O—R⁸′, each of R⁶′, R⁷′ and R⁸′ independently represents a linear or branched saturated hydrocarbon group of 1 to 25 atoms, a cyclic saturated hydrocarbon group of 3 to 20 carbon atoms or a linear or branched, aliphatic unsaturated hydrocarbon group of 2 to 5 carbon atoms.

The linear or branched, saturated hydrocarbon group preferably has 1 to 25 carbon atoms, more preferably 1 to 15, and still more preferably 4 to 10.

Examples of the linear, saturated hydrocarbon group include a methyl group, an ethyl group, a propyl group, a butyl group, a pentyl group, a hexyl group, a heptyl group, an octyl group, a nonyl group and a decyl group.

Examples of the branched, saturated hydrocarbon group include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group, but excluding tertiary alkyl groups.

The linear or branched, saturated hydrocarbon group may have a substituent. Examples of the substituent include an alkoxy group, a halogen atom, a halogenated alkyl group, a hydroxyl group, an oxygen atom (═O), a cyano group and a carboxy group.

The alkoxy group as the substituent for the linear or branched saturated hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the linear or branched, saturated alkyl group include a fluorine atom, a chlorine atom, a bromine atom and an iodine atom, and a fluorine atom is preferable.

Example of the halogenated alkyl group as the substituent for the linear or branched, saturated hydrocarbon group includes a group in which part or all of the hydrogen atoms within the aforementioned linear or branched, saturated hydrocarbon group have been substituted with the aforementioned halogen atoms.

The cyclic saturated hydrocarbon group of 3 to 20 carbon atoms for R⁶′, R⁷′ and R⁸′ may be either a polycyclic group or a monocyclic group, and examples thereof include groups in which one hydrogen atom has been removed from a monocycloalkane, and groups in which one hydrogen atom has been removed from a polycycloalkane (e.g., a bicycloalkane, a tricycloalkane or a tetracycloalkane). More specific examples include groups in which one hydrogen atom has been removed from a monocycloalkane such as cyclopentane, cyclohexane, cycloheptane or cyclooctane; and groups in which one or more hydrogen atoms have been removed from a polycycloalkane such as adamantane, norbornane, isobornane, tricyclodecane or tetracyclododecane.

The cyclic, saturated hydrocarbon group may have a substituent. For example, part of the carbon atoms constituting the ring within the cyclic alkyl group may be substituted with a hetero atom, or a hydrogen atom bonded to the ring within the cyclic alkyl group may be substituted with a substituent.

In the former example, a heterocycloalkane in which part of the carbon atoms constituting the ring within the aforementioned monocycloalkane or polycycloalkane has been substituted with a hetero atom such as an oxygen atom, a sulfur atom or a nitrogen atom, and one hydrogen atom has been removed therefrom, can be used. Further, the ring may contain an ester bond (—C(═O)—O—). More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane containing a lactone ring.

In the latter example, as the substituent, the same substituent groups as those for the aforementioned linear or branched alkyl group, or a lower alkyl group can be used.

Alternatively, R⁶′, R⁷′ and R⁸′ may be a combination of a linear or branched alkyl group and a cyclic group.

Examples of the combination of a linear or branched alkyl group with a cyclic alkyl group include groups in which a cyclic alkyl group as a substituent is bonded to a linear or branched alkyl group, and groups in which a linear or branched alkyl group as a substituent is bonded to a cyclic alkyl group.

Examples of the linear aliphatic unsaturated hydrocarbon group for R⁶′, R⁷′ and R⁸′ include a vinyl group, a propenyl group (an allyl group) and a butynyl group.

Examples of the branched aliphatic unsaturated hydrocarbon group for R⁶′, R⁷′ and R⁸′ include a 1-methylpropenyl group and a 2-methylpropenyl group.

The aforementioned linear or branched, aliphatic unsaturated hydrocarbon group may have a substituent. Examples of substituents include the same substituents as those which the aforementioned linear or branched alkyl group may have.

Among the aforementioned examples, as R^{7′} and R⁸′, n terms of improvement in lithography properties and shape of the resist pattern, a linear or branched, saturated hydrocarbon group of 1 to 15 carbon atoms or a cyclic saturated hydrocarbon group of 3 to 20 carbon atoms is preferable.

The aryl group for R¹″ to R³″ is preferably a phenyl group or a naphthyl group.

Examples of the alkyl group for R¹″ to R³″ include linear, branched or cyclic alkyl groups of 1 to 10 carbon atoms. Among these, alkyl groups of 1 to 5 carbon atoms are preferable as the resolution becomes excellent. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group, and a methyl group is most preferable because it is excellent in resolution and can be synthesized at a low cost.

The alkenyl group for R¹″ to R³″ preferably has 2 to 10 carbon atoms, more preferably 2 to 5, and still more preferably 2 to 4. Specific examples thereof include a vinyl group, a propenyl group (an allyl group), a butynyl group, a 1-methylpropenyl group and a 2-methylpropenyl group.

When two of R¹″ to R³″ are bonded to each other to form a ring with the sulfur atom, it is preferable that the two of R¹″ to R³″ form a 3 to 10-membered ring including the sulfur atom, and it is particularly desirable that the two of R¹″ to R³″ form a 5 to 7-membered ring including the sulfur atom.

When two of R¹″ to R³″ are bonded to each other to form a ring with the sulfur atom, the remaining one of R¹″ to R³″ is preferably an aryl group. As examples of the aryl group, the same aryl groups as those described above for R¹″ to R³″ can be used.

Specific examples of cation moiety of the compound represented by general formula (b-1) include triphenylsulfonium, (3,5-dimethylphenyl)diphenylsulfonium, (4-(2-adamantoxymethyloxy)-3,5-dimethylphenyl)diphenylsulfonium, (4-(2-adamantoxymethyloxy)phenyl)diphenylsulfonium, (4-(tert-butoxycarbonylmethyloxy)phenyl)diphenylsulfonium, (4-(tert-butoxycarbonylmethyloxy)-3,5-dimethylphenyl)diphenylsulfonium, (4-(2-methyl-2-adamantyloxycarbonylmethyloxy)phenyl)diphenylsulfonium, (4-(2-methyl-2-adamantyloxycarbonylmethyloxy)-3,5-dimethylphenyl)diphenylsulfonium, tri(4-methylphenyl)sulfonium, dimethyl(4-hydroxynaphthyl)sulfonium, monophenyldimethylsulfonium, diphenylmonomethylsulfonium, (4-methylphenyl)diphenylsulfonium, (4-methoxyphenyl)diphenylsulfonium, tri(4-tert-butyl)phenylsulfonium, diphenyl(1-(4-methoxy)naphthyl)sulfonium, di(1-naphthyl)phenylsulfonium, 1-phenyltetrahydrothiophenium, 1-(4-methylphenyl)tetrahydrothiophenium, 1-(3,5-dimethyl-4-hydroxyphenyl)tetrahydrothiophenium, 1-(4-methoxynaphthalene-1-yl)tetrahydrothiophenium, 1-(4-ethoxynaphthalene-1-yl)tetrahydrothiophenium, 1-(4-n-butoxynaphthalene-1-yl)tetrahydrothiophenium, 1-phenyltetrahydrothiopyranium, 1-(4-hydroxyphenyl)tetrahydrothiopyranium, 1-(3,5-dimethyl-4-hydroxyphenyl)tetrahydrothiopyranium and 1-(4-methylphenyl)tetrahydrothiopyranium.

Specific examples of the cation moiety within the compound represented by the formula (b-1) are shown below.

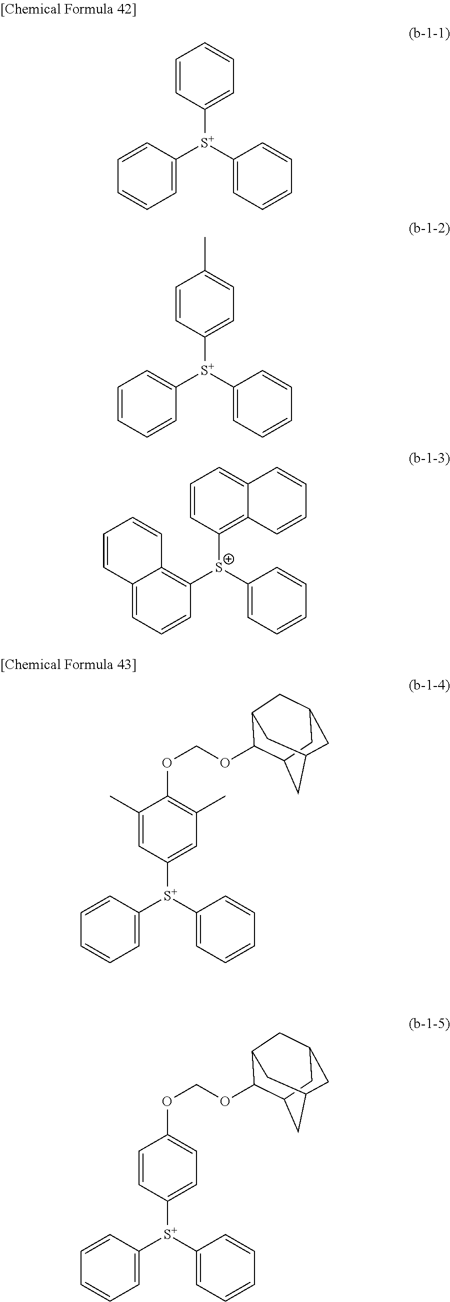

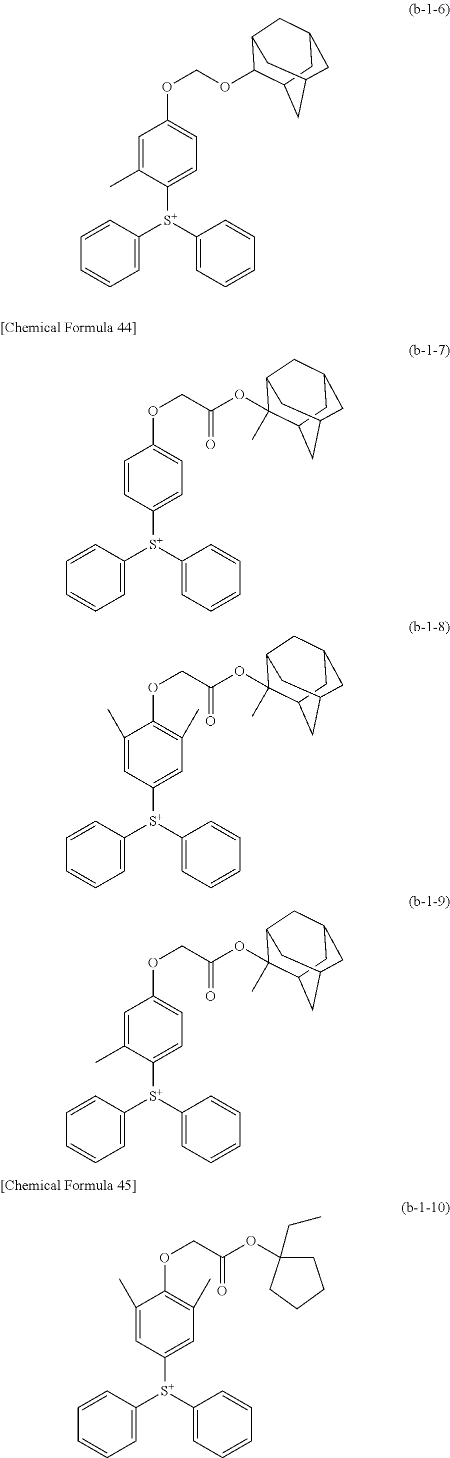

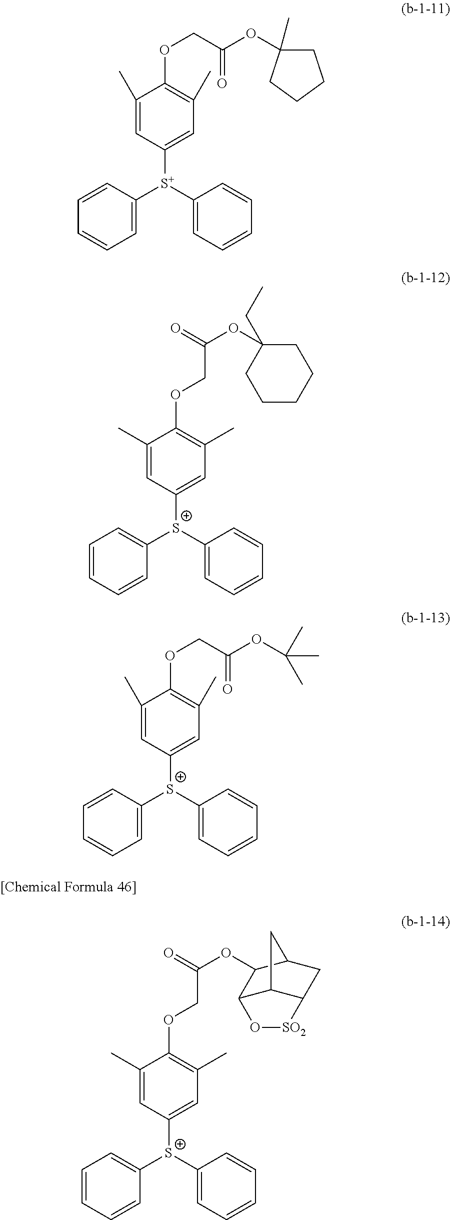

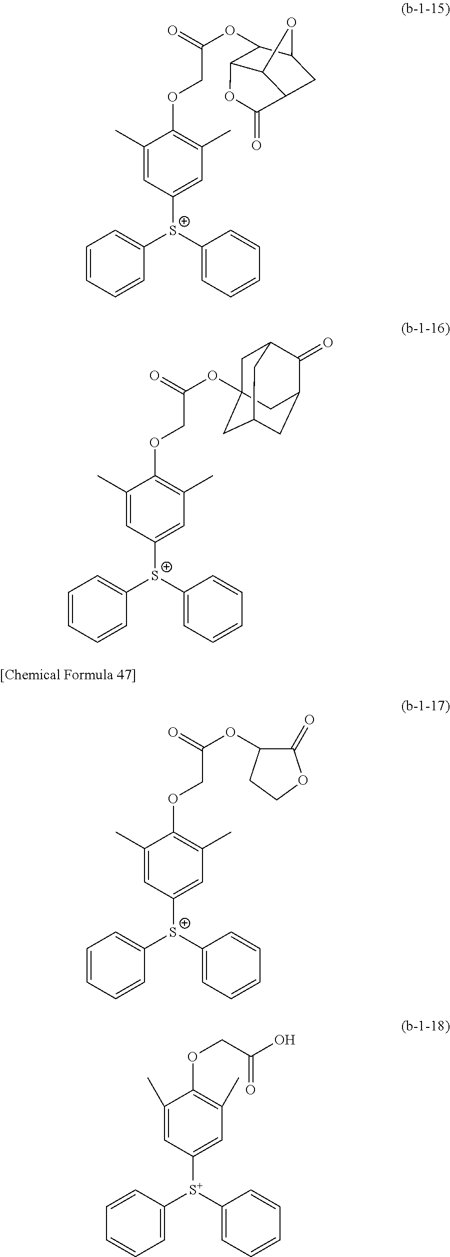

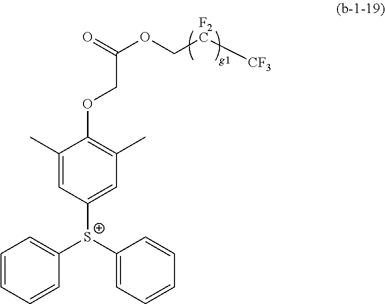

In the formula, g1 represents a recurring number, and is an integer of 1 to 5.

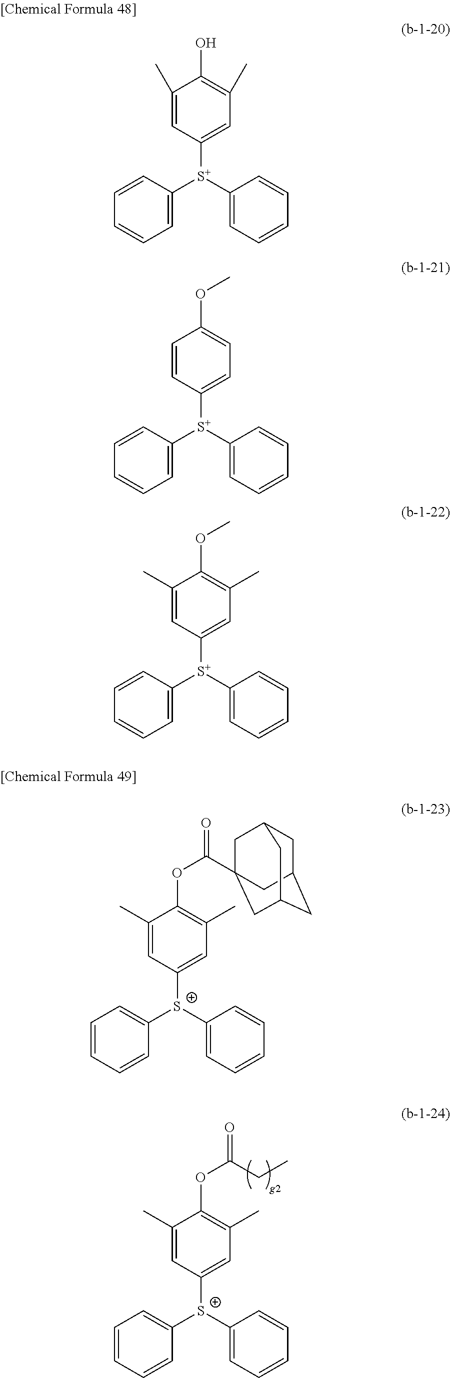

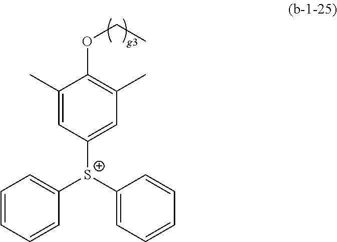

In the formula, g2 and g3 represent recurring numbers, wherein g2 is an integer of 0 to 20, and g3 is an integer of 0 to 20.

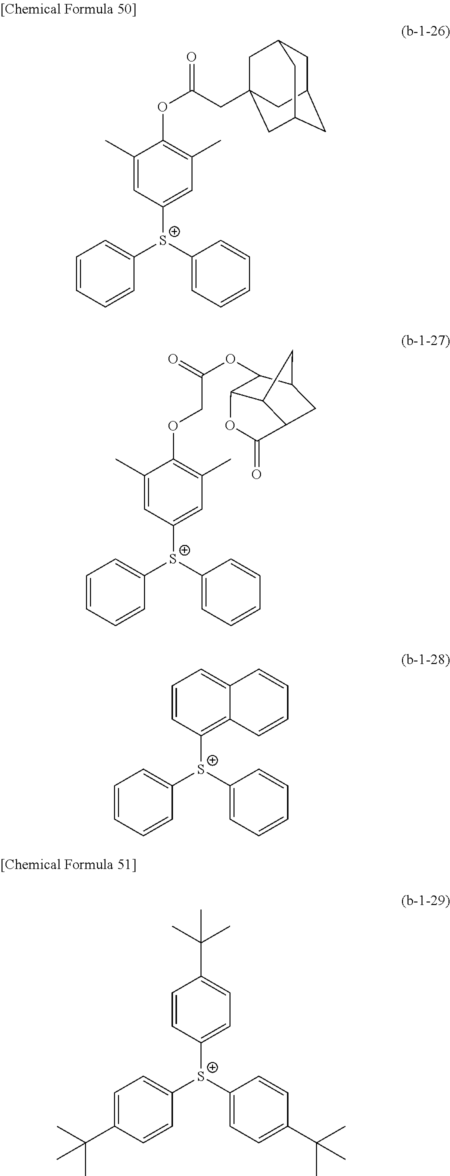 [SMILES: Cc1cc([S+](c2ccccc2)c2ccccc2)cc(C)c1OC(=O)CC12CC3CC(CC(C3)C1)C2 ; Cc1cc([S+](c2ccccc2)c2ccccc2)cc(C)c1OCC(=O)OC1C2CC3C(=O)OC1C3C2 ; c1ccc([S+](c2ccccc2)c2cccc3ccccc23)cc1 ; CC(C)(C)c1ccc([S+](c2ccc(C(C)(C)C)cc2)c2ccc(C(C)(C)C)cc2)cc1]

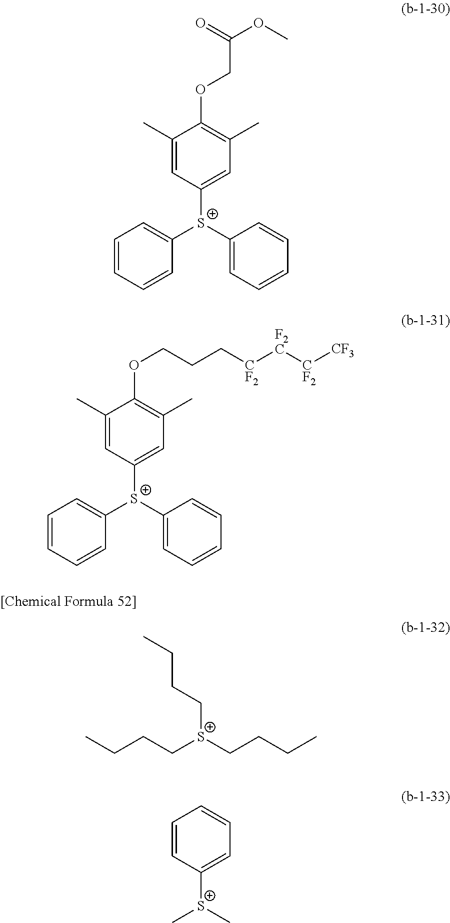

In formulas (b-1) and (b-2), R⁴″ represents an alkyl group, a halogenated alkyl group, an aryl group or an alkenyl group which may have a substituent.

The alkyl group for R⁴″ may be any of linear, branched or cyclic.

The linear or branched alkyl group preferably has 1 to 10 carbon atoms, more preferably 1 to 8 carbon atoms, and most preferably 1 to 4 carbon atoms.

The cyclic alkyl group preferably has 4 to 15 carbon atoms, more preferably 4 to 10 carbon atoms, and most preferably 6 to 10 carbon atoms.

As an example of the halogenated alkyl group for R⁴″, a group in which part of or all of the hydrogen atoms of the aforementioned linear, branched or cyclic alkyl group have been substituted with halogen atoms can be given. Examples of the aforementioned halogen atom include a fluorine atom, a chlorine atom, a bromine atom and an iodine atom, and a fluorine atom is preferable.

In the halogenated alkyl group, the percentage of the number of halogen atoms based on the total number of halogen atoms and hydrogen atoms (halogenation ratio (%)) is preferably 10 to 100%, more preferably 50 to 100%, and most preferably 100%.

Higher halogenation ratio is preferable because the acid strength increases.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X³-Q¹- (in the formula, Q¹ represents a divalent linking group containing an oxygen atom; and X³ represents a hydrocarbon group of 3 to 30 carbon atoms which may have a substituent).

Examples of halogen atoms and alkyl groups include the same halogen atoms and alkyl groups as those described above with respect to the halogenated alkyl group for R⁴″.

Examples of hetero atoms include an oxygen atom, a nitrogen atom, and a sulfur atom.

In the group represented by formula X³-Q¹-, Q¹ represents a divalent linking group containing an oxygen atom.

Q¹ may contain an atom other than an oxygen atom. Examples of atoms other than oxygen include a carbon atom, a hydrogen atom, a sulfur atom and a nitrogen atom.

Examples of divalent linkage groups containing an oxygen atom include non-hydrocarbon, oxygen atom-containing linkage groups such as an oxygen atom (an ether bond; —O—), an ester bond (—C(═O)—O—), an amido bond (—C(═O)—NH—), a carbonyl group (—C(═O)—) and a carbonate group (—O—C(═O)—O—); and a combination of any of the aforementioned non-hydrocarbon, oxygen atom-containing linkage groups with an alkylene group.

Specific examples of the combinations of the aforementioned non-hydrocarbon, oxygen atom-containing linkage groups with alkylene groups include —R⁹¹—O—, —R⁹²—O—C(═O)— and —C(═O)—O—R⁹³—O—C(═O)— (in the formulas, R⁹′ to R⁹³ each independently represent an alkylene group.)

The alkylene group for R⁹¹ to R⁹³ is preferably a linear or branched alkylene group, and preferably has 1 to 12 carbon atoms, more preferably 1 to 5, and most preferably 1 to 3.

Specific examples of the alkylene group include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂— ].

Q¹ is preferably a divalent linking group containing an ester linkage or ether linkage, and more preferably a group of —R⁹¹—O—, —R⁹²—O—C(═O)— or —C(═O)—O—R⁹³—β—C(═O)—.

In the group represented by the formula X³-Q¹-, the hydrocarbon group for X³ may be either an aromatic hydrocarbon group or an aliphatic hydrocarbon group.

The aromatic hydrocarbon group is a hydrocarbon group having an aromatic ring. The aromatic hydrocarbon group preferably has 5 to 30 carbon atoms, more preferably 5 to 20, still more preferably 6 to 15, and most preferably 6 to 12. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2, and most preferably 1.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned heteroatom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is most desirable.

The alkoxy group as the substituent for the aromatic hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X³ may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X³, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for X³, there is no particular limitation as long as it is an atom other than carbon and hydrogen. Examples of hetero atoms include a halogen atom, an oxygen atom, a sulfur atom and a nitrogen atom.

Examples of the halogen atom include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting a part of the carbon atoms include —O—, —C(═O)—O—, —C(═O)—, —O—C(═O)—O—, —C(═O)—NH—, —NH— (the H may be substituted with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5, still more preferably 2 to 4, and particularly preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30, still more preferably 5 to 20, particularly preferably 6 to 15, and most preferably 6 to 12.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

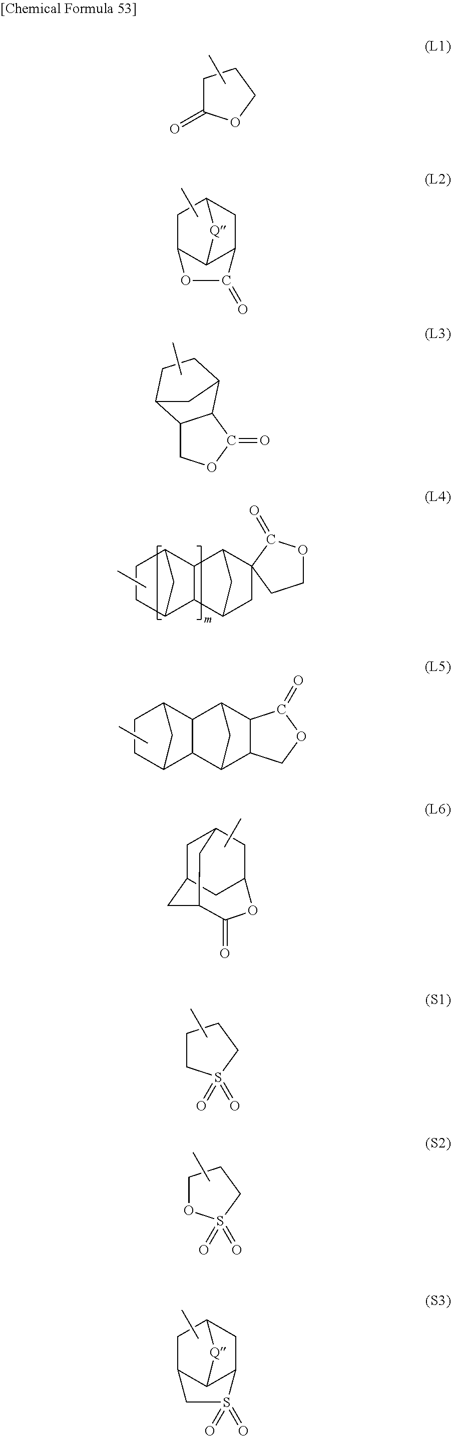

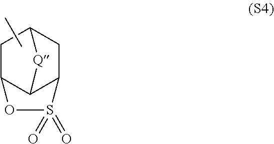

In the formulas, Q″ represents an alkylene group of 1 to 5 carbon atoms, —O—, —S—, —O—R⁹⁴— or —S—R⁹⁵—, and R⁹⁴ and R⁹⁵ each independently represent an alkylene group of 1 to 5 carbon atoms); and m represents an integer 0 or 1.

As the alkylene group for Q″, R⁹⁴ and R⁹⁵, the same alkylene groups as those described above for R⁹¹ to R⁹³ can be used.

In these aliphatic cyclic groups, part of the hydrogen atoms bonded to the carbon atoms constituting the ring structure may be substituted with a substituent. Examples of substituents include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

As the alkoxy group and the halogen atom, the same groups as the substituent groups for substituting part or all of the hydrogen atoms can be used.

In the present invention, as X³, a cyclic group which may have a substituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by the aforementioned formulas (L2) to (L6), (S3) and (S4) are preferable.

In the present invention, R⁴″ preferably has X³-Q¹- as a substituent. In this case, R⁴″ is preferably a group represented by formula X³-Q¹-Y¹⁰-[wherein Q¹ and X³ are the same as defined above; and Y¹⁰ represents an alkylene group of 1 to 4 carbon atoms which may have a substituent or a fluorinated alkylene group of 1 to 4 carbon atoms which may have a substituent].

In the group represented by the formula X³-Q¹-Y¹⁰, as the alkylene group for Y¹⁰, the same alkylene group as those described above for Q¹ in which the number of carbon atoms is 1 to 4 can be used.

As the fluorinated alkylene group, the aforementioned alkylene group in which part or all of the hydrogen atoms has been substituted with fluorine atoms can be used.

Specific examples of Y¹⁰ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—, —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)— and —C(CH₃)(CH₂CH₃)—.

As Y¹⁰, a fluorinated alkylene group is preferable, and a fluorinated alkylene group in which the carbon atom bonded to the adjacent sulfur atom is fluorinated is particularly desirable. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂C—CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxyl group.

In formula (b-2), R⁵″ and R⁶″ each independently represents an aryl group which may have a substituent, an alkyl group which may have a substituent or an alkenyl group which may have a substituent.

In terms of improving lithography properties and resist pattern shape, among R⁵″ and R⁶″, it is more preferable that at least one of R⁵″ and R⁶″ is aryl groups, and it is more preferable that all of R¹″ to R³″ are aryl groups.

As the aryl group for R⁵″ and R⁶″, the same aryl groups as those described above for R¹″ to R³″ can be used.

As the alkyl group for R⁵″ and R⁶″, the same alkyl groups as those described above for R¹″ to R³″ can be used.

As the alkenyl group for R⁵″ and R⁶″, the same as the alkenyl groups for R¹″ to R³″ can be used.

It is particularly desirable that both of R⁵″ and R⁶″ represents a phenyl group.

Specific examples of the cation moiety of the compound represented by general formula (b-2) include diphenyliodonium and bis(4-tert-butylphenyl)iodonium.

As R⁴″ in formula (b-2), the same groups as those mentioned above for R⁴″ in formula (b-1) can be used.

Specific examples of suitable onium salt acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts is replaced by an alkyl sulfonate, such as methanesulfonate, n-propanesulfonate, n-butanesulfonate, n-octanesulfonate, 1-adamantanesulfonate, 2-norbornanesulfonate or d-camphor-10-sulfonate; or replaced by an aromatic sulfonate, such as benzenesulfonate, perfluorobenzenesulfonate or p-toluenesulfonate.

Furthermore, it is preferable that onium salts in which the anion moiety of these onium salts are replaced by an anion moiety represented by any one of formulas (b1) to (b9) shown below are used. Among these, it is more preferable that onium salts in which the anion moiety of these onium salts are replaced by an anion moiety represented by any one of formulas (b3) to (b6) and (b9) shown below are used. Furthermore, it is presumed that the effect of the present invention can be further improved, by using onium salts in which the anion moiety is replaced by any one of these anion moieties, because the structures of these anion moieties are similar to the structure of the anion moiety within the component (D) described later.

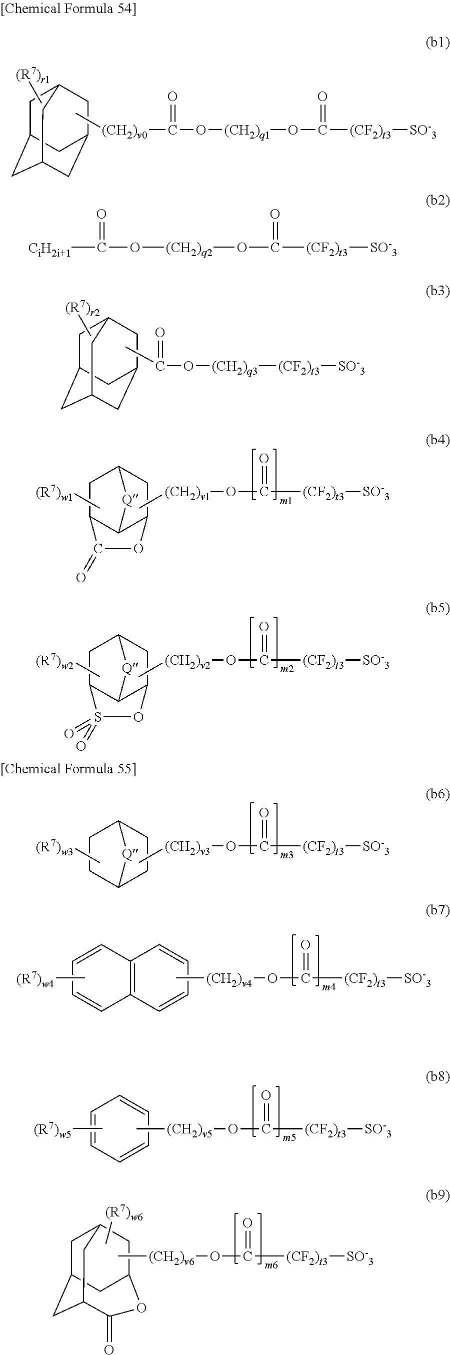

In the formulas, each of q1 and q2 independently represents an integer of 1 to 5; q3 represents an integer of 1 to 12; t3 represents an integer of 1 to 3; each of r1 and r2 independently represents an integer of 0 to 3; i represents an integer of 1 to 20; R⁷ represents a substituent; each of m1 to m6 independently represents 0 or 1; each of v0 to v6 independently represents an integer of 0 to 3; each of w1 to w6 independently represents an integer of 0 to 3; and Q″ is the same as defined above.

As the substituent for R⁷, the same groups as those which the aforementioned aliphatic hydrocarbon group or aromatic hydrocarbon group for X³ may have as a substituent can be used.

If there are two or more of the R⁷ group, as indicated by the values r1, r2, and w1 to w6 then the two or more of the R′ groups may be the same or different from each other.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may be used.

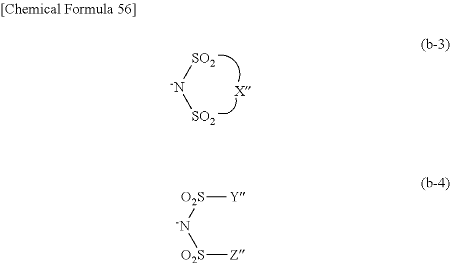

In the formulas, X″ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and more preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and it is preferable that the number of hydrogen atoms substituted with fluorine atoms is as large as possible because the acid strength increases and the transparency to high energy radiation of 200 nm or less or electron beam is improved.

The fluorination ratio of the alkylene group or alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

Furthermore, as an onium salt-based acid generator, a sulfonium salt having a cation represented by general formula (b-5) or (b-6) shown below as the cation moiety may be used.

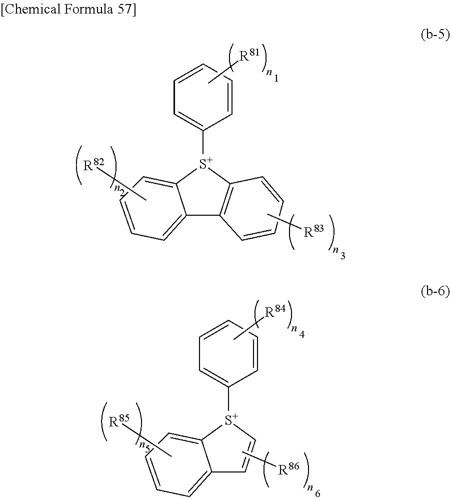

In formulas, each of R⁸¹ to R⁸⁶ independently represents an alkyl group, an acetyl group, an alkoxy group, a carboxy group, a hydroxyl group or a hydroxyalkyl group; each of n₁ to n₅ independently represents an integer of 0 to 3; and n₆ represents an integer of 0 to 2.

With respect to R⁸¹ to R⁸⁶, the alkyl group is preferably an alkyl group of 1 to 5 carbon atoms, more preferably a linear or branched alkyl group, and most preferably a methyl group, an ethyl group, a propyl group, an isopropyl group, an n-butyl group or a tert-butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably a group in which one or more hydrogen atoms in the aforementioned alkyl group have been substituted with hydroxy groups, and examples thereof include a hydroxymethyl group, a hydroxyethyl group and a hydroxypropyl group.

If there are two or more of an individual R⁸¹ to R⁸⁶ group, as indicated by the corresponding value of n₁ to n₆ then the two or more of the individual R″ to R⁸⁶ group may be the same or different from each other.

n₁ is preferably 0 to 2, more preferably 0 or 1, and still more preferably 0.

It is preferable that each of n₂ and n₃ independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

Preferable examples of the cation represented by formula (b-5) or (b-6) are shown below.

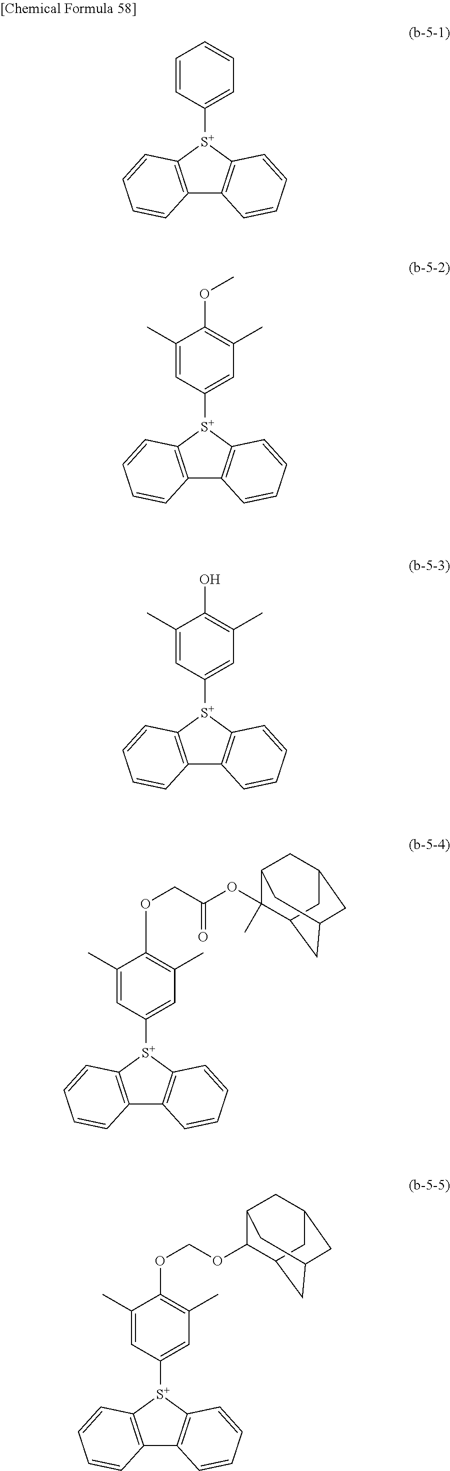 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

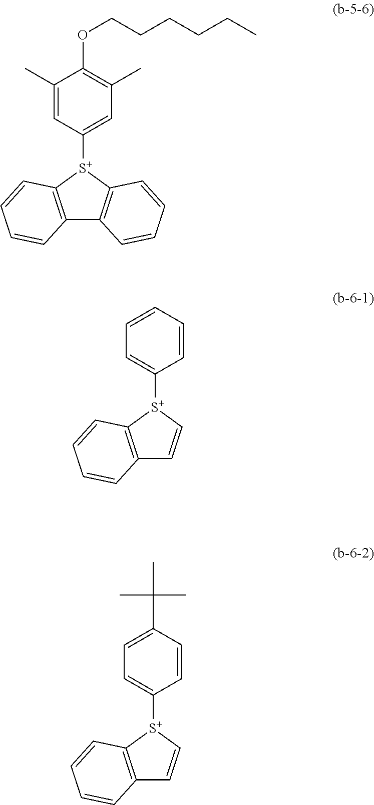 [SMILES: CCCCCCOc1c(C)cc(-[s+]2c3ccccc3c3ccccc32)cc1C ; c1ccc(-[s+]2ccc3ccccc32)cc1 ; CC(C)(C)c1ccc(-[s+]2ccc3ccccc32)cc1]

Furthermore, a sulfonium salt having a cation represented by general formula (b-7) or (b-8) shown below as the cation moiety may be used.

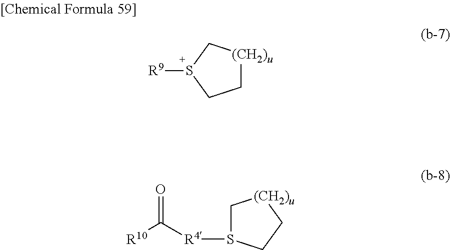

In formulas (b-7) and (b-8) shown below, each of R⁹ and R¹⁰ independently represents a phenyl group or naphthyl group which may have a substituent, an alkyl group of 1 to 5 carbon atoms, an alkoxy group or a hydroxyl group. Examples of the substituent are the same as the substituents described above in relation to the substituted aryl group for to R³″ (i.e., an alkyl group, an alkoxy group, an alkoxyalkyloxy group, an alkoxycarbonylalkyloxy group, a halogen atom, a hydroxy group, an oxo group (═O), an aryl group, —C(═O)—O—R⁶′, —O—C(═O)—R⁷′, —O—R⁸′, a group in which R⁵⁶ in the aforementioned general formula —O—R⁵⁰—C(═O)—O—R⁵⁶ has been substituted with R⁵⁶′).

R⁴′ represents an alkylene group of 1 to 5 carbon atoms.

u is an integer of 1 to 3, and most preferably 1 or 2.

Preferable examples of the cation represented by formula (b-7) or (b-8) are shown below. In the formula, examples of R^{C} are the same as the substituents described above in relation to the substituted aryl group (i.e., an alkyl group, an alkoxy group, an alkoxyalkyloxy group, an alkoxycarbonylalkyloxy group, a halogen atom, a hydroxy group, an oxo group (═O), an aryl group, —C(═O)—O—R⁶′, —O—C(═O)—R⁷′ and —O—R⁸′).

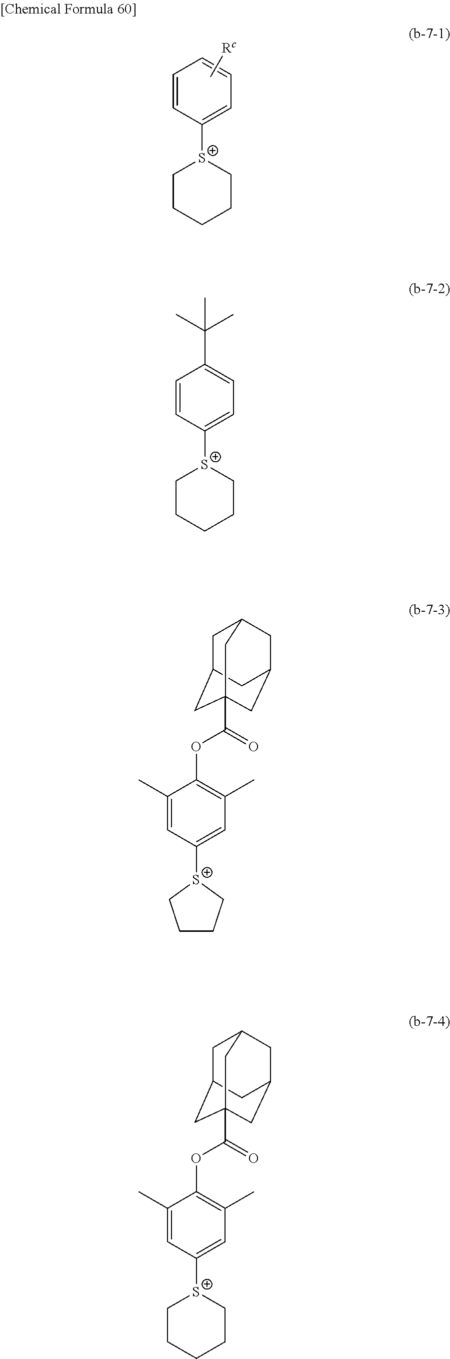

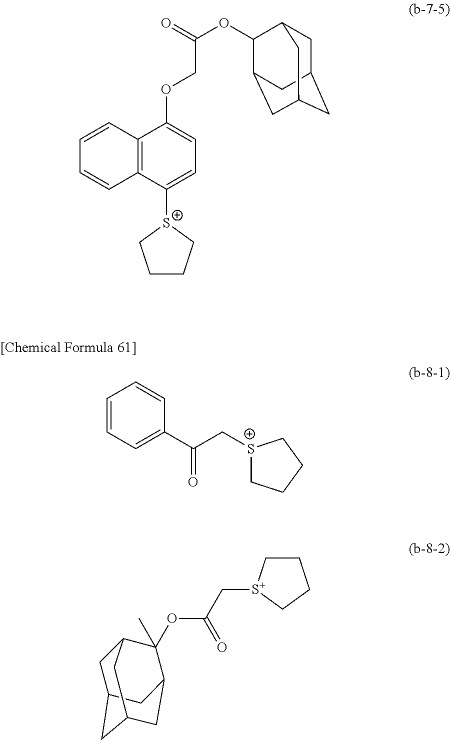 [SMILES: O=C(COc1ccc([S+]2CCCC2)c2ccccc12)OC1C2CC3CC(C2)CC1C3 ; O=C(C[S+]1CCCC1)c1ccccc1 ; CC1(OC(=O)C[S+]2CCCC2)C2CC3CC(C2)CC1C3]

The anion moiety of the sulfonium salt having a cation moiety represented by any one of general formulas (b-5) to (b-8) as a cation moiety thereof is not particularly limited, and the same anion moieties for onium salt-based acid generators which have been proposed may be used. Examples of such anion moieties include fluorinated alkylsulfonic acid ions such as anion moieties (R⁴″SO₃⁻) for onium salt-based acid generators represented by general formula (b-1) or (b-2) shown above; anion moieties represented by general formula (b-3) or (b-4) shown above; and anion moieties represented by formulas (131) to (b9) shown above.

In the present description, an oximesulfonate acid generator is a compound having at least one group represented by general formula (B-1) shown below, and has a feature of generating acid by irradiation. Such oximesulfonate acid generators are widely used for a chemically amplified resist composition, and can be appropriately selected.

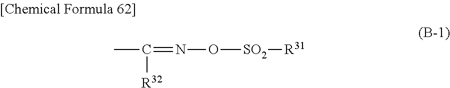

In the formula, R³¹ and R³² each independently represent an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a substituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, particularly preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly preferred. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. As the alkyl group or aryl group for R³², the same alkyl groups or aryl groups as those described above for R³¹ can be used.

As R³², a cyano group, an alkyl group of 1 to 8 carbon atoms having no substituent or a fluorinated alkyl group of 1 to 8 carbon atoms is particularly desirable.

Preferable examples of the oxime sulfonate-based acid generator include compounds represented by general formula (B-2) or (B-3) shown below.

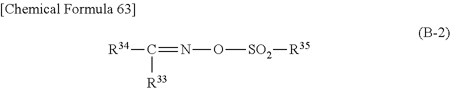

In the formula, R³³ represents a cyano group, an alkyl group having no substituent or a halogenated alkyl group; R³⁴ represents an aryl group; and R⁻³⁵ represents an alkyl group having no substituent or a halogenated alkyl group.

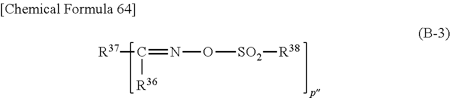

In the formula, R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenantryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyamino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexyl sulfonyl oxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 86) may be preferably used.

Furthermore, as preferable examples, the following can be used.

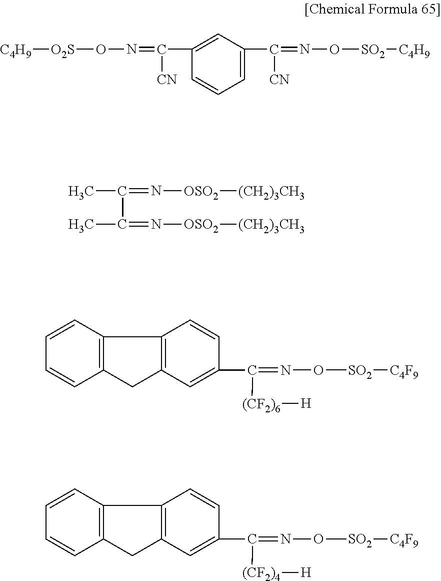

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be mentioned.

As the component (B), one type of acid generator may be used, or two or more types of acid generators may be used in combination.

Among these examples, as the component (B), it is preferable to use an onium salt having a fluorinated alkylsulfonic acid ion as the anion moiety.

In the positive resist composition of the present invention, the amount of the component (B) relative to 100 parts by weight of the component (A) is preferably 0.5 to 50 parts by weight, and more preferably 1 to 40 parts by weight. When the amount of the component (B) is within the above-mentioned range, formation of a resist pattern can be satisfactorily performed. Further, by virtue of the above-mentioned range, a uniform solution can be obtained and the storage stability becomes satisfactory.

### <Component (D1)>

In the resist composition of the present invention, the compound (D1) is a compound composed of a cation moiety which contains a quaternary nitrogen atom, and an anion moiety represented by formula (d1-an1) or (d1-an2) described later.

### (Cation Moiety)

As the cation moiety which contains a quaternary nitrogen atom (N⁺), cation moieties such as a quaternary ammonium cation, a pyridinium cation, a pyridazinium cation, a pyrimidinium cation, a pyrazinium cation, an imidazolium cation, a pyrazolium cation, a thiazolium cation, an oxazolium cation, a triazolium cation, an imidazolinium cation, a methylpyrrolidinium cation, an isothiazolium cation, an isoxazolium cation, an oxazolium cation and a pyrrolium cation can be mentioned. In addition, as the cation moiety, a cation moiety having two or more quaternary nitrogen atoms (N⁺) (preferably, having two quaternary nitrogen atoms) can be also mentioned.

These cation moieties may have a substituent. Here, examples of the substituent include an alkyl group, a cycloalkyl group, an alkenyl group, an aryl group, a hydroxy group, an alkoxy group, a carboxy group, an acyl group, a group consisted of an acyl group and —O— (oxygen atom), and an ester group.

Among these, as the cation moiety for a component (D1), a quaternary ammonium cation is preferable, and a cation represented by formula (d1-c1) shown below is particularly preferable.

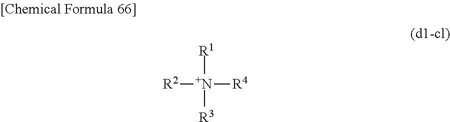

In formula, R¹ to R⁴ each independently represents an alkyl group which may have a substituent, or an aryl group which may have a substituent.

In the aforementioned formula (d1), R¹ to R⁴ each independently represents an alkyl group which may have a substituent or an aryl group which may have a substituent.

The alkyl group for R¹ to R⁴ may be any of linear, branched or cyclic.

The linear alkyl group preferably has 1 to 20 carbon atoms, more preferably 1 to 15 carbon atoms, and still more preferably 1 to 10 carbon atoms, and particularly preferably 1 to 4 carbon atoms. Specific examples include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The cyclic alkyl group is a group containing a saturated hydrocarbon cyclic structure in the structure thereof. As examples of the cyclic alkyl group, a group in which two hydrogen atom have been removed from a saturated hydrocarbon ring (hereafter, referred to as “saturated aliphatic cyclic group”), and a group in which the saturated aliphatic cyclic group is bonded to the terminal of the linear or branched alkyl group or interposed within the aforementioned linear or branched alkyl group, can be given.

The saturated aliphatic cyclic group may be either a monocyclic group or a polycyclic group. Further, the saturated aliphatic cyclic group may be a heterocyclic group having an oxygen atom. The aliphatic cyclic group preferably has 3 to 30 carbon atoms, more preferably 5 to 30, still more preferably 5 to 20, particularly preferably 6 to 15, and most preferably 6 to 12. As the aliphatic cyclic group, a group in which one hydrogen atom has been removed from a monocycloalkane or a polycycloalkane such as a bicycloalkane, tricycloalkane or tetracycloalkane can be used. Specific examples include groups in which one hydrogen atom has been removed from a monocycloalkane such as cyclopentane or cyclohexane; and groups in which one hydrogen atom has been removed from a polycycloalkane such as adamantane, norbornane, isobornane, tricyclodecane or tetracyclododecane.

Examples of the aryl group for R¹ to R⁴ include a phenyl group, a biphenyl group, a fluorenyl group, a naphthyl group, an anthryl group, and a phenantryl group; and heteroaryl groups in which some of the carbon atoms constituting the ring(s) of these aryl groups are substituted with hetero atoms such as an oxygen atom, a sulfur atom, and a nitrogen atom.

The alkyl group or the aryl group for R¹ to R⁴ may have a substituent. Here, the aryl group or the alkyl group “has a substituent” means that part or all of the hydrogen atoms within the hydrocarbon group has been substituted with groups or atoms other than hydrogen atom.

Examples of the substituent include an alkyl group, an alkeny group, an alkyl group containing a quaternary nitrogen atom, a halogen atom, a halogenated alkyl group, a polar group-containing group, an aromatic group, a hydroxy group and a carboxy group.

As the alkyl group, a linear, branched or cyclic alkyl group having 1 to 30 carbon atoms can be mentioned. Preferable examples of the alkyl group include the same alkyl groups as those described above with respect to the alkyl group for R¹ to R⁴.

The alkenyl group may be linear or branched, and preferably a linear alkenyl group in which —CH═CH² group has been introduced at the terminal of a linear alkyl group exemplified in the explanation of alkyl group for R¹ to R⁴. The alkenyl group preferably has 2 to 5 carbon atoms, and more preferably 2 to 4.

As the alkyl group containing a quaternary nitrogen atom, preferable examples include groups in which one hydrogen atom has been removed from any one of the alkyl group for R¹ to R⁴ in the formula (d1-c1). R¹ to R⁴ are the same as defined above.

Examples of the halogen atom include a fluorine atom, a chlorine atom, a bromine atom and an iodine atom, and a fluorine atom is preferable.

As the halogenated alkyl group, a group in which a part or all of the hydrogen atoms of an alkyl group is substituted with halogen atoms can be mentioned. In particular, a fluorinated alkyl group is preferable.

The polar group-containing group is a group containing a polar group in the structure thereof, and may be a group consisting of polar groups or a group composed of a polar group and an atom or group other than the polar group. Examples of the atom or group other than the polar group include a hydrocarbon group such as an alkyl group or an alkylene group. Examples of the alkyl group include the same alkyl groups as those described above with respect to the alkyl group for R¹ to R⁴. With respect to the polar group-containing group, examples of polar groups include an ether bond (—O—), an ester bond, a hydroxy group (—OH), a carbonyl group (—C(═O)—), a carboxy group (—COOH), an oxygen atom (═O), a cyano group (—CN), a lactone ring, an amino group (—NH₂) and an amide group (—NHC(═O)—). In addition, examples of a group composed of a polar group with an atom or a group other than the polar group include an alkyloxy group, a hydroxyalkyloxy group, an alkyloxyalkyloxy group, an alkyloxycarbonyloxy group, an alkoxycarbonylalkyloxy group, an alkyloxycarbonyl group, an acyl group and a group consisted of an acyl group and O(oxygen atom)-.

Examples of the aromatic group include an arylalkyl group such as a benzyl group, a phenethyl group, a 1-naphthylmethyl group, a 2-naphthylmethyl group, a 1-naphthylethyl group or a 2-naphthylethyl group, in addition to aryl groups exemplified in the explanation for R¹ to R⁴. The alkyl chain within the arylalkyl group preferably has 1 to 4 carbon atom, more preferably 1 or 2, and particularly preferably 1. The aromatic group may have a substituent such as an alkyl group of 1 to 10 carbon atoms, a halogenated alkyl group, an alkoxy group, a hydroxyl group or a halogen atom. The alkyl group or halogenated alkyl group as a substituent preferably has 1 to 8 carbon atoms, and more preferably 1 to 4 carbon atoms. Further, the halogenated alkyl group is preferably a fluorinated alkyl group. Examples halogen atoms include a fluorine atom, a chlorine atom, an iodine atom and a bromine atom, and a fluorine atom is preferable.

Specific examples of the canion moiety in the component (D1) are shown below.

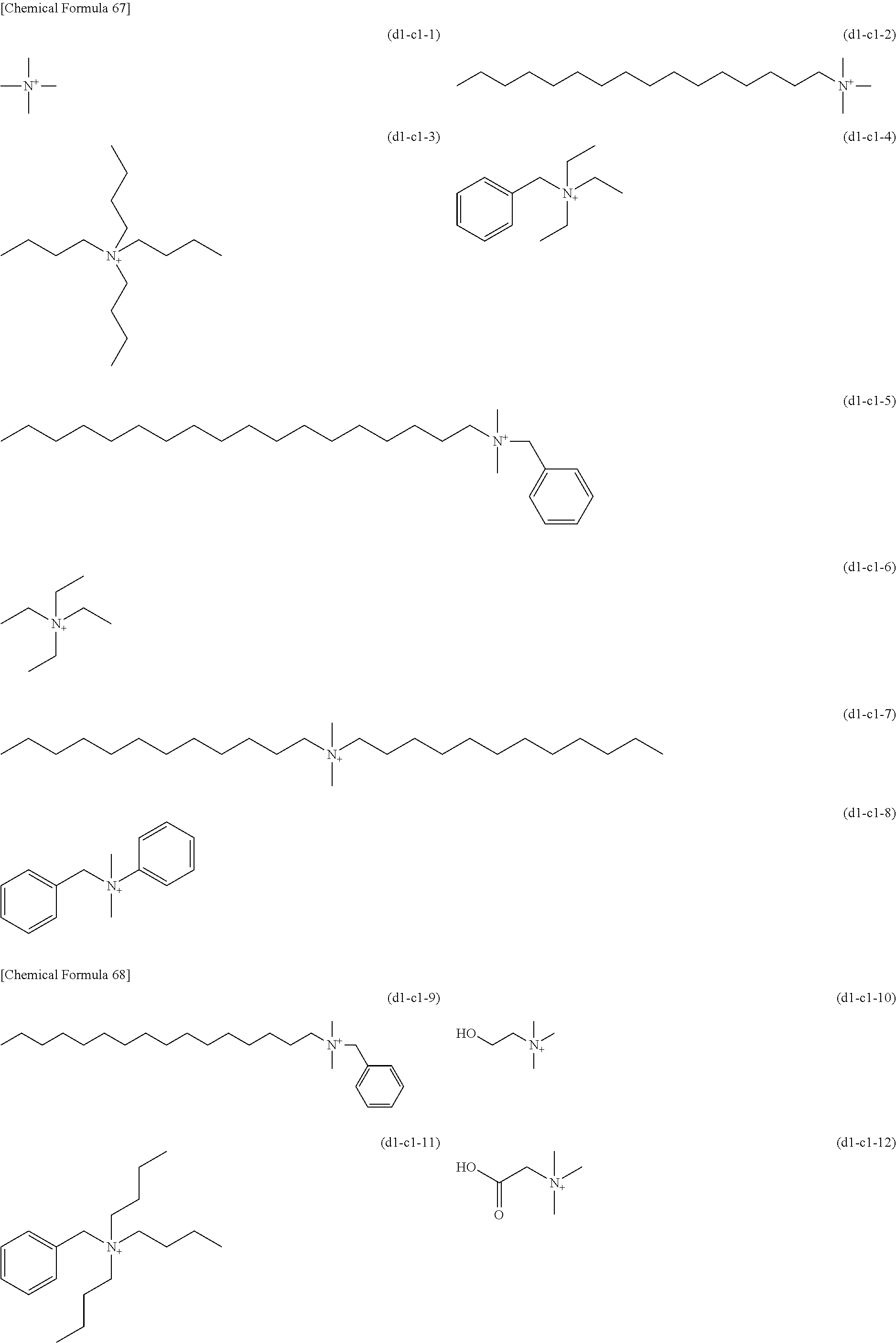

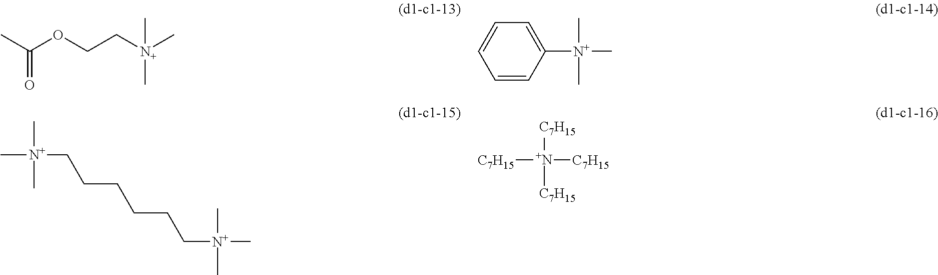

In the present invention, it is preferable that each of R¹ to R⁴ independently represents an alkyl group, and it is more preferable that each of R¹ to R⁴ independently represents a linear alkyl group. Further, it is particularly preferable that all of R¹ to R⁴ are linear alkyl groups.

As a cation moiety in the component (D1), a cation represented by formula (d1-c2) shown below is particularly preferable.

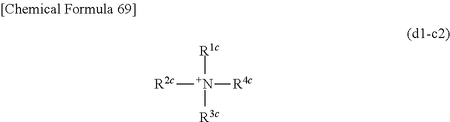

In the formula, each of R^{1C}, R^{2C}, R^{3C} and R^{4C} independently represents a linear alkyl group of 1 to 10 carbon atoms which may have a substituent.

In the formula (d1-c2), each of R^{1C}, R^{2C}, R^{3C} and R^{4C} independently represents a linear alkyl group of 1 to 10 carbon atoms which may have a substituent, preferably a linear alkyl group of 1 to 4 carbon atoms, and n-butyl group is more preferable.

In addition, it is preferable that all of R^{1C}, R^{2C}, R^{3C} and R^{4C} are the same groups, and it is particularly preferable that all of R^{1C}, R^{2C}, R^{3C} and R^{4C} are n-butyl groups.

The substituent is preferably an alkenyl group or an alkyl group containing a quaternary nitrogen atom.

The alkenyl group as a substituent is the same as defined above. The alkyl group containing a quaternary nitrogen atom is preferably a group in which one hydrogen atom has been removed from an alkyl group for R^{1C}, R^{2C}, R^{3C} or R^{4C} in the formula (d1-c2). R^{1C}, R^{2C}, R^{3C} and R^{4C} are the same as defined above.

### (Anion Moiety)

The anion moiety within the compound (D1) is composed of an anion represented by formula (d1-an1) or (d1-an2) shown below:

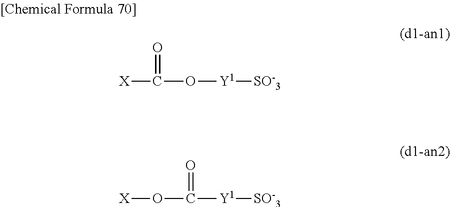

wherein, X represents a cyclic aliphatic hydrocarbon group of 3 to 30 carbon atoms which may have a substituent; and Y¹ represents a fluorinated alkylene group of 1 to 4 carbon atoms which may have a substituent.

In the formulas (d1-an1) and (d1-an2), X represents a cyclic aliphatic hydrocarbon group of 3 to 30 carbon atoms which may have a substituent. Preferable examples for X include the same “cyclic aliphatic hydrocarbon group (aliphatic cyclic group)” as described in the explanation of the hydrocarbon group of 3 to 30 carbon atoms which may have a substituent for X³. In particular, preferable examples of X include a polycyclic aliphatic cyclic group, and specifically a group represented by the aforementioned formula (L2), (L6), (S3) or (S4).

Y¹ represents a fluorinated alkylene group of 1 to 4 carbon atoms which may have a substituent. Y¹ is the same “fluorinated alkylene group of 1 to 4 carbon atoms which may have a substituent” as described in the explanation of the alkylene group of 1 to 4 carbon atoms which may have a substituent or fluorinated alkylene group of 1 to 4 carbon atoms which may have a substituent for Y¹⁰.

As Y¹, a fluorinated alkylene group is preferable, and a fluorinated alkylene group in which the carbon atom bonded to the adjacent sulfur atom is fluorinated is particularly desirable. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, as Y¹, —CF₂—, —CF₂CF₂—, —CF₂CF₂CF₂—, —CH₂CF₂— or CH₂CF₂CF₂— is preferable, —CF₂CF₂—, —CH₂CF₂— or —CF₂CF₂CF₂— is more preferable, and —CH₂CF₂— or —CF₂— is particularly desirable.

The fluorinated alkylene group for Y¹ may have a substituent. When the fluorinated alkylene group “has a substituent”, it means that part or all of the hydrogen atoms and/or fluorine atoms within the fluorinated alkylene group has been substituted with atoms or groups other than a hydrogen atom or a fluorine atom. Examples of substituents which the fluorinated alkylene group may have include an alkyl group of 1 to 4 carbon atoms, an alkoxy group of 1 to 4 carbon atoms and a hydroxyl group.

Preferable examples of anions represented by formula (d1-an1) include anions represented by formula (d1-an1-1) shown below.

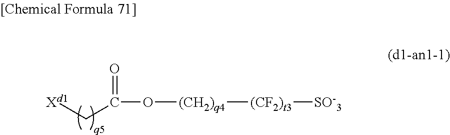

In the formula, q4 represents an integer of 0 to 3; q5 represents an integer of 0 or 1; and t3 represents an integer of 1 to 3, provided that q4+t3=1 to 4; and X^{d1} represents an aliphatic polycyclic group which may have a substituent.

In general formula (d1-an1-1), t3 is the same as defined above for t3 in the aforementioned formula (b3).

q4 is preferably an integer of 0 to 2, more preferably 1 or 2, and particularly preferably 1.

As the aliphatic polycyclic group for X^{d1}, an adamantyl group, a norbornyl group, an isobornyl group, a tricyclodecyl group and a tetracyclododecanyl group are preferable, and an adamantyl group is particularly desirable. Examples of the substituent for substituting X^{d1} include an oxo group and a hydroxy group.

Preferable examples of anions represented by formula (d1-an2) include anions represented by formula (d1-an2-1) shown below.

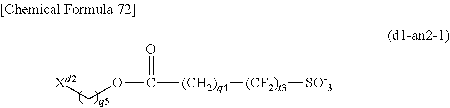

In the formula, q4 represents an integer of 0 to 3; q5 represents an integer of 0 or 1; t3 represents an integer of 1 to 3, provided that q4+t3=1 to 4; and X^{d2} represents an aliphatic polycyclic group which may have a substituent or a group represented by any one of the aforementioned formulas (L1) to (L6) and (S1) to (S4).

In general formula (d1-an2-1), t3 and q4 are the same as defined above for t3 and q4 in formula (d1-an2-1).

The aliphatic polycyclic group which may have a substituent for X^{d2} is the same group defined for X^{d1}. In particular, an adamantyl group and group represented by the aforementioned formula (L2), (L6), (S3) or (S4) are preferable.

Specific examples of the anion moiety in the component (D1) are shown below.

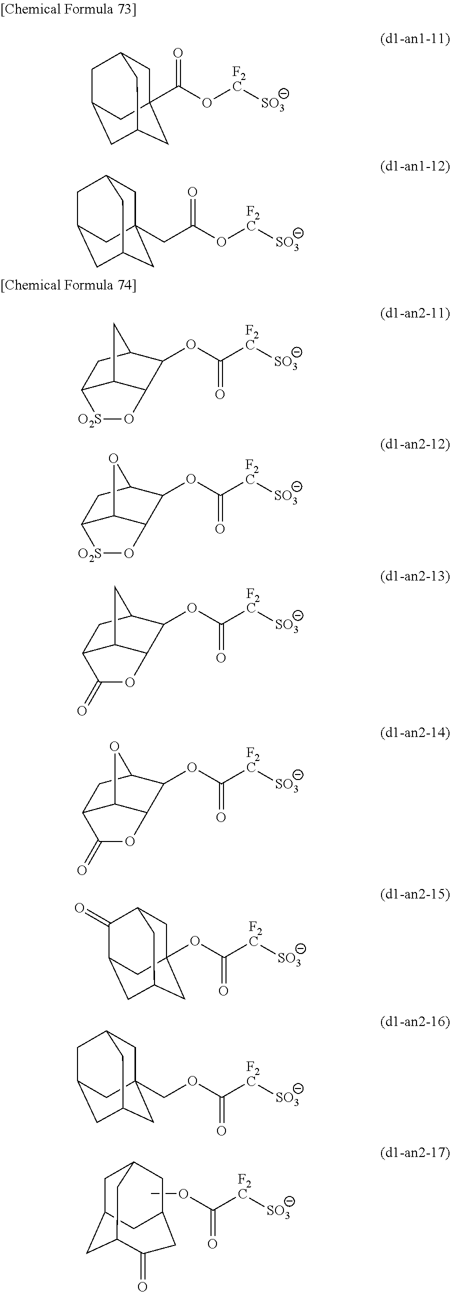

In the resist composition of the present invention, as the compound (D1), one type may be used, or two or more types of compounds may be used in combination.

As the component (D1) composed of the combination of a cation moiety and an anion moiety, a combination of a cation moiety represented by the aforementioned formula (d1-c2) and an anion moiety represented by the aforementioned formula (d1-an1-1), and a combination of a cation moiety represented by the aforementioned formula (d1-c2) and an anion moiety represented by the aforementioned formula (d1-an2-1) are particularly preferred, in terms of the effects of the present invention.

In the resist composition according to the present invention, the amount of the component (D1) relative to 100 parts by weight of the component (A) is preferably 1 to 20 parts by weight, more preferably 3 to 15 parts by weight, and still more preferably 5 to 10 parts by weight. When the amount of the component (D1) is within the above-mentioned range, the effects of the present invention are further improved.

### <Optional Components>

### [Component (C)]

The resist composition of the present invention may contain a basic-compound component (C) (hereafter referred to as “component (C)”) as an optional component. In the present invention, the component (C) functions as an acid diffusion control agent, i.e., a quencher which traps the acid generated from the component (B) upon exposure. In the present invention, a “basic compound” refers to a compound which is basic relative to the component (B).

The component (C) may be a basic compound (C1) (hereafter, referred to as “component (C1)”) which has a cation moiety and an anion moiety, or a basic compound (C2) (hereafter, referred to as “component (C2)”) which does not fall under the definition of component (C1).

### -Component (C1)

In the present invention, it is preferable that the component (C) include at least one member selected from the group consisting of a compound (c1-1) represented by general formula (c1-1) shown below (hereafter, referred to as “component (c1-1)”), a compound (c1-2) represented by general formula (c1-2) shown below (hereafter, referred to as “component (c1-2)”) and a compound (c1-3) represented by general formula (c1-3) shown below (hereafter, referred to as “component (c1-3)”).

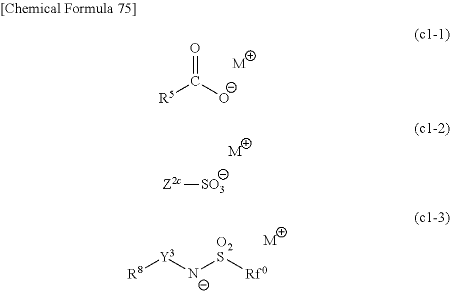

In the formulas, R⁵ represents a hydrocarbon group which may have a substituent; Z^{2C} represents a hydrocarbon group of 1 to 30 carbon atoms which may have a substituent (provided that the carbon atom adjacent to S has no fluorine atom as a substituent); R⁸ represents an organic group; Y³ represents a linear, branched or cyclic alkylene group or an arylene group; Rf⁰ represents a hydrocarbon group containing a fluorine atom; and each of M⁺independently represents a sulfonium cation or a iodonium cation having no aromaticity.
..Component (c1-1)

### (Anion Moiety)

In formula (c1-1), R⁵ represents a hydrocarbon group which may have a substituent.

The hydrocarbon group for R⁵ which may have a substituent may be either an aliphatic hydrocarbon group or an aromatic hydrocarbon group, and the same aliphatic hydrocarbon groups and aromatic hydrocarbon groups as those described above for X³ in the explanation of the aforementioned component (B) can be used.

Among these, as the hydrocarbon group for R⁵ which may have a substituent, an aromatic hydrocarbon group which may have a substituent or an aliphatic cyclic group which may have a substituent is preferable, and a phenyl group or a naphthyl group which may have a substituent, or a group in which one or more hydrogen atoms have been removed from a polycycloalkane such as adamantane, norbornane, isobornane, tricyclodecane or tetracyclododecane is more preferable.

As the hydrocarbon group for R⁵ which may have a substituent, a linear or branched alkyl group or a fluorinated alkyl group is also preferable.

The linear or branched alkyl group for R⁵ preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

The fluorinated alkyl group for R⁵ may be either chain-like or cyclic, but is preferably linear or branched.

The fluorinated alkyl group preferably has 1 to 11 carbon atoms, more preferably 1 to 8, and still more preferably 1 to 4. Specific examples include a group in which part or all of the hydrogen atoms constituting a linear alkyl group (such as a methyl group, an ethyl group, a propyl group, a butyl group, a pentyl group, a hexyl group, a heptyl group, an octyl group, a nonyl group or a decyl group) have been substituted with fluorine atom(s), and a group in which part or all of the hydrogen atoms constituting a branched alkyl group (such as a 1-methylethyl group, a 1-methylpropyl group, a 2-methylpropyl group, a 1-methylbutyl group, a 2-methylbutyl group or a 3-methylbutyl group) have been substituted with fluorine atom(s).

The fluorinated alkyl group for R⁵ may contain an atom other than fluorine atom. Examples of the atom other than fluorine include an oxygen atom, a carbon atom, a hydrogen atom, an oxygen atom, a sulfur atom and a nitrogen atom.

Among these, as the fluorinated alkyl group for R⁵, a group in which part or all of the hydrogen atoms constituting a linear alkyl group have been substituted with fluorine atom(s) is preferable, and a group in which all of the hydrogen atoms constituting a linear alkyl group have been substituted with fluorine atoms (i.e., a perfluoroalkyl group) is particularly preferable.

Specific examples of preferable anion moieties in the component (c1-1) are shown below.

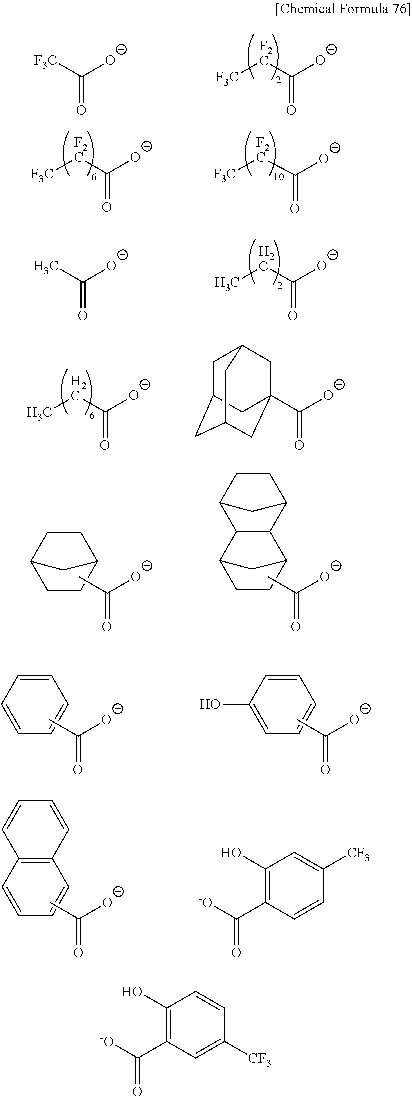

### (Cation Moiety)

In formula (c1-1), M⁺represents an organic cation.

The organic cation for M⁺is not particularly limited, and examples thereof include the same cation moieties as those within compounds represented by the aforementioned formula (b-1) or (b-2).

As the component (c1-1), one type of compound may be used, or two or more types of compounds may be used in combination.

..(Component (c1-2)

### (Anion Moiety)

In formula (c1-2), Z^{2C} represents a hydrocarbon group of 1 to 30 carbon atoms which may have a substituent.

The hydrocarbon group of 1 to 30 carbon atoms for Z^{2C} which may have a substituent may be either an aliphatic hydrocarbon group of 1 to 30 carbon atoms or an aromatic hydrocarbon group of 1 to 30 carbon atoms, and the same aliphatic hydrocarbon groups and aromatic hydrocarbon groups as those described above for X³ in the explanation of the aforementioned component (B) can be used.

Among these, as the hydrocarbon group for Z^{2C} which may have a substituent, an aliphatic cyclic group which may have a substituent is preferable, and a group in which one or more hydrogen atoms have been removed from adamantane, norbornane, isobornane, tricyclodecane, tetracyclododecane or camphor (which may have a substituent) is more preferable.

The hydrocarbon group for Z^{2C} may have a substituent, and the same substituents as those described above for X³ in the explanation of the aforementioned component (B) can be used.

However, in Z^{2C}, the carbon atom adjacent to the sulfur atom within the —SO₃⁻ group has no fluorine atom bonded thereto. By virtue of SO₃⁻ having no fluorine atom adjacent thereto, the anion of the component (c1-2) becomes an appropriately weak acid anion, thereby improving the quenching ability of the component (C).

Specific examples of preferable anion moieties in the component (c1-2) are shown below.

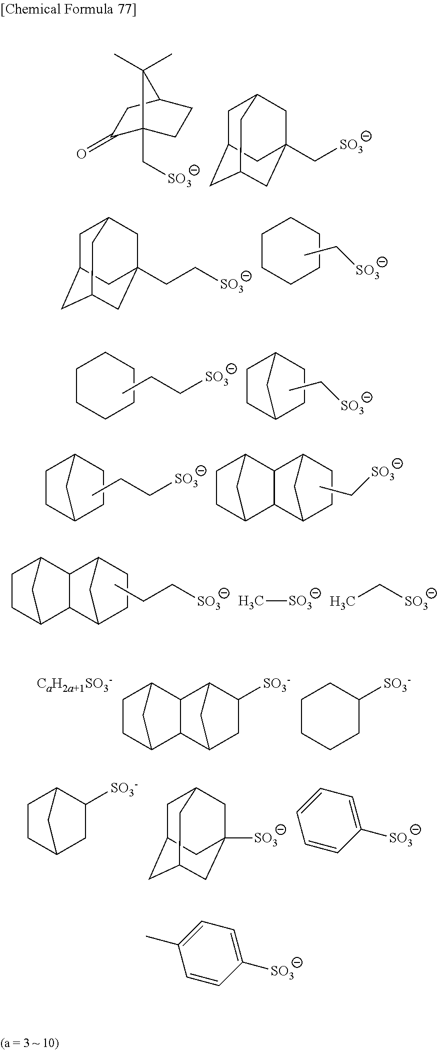

### (Cation Moiety)

In formula (c1-2), M⁺is the same as defined for M⁺in the aforementioned formula (c1-1).

As the component (c1-2), one type of compound may be used, or two or more types of compounds may be used in combination.

..Component (c1-3)

### (Anion Moiety)

In formula (c1-3), R⁸ represents an organic group.

The organic group for R⁸ is not particularly limited, and examples thereof include an alkyl group, an alkoxy group, —O—C(═O)—C(R^{C2})═CH₂ (R^{C2} represents a hydrogen atom, an alkyl group of 1 to 5 carbon atoms or a halogenated alkyl group of 1 to 5 carbon atoms) and —O—C(═O)—R^{C3} (R^{C3} represents a hydrocarbon group).

The alkyl group for R⁸ is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for R⁸ may be substituted with a hydroxy group, a cyano group or the like.

The alkoxy group for R⁸ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are particularly desirable.

When R⁸ is −O—C(═O)—C(R^{C2})═CH₂, R^{C2} represents a hydrogen atom, an alkyl group of 1 to 5 carbon atoms or a halogenated alkyl group of 1 to 5 carbon atoms.

The alkyl group of 1 to 5 carbon atoms for R^{C2} is preferably a linear or branched alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The halogenated alkyl group for R^{C2} is a group in which part or all of the hydrogen atoms of the aforementioned alkyl group of 1 to 5 carbon atoms has been substituted with halogen atoms. Examples of the halogen atom include a fluorine atom, a chlorine atom, a bromine atom and an iodine atom, and a fluorine atom is particularly preferred.

As R^{C2}, a hydrogen atom, an alkyl group of 1 to 3 carbon atoms or a fluorinated alkyl group of 1 to 3 carbon atoms is preferable, and a hydrogen atom or a methyl group is particularly desirable in terms of industrial availability.

When R⁸ is —O—C(═O)—R^{C3}, R^{C3} represents a hydrocarbon group.

The hydrocarbon group for R^{C3} may be either an aromatic hydrocarbon group or an aliphatic hydrocarbon group. Specific examples of the hydrocarbon group for R^{C3} include the same hydrocarbon groups as those described for X³ in the explanation of the component (B).

Among these, as the hydrocarbon group for R^{C3}, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When R^{C3} is an alicyclic group, the resist composition can be satisfactorily dissolved in an organic solvent, thereby improving the lithography properties.

Alternatively, when R^{C3} is an aromatic group, the resist composition exhibits an excellent photoabsorption efficiency in a lithography process using EUV or the like as the exposure source, thereby resulting in the improvement of the sensitivity and the lithography properties.

Among these, as R⁸, —O—C(═O)—C(R^{C2}′)═CH₂ (R^{C2}′ represents a hydrogen atom or a methyl group) or —O—C(═O)—R^{C3}′ (R^{C3}′ represents an aliphatic cyclic group) is preferable.

In formula (c1-3), Y³ represents a linear, branched or cyclic alkylene group or an arylene group.

Examples of the linear, branched or cyclic alkylene group or the arylene group for Y³ include the “linear or branched aliphatic hydrocarbon group”, “aliphatic hydrocarbon group containing a ring in the structure thereof” and “aromatic hydrocarbon group” described above as the divalent linking group for Y² in the aforementioned formula (a11-0-2).

Among these, as Y³, an alkylene group is preferable, a linear or branched alkylene group is more preferable, and a methylene group or an ethylene group is still more preferable.

In formula (c1-3), Rf⁰ represents a hydrocarbon group containing a fluorine atom.

The hydrocarbon group containing a fluorine atom for Rf⁰ is preferably a fluorinated alkyl group.

As the fluorinated alkyl group, the same fluorinated alkyl groups as those described above for R⁵ can be used.

Specific examples of preferable anion moieties in the component (c1-3) are shown below.

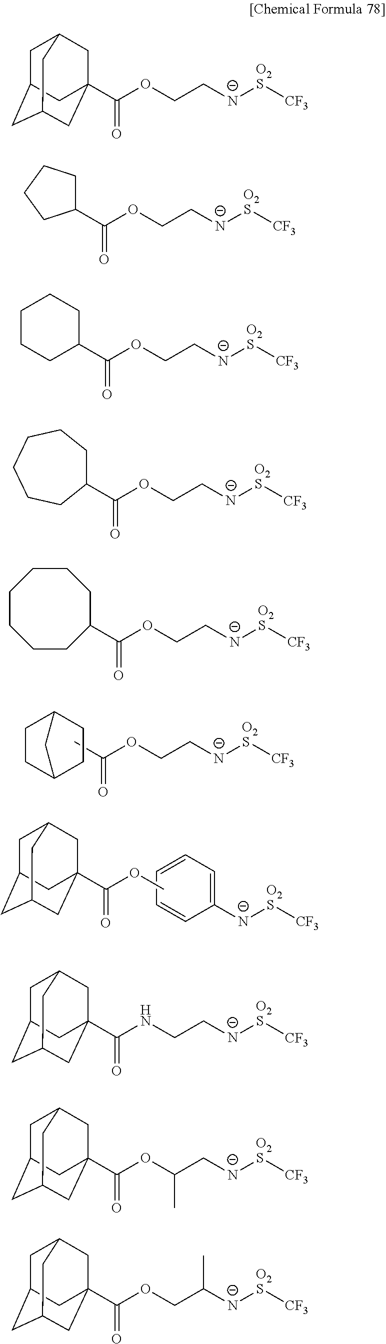

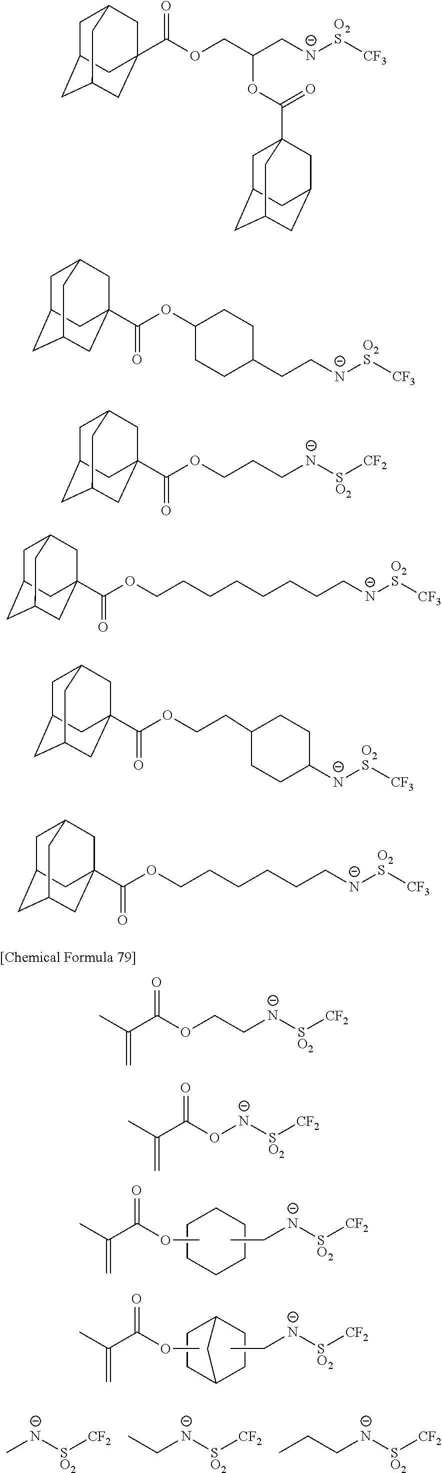

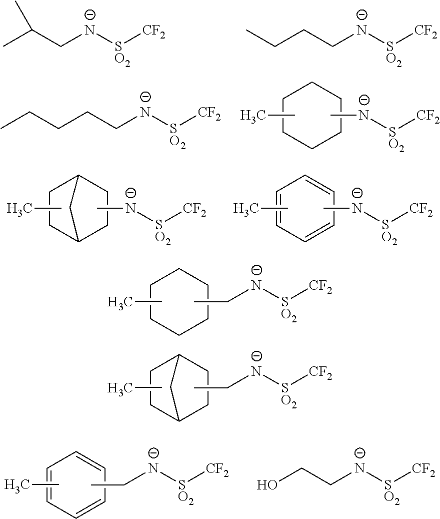

### (Cation Moiety)

In formula (c1-3), M⁺is the same as defined for M⁺in the aforementioned formula (c1-1).

As the component (c1-3), one type of compound may be used, or two or more types of compounds may be used in combination.

The component (C1) may contain one of the aforementioned components (c1-1) to (c1-3), or at least two of the aforementioned components (c1-1) to (c1-3).

The amount of the component (C1) (that is, the total amount of the components (c1-1) to (c1-3)) relative to 100 parts by weight of the component (A) is preferably within a range from 0.5 to 10.0 parts by weight, more preferably from 0.5 to 8.0 parts by weight, and still more preferably from 1.0 to 8.0 parts by weight.

When the amount of the component (C1) is at least as large as the lower limit of the above-mentioned range, excellent lithography properties and excellent resist pattern shape can be obtained. On the other hand, when the amount of the component (C1) is no more than the upper limit of the above-mentioned range, sensitivity can be maintained at a satisfactory level, and throughput becomes excellent.

### [Production Method of Component (C1)]

The production methods of the components (c1-1) and (c1-2) are not particularly limited, and the components (c1-1) and (c1-2) can be produced by conventional methods.

The production method of the compound (C1-3) of the present invention is not particularly limited. For example, in the case where R⁸ in formula (c1-3) is a group having an oxygen atom on the terminal thereof which is bonded to Y³, the compound (c1-3) represented by general formula (c1-3) can be produced by reacting a compound (i-1) represented by general formula (i-1) shown below with a compound (i-2) represented by general formula (i-2) shown below to obtain a compound (i-3) represented by general formula (i-3) shown below, and then reacting the compound (i-3) with a compound (i-4) represented by B⁻M⁺having the desired cation M⁺thereby obtaining the compound (c1-3).

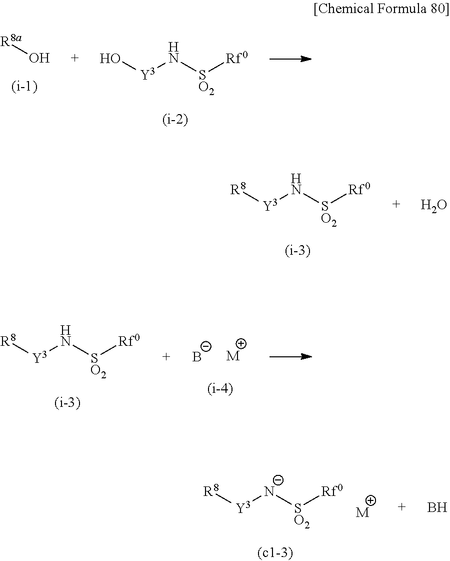

In the formulas, R⁸, Y³, Rf⁰ and M⁺are respectively the same as defined for R⁸, Y³ and Rf, M⁺in the aforementioned general formula (c1-3); R^{8a} represents a group in which the terminal oxygen atom has been removed from R⁸; and B⁻ represents a counteranion.

Firstly, the compound (i-1) is reacted with the compound (i-2), thereby obtaining the compound (i-3).

In formula (i-1) R^{8a} represents a group in which the terminal oxygen atom has been removed from R⁸, and R⁸ is the same as described above. In formula (i-2), Y³ and Rf⁰ are the same as defined above.

As the compound (i-1) and the compound (i-2), commercially available compounds may be used, or the compounds may be synthesized.

The method for reacting the compound (i-1) with the compound (i-2) to obtain the compound (i-3) is not particularly limited, but can be performed, for example, by reacting the compound (i-1) with the compound (i-2) in an organic solvent in the presence of an appropriate acidic catalyst, followed by washing and recovering the reaction mixture.

The acidic catalyst used in the above reaction is not particularly limited, and examples thereof include toluenesulfonic acid and the like. The amount of the acidic catalyst is preferably 0.05 to 5 moles, per 1 mole of the compound (i-2).

As the organic solvent used in the above reaction, any organic solvents which are capable of dissolving the raw materials, i.e., the compound (i-1) and the compound (i-2) can be used, and specific examples thereof include toluene and the like. The amount of the organic solvent is preferably 0.5 to 100 parts by weight, more preferably 0.5 to 20 parts by weight, relative to the amount of the compound (i-1). As the solvent, one type may be used alone, or two or more types may be used in combination.

In general, the amount of the compound (i-2) used in the above reaction is preferably 0.5 to 5 moles per 1 mole of the compound (i-1), and more preferably 0.8 to 4 moles per 1 mole of the compound (i-1).

The reaction time varies depending on the reactivity of the compounds (i-1) and (i-2), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

Next, the obtained compound (i-3) is reacted with the compound (i-4), thereby obtaining the compound (c1-3).

In formula (i-4), M⁺ is the same as defined above, and Z⁻ represents a counteranion.

The method for reacting the compound (i-3) with the compound (i-4) to obtain the compound (c1-3) is not particularly limited, but can be performed, for example, by dissolving the compound (i-3) in an organic solvent and water in the presence of an appropriate alkali metal hydroxide, followed by addition of the compound (i-4) and stirring.

The alkali metal hydroxide used in the above reaction is not particularly limited, and examples thereof include sodium hydroxide, potassium hydroxide and the like. The amount of the alkali metal hydroxide is preferably 0.3 to 3 moles, per 1 mole of the compound (i-3).

Examples of the organic solvent used in the above reaction include dichloromethane, chloroform, ethyl acetate and the like. The amount of the organic solvent is preferably 0.5 to 100 parts by weight, and more preferably 0.5 to 20 parts by weight, relative to the amount of the compound (i-3).

As the solvent, one type may be used alone, or two or more types may be used in combination.

In general, the amount of the compound (i-4) used in the above reaction is preferably 0.5 to 5 moles per 1 mole of the compound (i-3), and more preferably 0.8 to 4 moles per 1 mole of the compound (i-3).

The reaction time depends on the reactivity of the compounds (i-3) and (i-4), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

After the reaction, the compound (c1-3) contained in the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The structure of the compound (c1-3) obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

### -Component (C2)

The component (C2) is not particularly limited, as long as it is a compound which is basic relative to the component (B), so as to functions as an acid diffusion inhibitor, and does not fall under the definition of the component (C1). As the component (C2), any of the conventionally known compounds may be selected for use. Among these, an aliphatic amine, particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine. Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-[2-(2-hydroxyethoxy)ethoxy]ethyl]amine and triethanolamine triacetate, and triethanolamine triacetate is preferable.

Further, as the component (C2), an aromatic amine may be used.

Examples of aromatic amines include aniline, pyridine, 4-dimethylaminopyridine, pyrrole, indole, pyrazole, imidazole and derivatives thereof, diphenylamine, triphenylamine, tribenzylamine, 2,6-diisopropylaniline and N-tert-butoxycarbonylpyrrolidine.

As the component (C), one type of acid generator may be used, or two or more types may be used in combination.

The component (C2) is typically used in an amount within a range from 0.01 to 5.0 parts by weight, relative to 100 parts by weight of the component (A). When the amount of the component (C2) is within the above-mentioned range, the shape of the resist pattern and the post exposure stability of the latent image formed by the pattern-wise exposure of the resist layer are improved.

As the component (C2), one type of compound may be used, or two or more types of resins may be used in combination.

When the resist composition of the present invention contains the component (C), the amount of the component (C) (that is, the total amount of the components (C1) and (C2)) relative to 100 parts by weight of the component (A) is preferably within a range from 0.05 to 15 parts by weight, more preferably from 0.1 to 15 parts by weight, and still more preferably from 0.1 to 12 parts by weight. When the amount of the component (C) is at least as large as the lower limit of the above-mentioned range, various lithography properties (such as roughness) of the resist composition are improved. Further, a resist pattern having an excellent shape can be obtained. On the other hand, when the amount of the component (C1) is no more than the upper limit of the above-mentioned range, sensitivity can be maintained at a satisfactory level, and throughput becomes excellent.

### [Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

As the component (E), salicylic acid is particularly desirable.

As the component (E), one type may be used alone, or two or more types may be used in combination.

The component (E) is typically used in an amount within a range from 0.01 to 5.0 parts by weight, relative to 100 parts by weight of the component (A).

### [Component (F)]

The resist composition may further include a fluorine additive (hereafter, referred to as “component (F)”) for imparting water repellency to the resist film. As the component (F), for example, a fluorine-containing polymeric compound described in Japanese Unexamined Patent Application, First Publication No. 2010-002870.

As the component (F), a polymer having a structural unit represented by general formula (f1-1) shown below can be used. The polymer is preferably a polymer (homopolymer) consisting of a structural unit represented by formula (f1-1) shown below; a copolymer of a structural unit represented by formula (f1-1) shown below and the aforementioned structural unit (a1); or a copolymer of a structural unit represented by formula (f1-1) shown below, a structural unit derived from acrylic acid or methacrylic acid and the aforementioned structural unit (a1). As the structural unit (a1) to be copolymerized with a structural unit represented by formula (f1-1) shown below, a structural unit represented by the aforementioned formula (a11-1) is preferable, and a structural unit represented by the aforementioned formula (a1-1-32) is particularly preferable.

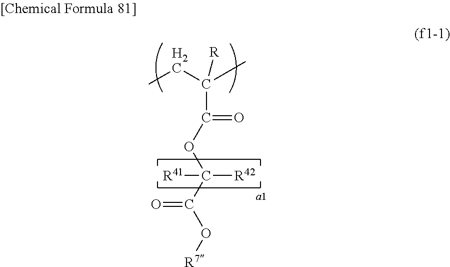

In the formula, R is the same as defined above; each of R⁴¹ and R⁴² independently represents a hydrogen atom, a halogen atom, an alkyl group of 1 to 5 carbon atoms or a halogenated alkyl group of 1 to 5 carbon atoms, provided that the plurality of R⁴¹ to R⁴² may be the same or different from each other; a1 represents an integer of 1 to 5; and R⁷″ represents an organic group containing a fluorine atom.

In formula (f1-1), R is the same as defined above. As R, a hydrogen atom or a methyl group is preferable.

In formula (f1-1), examples of the halogen atom for R⁴¹ and R⁴² include a fluorine atom, a chlorine atom, a bromine atom and an iodine atom, and a fluorine atom is particularly desirable. Examples of the alkyl group of 1 to 5 carbon atoms for R⁴¹ and R⁴² include the same alkyl group of 1 to 5 carbon atoms as those defined above for R, and a methyl group or an ethyl group is preferable. Specific examples of the halogenated alkyl group of 1 to 5 carbon atoms represented by R⁴¹ or R⁴² include groups in which part or all of the hydrogen atoms of the aforementioned alkyl groups of 1 to 5 carbon atoms have been substituted with halogen atoms. Examples of the halogen atom include a fluorine atom, a chlorine atom, a bromine atom and an iodine atom, and a fluorine atom is particularly preferred. Among these, R⁴¹ and R⁴² are preferably a hydrogen atom, a fluorine atom or an alkyl group of 1 to 5 carbon atoms, and more preferably a hydrogen atom, a fluorine atom, a methyl group or an ethyl group.

In formula (f1-1), a1 represents an integer of 1 to 5, preferably an integer of 1 to 3, and more preferably 1 or 2.

In formula (f1-1), R⁷″ represents an organic group containing a fluorine atom, and is preferably a hydrocarbon group containing a fluorine atom.

The hydrocarbon group containing a fluorine atom may be linear, branched or cyclic, and preferably has 1 to 20 carbon atoms, more preferably 1 to 15 carbon atoms, and particularly preferably 1 to 10 carbon atoms.

The hydrocarbon group having a fluorine atom preferably has 25% or more of the hydrogen atoms within the hydrocarbon group fluorinated, more preferably 50% or more, and particularly preferably 60% or more, as the hydrophobicity of the resist film during immersion exposure is enhanced.

As R⁷″, a fluorinated hydrocarbon group of 1 to 5 carbon atoms is particularly preferable, and most preferably methyl group, —CH₂—CF₃, —CH₂—CF₂—CF₃, —CH(CF₃)₂, —CH₂—CH₂—CF₃ and —CH₂—CH₂—CF₂—CF₂—CF₂—CF₃.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight of the polymer is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5.

The component (F) can be produced by a conventional radical polymerization or the like of the monomers corresponding with each of the structural units, using a radical polymerization initiator such as dimethyl 2,2′-azobis(isobutyrate) (V-601) or azobisisobutyronitrile (AIBN). By using a chain transfer agent such as HS—CH₂—CH₂—CH₂—C(CF₃)₂—OH, a —C(CF₃)₂—OH group can be introduced at the terminals. Such a copolymer having introduced a hydroxyalkyl group in which some of the hydrogen atoms of the alkyl group are substituted with fluorine atoms is effective in reducing defects and LER (line edge roughness: unevenness of the side walls of a line pattern).

As the monomers which yield the corresponding structural units, commercially available monomers may be used, or the monomers may be synthesized by a conventional method.

As the component (F), one type may be used alone, or two or more types may be used in combination.

The component (F) is used in an amount within a range from 0.5 to 10 parts by weight, relative to 100 parts by weight of the component (A).

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

### [Component (5)]

The resist composition according to the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These solvents can be used individually, or in combination as a mixed solvent.

Among these, propylene glycol monomethyl ether acetate (PGMEA), propylene glycol monomethyl ether (PGME), cyclohexanone and γ-butyrolactone are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

Furthermore, as the component (5), a mixed solvent of PGMEA and cyclohexanone or a mixed solvent of PGMEA, PGME and cyclohexanone is also preferable. The former mixing ratio of such a mixed solvent is preferably PGMEA:cyclohexanone=95-5:10-90, whereas the latter mixing ratio of such a mixed solvent is preferably PGMEA:PGME:cyclohexanone=35-55:20-40:15-35.

The amount of the component (S) is not particularly limited, and is appropriately adjusted to a concentration which enables coating of a coating solution to a substrate. In general, the organic solvent is used in an amount such that the solid content of the resist composition becomes within the range from 1 to 20% by weight, and preferably from 2 to 15% by weight.

The resist composition according to the present invention is superior in depth of focus (DOF) and mask error factor (MEF). The reason why these effects can be achieved has not been elucidated yet, but is presumed as follows.

As miniaturization of resist patterns progresses, when forming a resist pattern, there is a situation where an exposure light is less likely to reach to a substrate, and therefore acid is less likely to be diffused to the vicinity of the interface between the resist film and the substrate. For this reason, it becomes difficult to form a resist pattern with a high resolution, and therefore, improvement in lithography properties such as mask error factor (MEF) and depth of focus (DOF) is required.

In order to improve MEF, it is effective to suppress the diffusion of the acid generated from the acid generator component upon exposure. On the other hand, in order to improve DOF properties, it is effective to blend a large amount of acid generator component so as to increase the amount of acid generated from the acid generator component upon exposure, and thereby expanding the range of acid diffusion. However, by expanding the range of acid diffusion, MEF is likely to be deteriorated. In this way, DOF properties and MEF are in a trade-off relationship.

The resist composition according to the present invention contains a compound (D1) including a cation moiety which contains a quaternary nitrogen atom, and an anion moiety having a specific structure, in addition to a base component (A) and an acid generator component (B). The anion moiety within the component (D1) is a sulfonate ion to which a fluorinated alkylene group is bonded, and the acid of the sulfonate ion can become the same as the acid generated from the component (B). The component (D1), unlike the component (B), is not a component which generates acid upon exposure. It is presumed that, by virtue of the presence of the component (D1) at exposed portions, the diffusion length of the acid generated at exposed portions increases, without increasing the concentration of acid (as compared to in the case where using a resist composition which does not contain the component (D1) is used). Therefore, it is presumed that the acid can be diffused to the vicinity of the interface between the resist film and substrate where exposure light is difficult to reach. As a result, the DOF properties can be improved. In addition, according to the resist composition of the present invention, it is not necessary to blend a large amount of acid generator component as before, and the amount of acid generated from the acid generator component upon exposure is not increased but maintained to a certain amount, and therefore does not affect to MEF.

As described above, it is presumed that the resist composition of the present invention can maintain MEF, and improve DOF properties, and therefore achieve both excellent DOF properties and excellent MEF.

Furthermore, from the relationship between the component (B) and component (D1), it is presumed that the effect of the present invention is further improved, by using the component (D1) with the component (B) having an anion moiety that is the similar structure as the structure of anion moiety in the component (D1).

Moreover, by using the resist composition of the present invention, a hole pattern having high circularity can be formed.

### <<Method of Forming a Resist Pattern>>

The method of forming a resist pattern according to the present invention includes: forming a resist film on a substrate using a resist composition of the present invention; conducting exposure of the resist film; and developing the resist film to form a resist pattern.

The method for forming a resist pattern according to the present invention can be performed, for example, as follows.

Firstly, a resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such as an ArF exposure apparatus, an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment.

The developing treatment is conducted using an alkali developing solution in the case of an alkali developing process, whereas the developing treatment is conducted using a developing solution containing an organic solvent (organic developing solution) in the case of a solvent developing process.

After the developing treatment, it is preferable to conduct a rinse treatment. The rinse treatment is preferably conducted using pure water in the case of an alkali developing process, whereas the rinse treatment is preferably conducted using a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV.

The exposure of the resist film can be either a general exposure (dry exposure) conducted in air or an inert gas such as nitrogen, or immersion exposure (liquid immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used which are capable of dissolving the component (A) (prior to exposure). Specific examples of the organic solvent include polar solvents such as ketone solvents, ester solvents, alcohol solvents, amide solvents and ether solvents, and hydrocarbon solvents.

If desired, the organic developing solution may have a conventional additive blended. Examples of the additive include surfactants. The surfactant is not particularly limited, and for example, an ionic or non-ionic fluorine surfactant and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone solvents, ester solvents, alcohol solvents, amide solvents and ether solvents is used. Among these, at least one solvent selected from the group consisting of hydrocarbon solvents, ketone solvents, ester solvents, alcohol solvents and amide solvents is preferable, more preferably at least one solvent selected from the group consisting of alcohol solvents and ester solvents, and an alcohol solvent is particularly desirable.

The rinse treatment (washing treatment) using the rinse liquid can be performed by a conventional rinse method. Examples thereof include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

### Production of Resist Composition (1)

### Examples 1 and 2, Comparative Examples 1 and 2

The components shown in Table 1 were mixed together and dissolved to obtain resist compositions.

TABLE 1

| | Component | Component | | Component | Component | Component | Component |
|---|---|---|---|---|---|---|---|
| | (A) | (B) | | (D) | (C) | (F) | (S) |
| Example 1 | (A)-1 | (B)-1 | (B)-2 | (D1)-1 | (C)-1 | (F)-1 | (S)-1 |
| | [100] | [11.5] | [1.9] | [8.3] | [3.0] | [2.5] | [2700] |
| Example 2 | (A)-1 | (B)-1 | (B)-2 | (D1)-2 | (C)-1 | (F)-1 | (S)-1 |
| | [100] | [11.5] | [1.9] | [8.3] | [3.0] | [2.5] | [2700] |
| Comparative | (A)-1 | (B)-1 | (B)-2 | — | (C)-1 | (F)-1 | (S)-1 |
| Example 1 | [100] | [11.5] | [1.9] | | [3.0] | [2.5] | [2700] |
| Comparative | (A)-1 | (B)-1 | (B)-2 | (D2)-1 | (C)-1 | (F)-1 | (S)-1 |
| Example 2 | [100] | [11.5] | [1.9] | [8.3] | [3.0] | [2.5] | [2700] |

In Table 1, the reference characters indicate the following. Further, the values in brackets [ ] indicate the amount (in terms of parts by weight) of the component added.

(A)-1: a polymeric compound represented by formula (A)-1 shown below; l/m/n/o=45/40/5/10, Mw=5,500, Mw/Mn=1.42

(B)-1: a compound represented by chemical formula (13)-1 shown below

(B)-2: a compound represented by chemical formula (B)-2 shown below

(D1)-1: a compound represented by chemical formula (D1)-1 shown below

(D1)-2: a compound represented by chemical formula (D1)-2 shown below

(D2)-1: a compound represented by chemical formula (D2)-1 shown below

(C)-1: a compound represented by chemical formula (C)-1 shown below

(F)-1: a polymeric compound represented by formula (F)-1 shown below; 1=100 (molar ratio), Mw=125,000, Mw/Mn=1.35

(S)-1: a mixed solvent of PGMEA/PGME/cyclohexanone=30/45/25 (weight ratio)

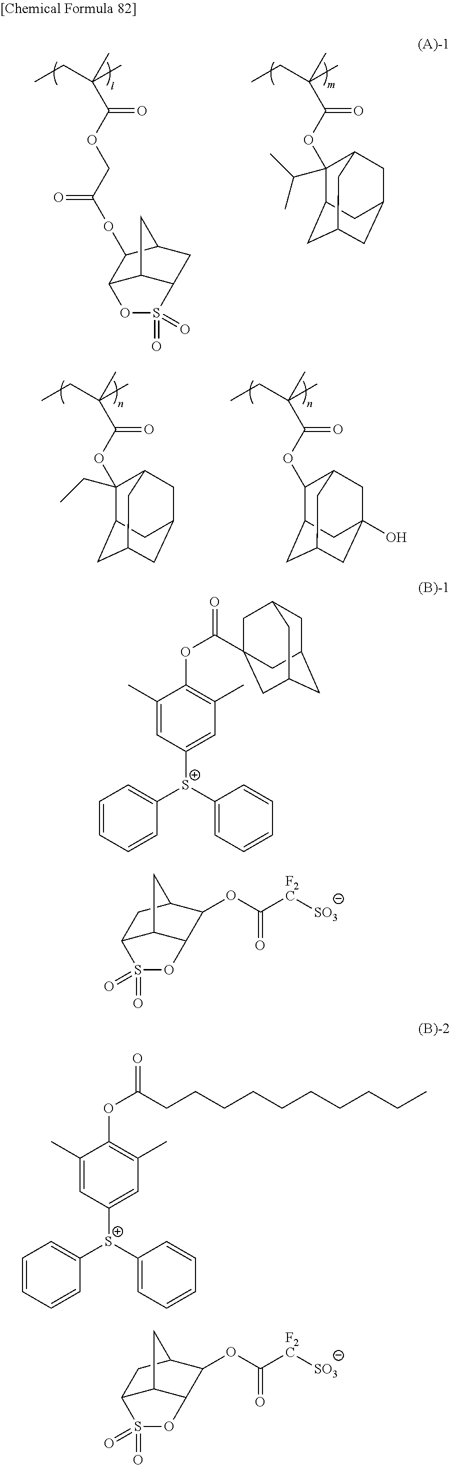

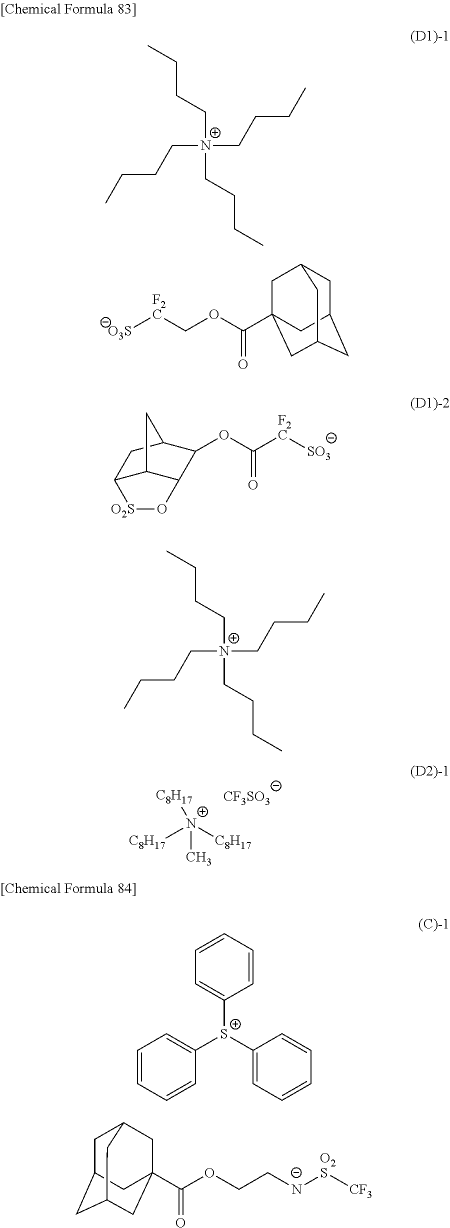

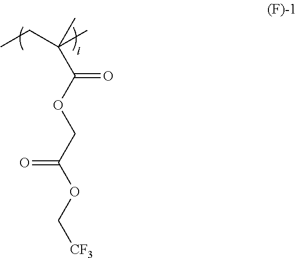

### <Formation of Resist Pattern (1)>

Using the obtained resist compositions, resist patterns were formed, and the following lithography properties were evaluated.

An organic anti-reflection film composition (product name: ARC29A, manufactured by Brewer Science Ltd.) was applied to an 8-inch silicon wafer using a spinner, and the composition was then baked at 205° C. for 60 seconds on a hotplate, thereby forming an organic anti-reflection film having a film thickness of 89 nm.

Then, the resist composition was applied onto the anti-reflection film using a spinner, and was then prebaked (PAB) on a hotplate at 80° C. for 60 seconds and dried, thereby forming a resist film having a film thickness of 100 nm.

Then, the resist film was selectively irradiated with an ArF excimer laser (193 nm) through a binary mask for forming a hole pattern, using an ArF exposure apparatus NSR-S609B (manufactured by Nikon Corporation, NA (numerical aperture)=1.07, Annular (out-0.97/In-0.78)w/XY-Pol. immersion medium: water).

Next, a post exposure bake (PEB) treatment was conducted at 80° C. for 60 seconds, followed by development for 20 seconds at 23° C. in a 2.38% by weight aqueous solution of tetramethylammonium hydroxide (TMAH) (product name: NMD-W; manufactured by Tokyo Ohka Kogyo Co., Ltd.). Then, the resist film was rinsed for 30 seconds with pure water, followed by drying by shaking.

Further, a post bake was conducted at 100° C. for 45 seconds on the hot plate.

Each of the contact hole patterns having target size recited in following conditions 1) to 3) was formed, according to the aforementioned method of forming a resist pattern.

1) a hole diameter (CD) of 65 nm and a pitch of 113.75 nm

2) a hole diameter (CD) of 70 nm and a pitch of 122.5 nm

3) a hole diameter (CD) of 75 nm and a pitch of 160 nm

### [Optimum Exposure Dose (EOP)]

The optimum exposure dose EOP (mJ/cm²; sensitivity) with which the hole pattern having each of the target sizes could be formed according to the aforementioned method of forming a resist pattern, was determined. The results are shown in Table 2.

### [Evaluation of Mask Error Factor (MEF)]

With the above EOP, with respect to each target size, 11 contact hole patterns were formed by varying the hole diameter within the range of ±5 nm of each target size (at intervals of 1 nm) with the pitch fixed. For example, in the case of the target size of the aforementioned condition 1), each of contact hole patterns having a hole diameter of 60 to 70 nm (at intervals of 1 nm) and a pitch of 113.75 nm was formed.

The value of the mask error factor (MEF) was determined as the gradient of a graph obtained by plotting the target size (nm) on the horizontal axis, and the actual hole diameter (nm) of the formed contact hole patterns on the vertical axis. The results are shown in Table 2.

A gradient of the plotted line (MEF) closer to 1 indicates that a resist pattern faithful to the mask pattern was formed.

### [Evaluation of Depth of Focus (DOF)]

With the above-mentioned EOP, the focus was appropriately shifted up and down and resist patterns were formed in the same manner as in the aforementioned method of forming a resist pattern, and the depth of focus (unit: μm) with which a contact hole having a hole diameter (CD) in the range of the target size ±5% could be formed was determined. The results are shown in Table 2.

For example, in the case of the target size of the aforementioned condition 1), the depth of focus (unit: μm) with which a contact hole pattern having a hole diameter (CD) in the range of the target size (i.e., 65 nm) ±5% (that is, in the range from 61.75 to 68.25 nm) could be formed was determined.

### [Evaluation of Circularity]

Each of the contact hole patterns formed in each of the target sizes with the above EOP was observed from the upper side thereof using a measuring scanning electron microscope (SEM) (pressurization voltage: 300 V, product name: S-9380, manufactured by Hitachi High-Technologies Corporation), and with respect to each of 25 holes, the distance from the center of the hole to the outer periphery thereof was measured in 24 directions. From the results, the value of 3 times the standard deviation 6 (i.e., 36) was calculated. The results are shown in Table 2.

The smaller this 36 value is, the higher the level of circularity of the holes.

### [Evaluation of CD Uniformity (CDU)]

With respect to each of the contact hole patterns formed in each of the target sizes with the above EOP, the hole diameter (CD) of 100 holes were measured. From the results, the value of 3 times the standard deviation σ (i.e., 3σ) was calculated. The results are shown in Table 2.

The smaller this 3σ value is, the higher the level of the uniformity of diameter of holes formed in the resist film.

TABLE 2

| | | Compar- | Compar- | | |
|---|---|---|---|---|---|
| | | ative | ative | | |
| Target | | Example | Example | Example | Example |
| Size | | 1 | 2 | 1 | 2 |
| Hole | EOP (mJ/cm²) | 25.1 | 26.6 | 25.6 | 27.6 |
| Diameter: 65 nm | MEF | 3.87 | 3.88 | 3.89 | 3.90 |
| Pitch: 113.75 nm | DOF(μm) | 0.38 | 0.38 | 0.40 | 0.40 |
| | Circularity | 3.00 | 2.90 | 2.89 | 2.82 |
| Hole | CDU | 4.80 | 4.50 | 4.30 | 4.20 |
| Diameter: 70 nm | | | | | |
| Pitch: 122.5 nm | | | | | |
| Hole | EOP (mJ/cm²) | 25.6 | 25.8 | 25.9 | 28.0 |
| Diameter: 75 nm | MEF | 2.63 | 2.64 | 2.64 | 2.65 |
| Pitch: 160 nm | DOF(μm) | 0.18 | 0.18 | 0.20 | 0.20 |
| | Circularity | 2.38 | 2.38 | 2.37 | 2.36 |

From the results shown in Table 2, it was confirmed that in forming a hole pattern, the resist compositions of Examples 1 and 2 were improved in depth of focus (DOF) properties with maintaining excellent mask error factor (MEF), as compared to the resist compositions of Comparative Examples 1 and 2.

### Production of Resist Composition (2)

### Examples 3 to 6 and Comparative Example 3

The components shown in Table 3 were mixed together and dissolved to obtain resist compositions.

TABLE 3

| | Component | Component | Component | Component | Component | Component |
|---|---|---|---|---|---|---|
| | (A) | (B) | (D) | (C) | (F) | (S) |
| Comparative | (A)-2 | (B)-3 | — | (C)-2 | (F)-2 | (S)-2 |
| Example 3 | [100] | [6.0] | | [3.5] | [1.5] | [2200] |
| Example 3 | (A)-2 | (B)-3 | (D1)-2 | (C)-2 | (F)-2 | (S)-2 |
| | [100] | [6.0] | [4.0] | [3.5] | [1.5] | [2200] |
| Example 4 | (A)-2 | (B)-3 | (D1)-2 | (C)-2 | (F)-2 | (S)-2 |
| | [100] | [6.0] | [8.0] | [3.5] | [1.5] | [2200] |
| Example 5 | (A)-2 | (B)-4 | (D1)-2 | (C)-2 | (F)-2 | (S)-2 |
| | [100] | [6.88] | [4.0] | [3.5] | [1.5] | [2200] |
| Example 6 | (A)-3 | (B)-3 | (D1)-2 | (C)-2 | (F)-2 | (S)-2 |
| | [100] | [6.0] | [4.0] | [3.5] | [1.5] | [2200] |

In Table 3, the reference characters indicate the following. Further, the values in brackets [ ] indicate the amount (in terms of parts by weight) of the component added.

(A)-2: a polymeric compound represented by formula (A)-2 shown below; l/m/n=50/40/10, Mw=10,000, Mw/Mn=1.5

(A)-3: a polymeric compound represented by formula (A)-2 shown below; l/m/n=50/35/15, Mw=10,000, Mw/Mn=1.5

(B)-3: a compound represented by chemical formula (B)-3 shown below

(B)-4: a compound represented by chemical formula (B)-4 shown below

(D1)-2: a compound represented by the aforementioned chemical formula (D1)-2

(C)-2: a compound represented by chemical formula (C)-2 shown below

(F)-2: a polymeric compound represented by formula (F)-2 shown below; 1/m=80/20 (molar ratio), Mw=15,000, Mw/Mn=1.5

(S)-2: a mixed solvent of PGMEA/cyclohexanone=9/1 (weight ratio)

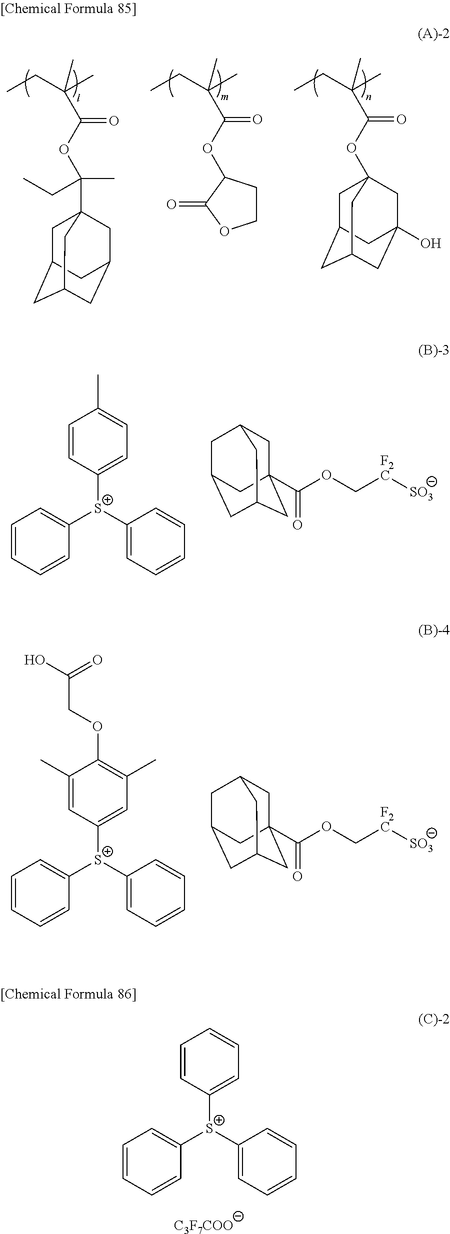

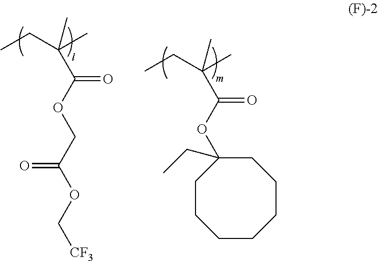

### <Formation of Resist Pattern (2)>

Using the obtained resist compositions, resist patterns were formed, and the following lithography properties were evaluated.

An organic anti-reflection film composition (product name: ARC29A, manufactured by Brewer Science Ltd.) was applied to an 12-inch silicon wafer using a spinner, and the composition was then baked at 205° C. for 60 seconds on a hotplate, thereby forming an organic anti-reflection film having a film thickness of 89 nm.

Then, the resist composition was applied onto the anti-reflection film using a spinner, and was then prebaked (PAB) on a hotplate at 105° C. for 60 seconds and dried, thereby forming a resist film having a film thickness of 120 nm.

Then, the resist film was selectively irradiated with an ArF excimer laser (193 nm) through a mask for forming a hole pattern, using an ArF exposure apparatus NSR-S609B (manufactured by Nikon Corporation, NA (numerical aperture)=1.07, Annular (out-0.97/In-0.78)w/XY-Pol. immersion medium: water).

Thereafter, a post exposure bake (PEB) treatment was conducted at 85° C. for 60 seconds, followed by development for 13 seconds at 23° C. in methyl amyl ketone. Further, a post bake was conducted at 100° C. for 45 seconds on the hot plate.

As a result, with each resist compositions, a contact hole pattern having a hole diameter (CD) of 60 nm and a pitch of 120 nm was formed.

The EOP, MEF, DOF and the circularity were evaluated in the same manner as in the aforementioned <Formation of resist pattern (1)>. The results are shown in Table 4.

TABLE 4

| | EOP | | DOF | |
|---|---|---|---|---|
| | (mJ/cm²) | MEF | (μm) | Circularity |
| Comparative | 22.2 | 10.82 | 0.14 | 1.92 |
| Example 3 | | | | |
| Example 3 | 26.2 | 6.52 | 0.17 | 1.80 |
| Example 4 | 24.2 | 6.74 | 0.16 | 1.82 |
| Example 5 | 26.3 | 7.48 | 0.18 | 1.68 |
| Example 6 | 25.0 | 6.80 | 0.16 | 1.90 |

From the results shown in Table 4, it was confirmed that the resist compositions of Examples 3 to 6 were improved in DOF properties, as compared to the resist compositions of Comparative Example 3. In addition, it was confirmed that the resist compositions of Examples 3 to 6 were further improved in MEF.

### <Formation of Resist Pattern (3)>

Contact hole patterns having a hole diameter (CD) of 60 nm and a pitch of 120 nm were formed in the same manner as in the <Formation of resist pattern (2)>, except that the organic solvent within the developing solution was changed to butyl acetate.

In this case, it was confirmed that the resist compositions of Examples 3 to 6 were improved in DOF properties and MEF, as compared to the resist compositions of Comparative Example 3.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition comprising:
a base component (A) which exhibits changed solubility in a developing solution under action of acid;
an acid-generator component (B) which generates acid upon exposure; and
a compound (D1) comprising a cation moiety which contains a quaternary nitrogen atom, and an anion moiety represented by formula (d1-an1) or (d1-an2) shown below: 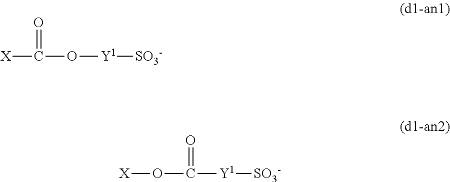
wherein, X represents a cyclic aliphatic hydrocarbon group of 3 to 30 carbon atoms which may have a substituent; and Y¹ represents a fluorinated alkylene group of 1 to 4 carbon atoms which may have a substituent.

2. The resist composition according to claim 1, wherein the base component (A) comprises a polymeric compound (A1) including a structural unit (a1) comprising an acid decomposable group that exhibits increased polarity by the action of acid.

3. A method of forming a resist pattern, comprising: forming a resist film on a substrate using a resist composition of claim 1 or 2; conducting exposure of the resist film; and developing the resist film to form a resist pattern.
